(19) United States
(12) Patent Application Publication
(10) Pub. No.: US 2025/0359034 A1
(43) Pub. Date: Nov. 20, 2025

(54) BACK-END-OF-LINE SEMICONDUCTOR DEVICE STRUCTURE PROVIDING A NOT-GATE LOGIC FUNCTION AND METHODS OF FORMING THE SAME

(71) Applicant: Taiwan Semiconductor Manufacturing Company Limited, Hsinchu (TW)

(72) Inventors: Ching-Wen Chan, Taichung City (TW); Chang-Chih Huang, Taichung (TW); Chih-Ren Hsieh, Changhua City (TW); Yi Ching Ong, Hsinchu (TW); Kuo-Chyuan Tzeng, Chu-Pei City (TW); Kuo-Ching Huang, Hsinchu City (TW); Harry-Hak-Lay Chuang, Zhubei City (TW)

(21) Appl. No.: 18/895,867

(22) Filed: Sep. 25, 2024

Related U.S. Application Data
(60) Provisional application No. 63/649,478, filed on May 20, 2024.

(51) Int. Cl. H10B 12/00

(52) U.S. Cl. CPC H10B 12/50; H10B 12/0335; H10B 12/09; H10B 12/31

(57) ABSTRACT

A device structure may be provided by forming a peripheral circuit and transistors of a memory array; forming lower-level metal interconnect structures formed within lower-level dielectric material layers; depositing a dielectric capping layer including an array of memory-region openings and at least one peripheral-region opening; depositing a capacitor material layer stack including a first electrode material layer, a node dielectric material layer, and a second electrode material layer over the dielectric capping layer; and patterning the capacitor material layer stack into an array of memory node capacitors and a voltage stabilization capacitor. Each of the memory node capacitors is a charge storage capacitor for a respective memory cell of the memory array, and the voltage stabilization capacitor is configured to stabilize a voltage of the peripheral circuit.

### RELATED APPLICATIONS

This application claims the benefit of priority from U.S. Provisional Application No. 63/649,748 titled “Method for Manufacturing Capacitors of a Memory Device and a Circuit Peripheral to the Device” and filed on May 20, 2024, the entire contents of which are hereby incorporated by reference for all purposes.

### BACKGROUND

Capacitors are essential for devices such as gain cell memory cells. The manufacture of high-capacitance capacitors with a minimal device footprint is a challenging task. Furthermore, integrating capacitors for both a memory array and a peripheral circuit increases production costs and process complexity, while also posing potential limitations on the performance and scalability of the resulting memory devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

It is noted that elements may be arbitrarily placed within, or out of, the vertical plane of the view in any pseudo vertical cross-sectional view, and there may not be a particular physical vertical plane that may display all elements illustrated in a pseudo vertical cross-sectional view.

FIG. 1 is a vertical cross-sectional view of a first embodiment structure after formation of memory transistors for a memory array, a peripheral circuit, lower-level dielectric material layers and lower-level metal interconnect structures according to a first embodiment of the present disclosure.

FIG. 2A is a circuit schematic of a two-transistor gain cell memory cell that may be used for the first embodiment structure.

FIG. 2B is a circuit schematic of a three-transistor gain cell memory cell that may be used for the first embodiment structure.

FIG. 3 is a vertical cross-sectional view of the first embodiment structure after formation of a dielectric capping layer according to the first embodiment of the present disclosure.

FIG. 4 is a vertical cross-sectional view of the first embodiment structure after formation of discrete openings through the dielectric capping layer according to the first embodiment of the present disclosure.

FIG. 5 is a vertical cross-sectional view of the first embodiment structure after deposition of a capacitor material layer stack including a first electrode material layer, a node dielectric material layer, and a second electrode material layer over the dielectric capping layer according to the first embodiment of the present disclosure.

FIG. 6 is a vertical cross-sectional view of the first embodiment structure after deposition of a hard mask material layer according to the first embodiment of the present disclosure.

FIG. 7 is a vertical cross-sectional view of the first embodiment structure after formation of an array of memory node capacitors and a voltage stabilization capacitor according to the first embodiment of the present disclosure.

FIG. 8A is a vertical cross-sectional view of the first embodiment structure after formation of an upper-level dielectric material layer and upper-level metal interconnect structures according to the first embodiment of the present disclosure.

FIGS. 8B-8H are vertical cross-sectional views of alternative configurations of the first embodiment structure according to the first embodiment of the present disclosure.

FIG. 9 is a vertical cross-sectional view of a second embodiment structure after deposition of a capacitor material layer stack including a first electrode material layer, a node dielectric material layer, and a second electrode material layer over the dielectric capping layer according to a second embodiment of the present disclosure.

FIG. 10 is a vertical cross-sectional view of the second embodiment structure after formation of various second electrodes by performing a planarization process according to the second embodiment of the present disclosure.

FIG. 11 is a vertical cross-sectional view of the second embodiment structure after formation of array hard mask plates and a peripheral hard mask plate according to the second embodiment of the present disclosure.

FIG. 12 is a vertical cross-sectional view of the second embodiment structure after formation of an array of memory node capacitors and a voltage stabilization capacitor according to the second embodiment of the present disclosure.

FIG. 13A is a vertical cross-sectional view of the second embodiment structure after formation of an upper-level dielectric material layer and upper-level metal interconnect structures according to the second embodiment of the present disclosure.

FIGS. 13B-13H are vertical cross-sectional views of alternative configurations of the second embodiment structure according to the second embodiment of the present disclosure.

FIG. 14 is a vertical cross-sectional view of a third embodiment structure after formation of various second electrodes by performing a planarization process according to the third embodiment of the present disclosure.

FIG. 15 is a vertical cross-sectional view of the third embodiment structure after formation of an array of memory node capacitors and a voltage stabilization capacitor according to the first embodiment of the present disclosure.

FIG. 16A is a vertical cross-sectional view of the third embodiment structure after formation of an upper-level dielectric material layer and upper-level metal interconnect structures according to the third embodiment of the present disclosure.

FIGS. 16B-16F are vertical cross-sectional views of alternative configurations of the third embodiment structure according to the third embodiment of the present disclosure.

FIG. 17 is a vertical cross-sectional view of a fourth embodiment structure after formation of a metallic fill material layer according to a fourth embodiment of the present disclosure.

FIG. 18 is a vertical cross-sectional view of the fourth embodiment structure after formation of an array of memory damascene pads and at least one peripheral damascene pad according to the fourth embodiment of the present disclosure.

FIG. 19 is a vertical cross-sectional view of the fourth embodiment structure after deposition of a capacitor material layer stack including a first electrode material layer, a node dielectric material layer, and a second electrode material layer over the dielectric capping layer and a hard mask material layer according to the fourth embodiment of the present disclosure.

FIG. 20 is a vertical cross-sectional view of the fourth embodiment structure after formation of an array of memory node capacitors and a voltage stabilization capacitor according to the fourth embodiment of the present disclosure.

FIG. 21A is a vertical cross-sectional view of the fourth embodiment structure after formation of an upper-level dielectric material layer and upper-level metal interconnect structures according to the fourth embodiment of the present disclosure.

FIGS. 21B-21K are vertical cross-sectional views of alternative configurations of the fourth embodiment structure according to the fourth embodiment of the present disclosure.

FIG. 22 is a first flowchart that illustrates a sequence of processing steps for forming a semiconductor structure of the present disclosure.

FIG. 23 is a second flowchart that illustrates a sequence of processing steps for forming a semiconductor structure of the present disclosure.

### DETAILED DESCRIPTION

The following disclosure provides many different embodiments, or examples, for implementing different features of the provided subject matter. Specific examples of components and arrangements are described below to facilitate understanding of the present disclosure. These are merely examples, and are not limiting. Drawings are not drawn to scale. Elements with the same reference numerals refer to the same element, and are presumed to have the same material composition and the same thickness range unless expressly indicated otherwise. Embodiments are expressly contemplated in which multiple instances of any described element are repeated unless expressly stated otherwise. Embodiments are expressly contemplated in which non-essential elements are omitted even if such embodiments are not expressly disclosed but are known in the art.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure is directed generally to a semiconductor device structure and methods for manufacturing the same. Specifically, the present disclosure is directed to a device structure including memory node capacitors for a memory array and a voltage stabilization capacitor that may be used for a peripheral circuit and methods for manufacturing the same. Peripheral circuit and memory array transistors may be formed over a semiconductor substrate. Lower-level metal interconnect structures may be formed within dielectric material layers. A dielectric capping layer with memory-region openings and peripheral-region openings may be formed. A capacitor material layer stack may be deposited and patterned to form memory node capacitors and a voltage stabilization capacitor. The process addresses the challenges of manufacturing high-capacitance capacitors with a minimal device footprint, and integrates capacitors for both memory arrays and peripheral circuits without requiring additional masks, thereby reducing production costs and process complexity. Embodiments of the present disclosure may be used to improve the performance and scalability of memory devices by efficiently integrating high-capacitance capacitors into both memory arrays and peripheral circuits. The various aspects of the present disclosure are now described with reference to the accompanying drawings.

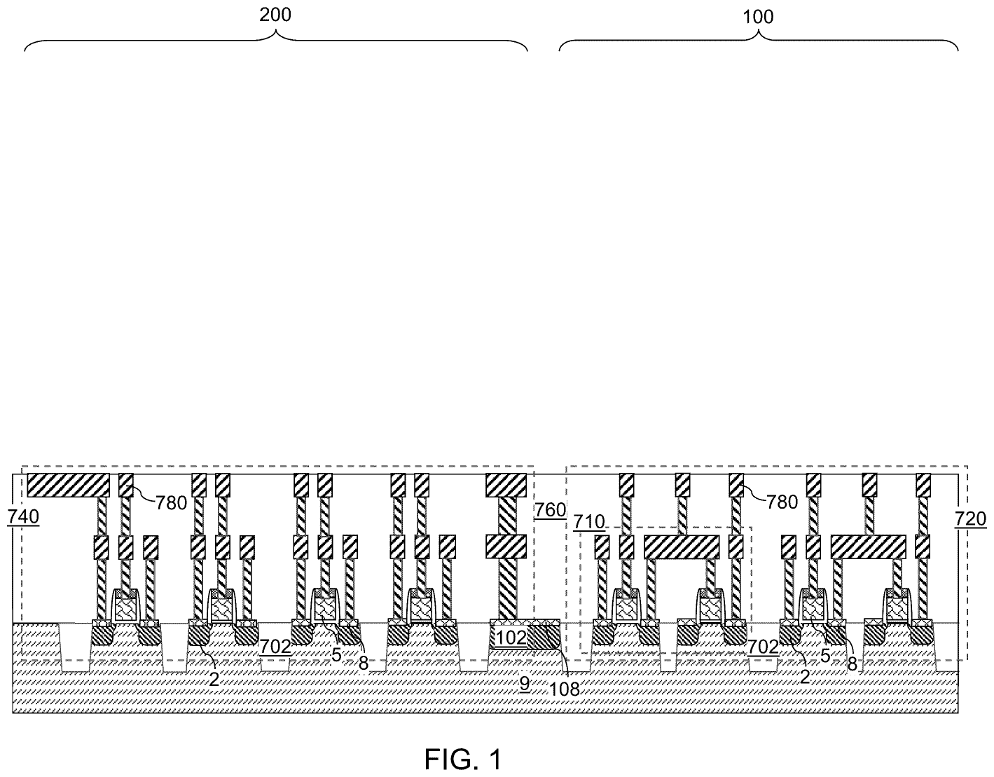

Referring to FIG. 1, a first embodiment structure for forming a memory array and a voltage stabilization capacitor is illustrated. As used herein, a voltage stabilization capacitor refers to any capacitor configured to maintain a steady voltage supply by mitigating fluctuations in a power supply circuit, thereby ensuring consistent performance and reliability of a powered circuit during operation. A voltage stabilization capacitor helps stabilize a voltage level within the power supply circuit, protecting sensitive components from voltage spikes and drops that could potentially affect data integrity, processing speeds, or any other performance metric of the powered circuit. Nonlimiting examples of a voltage stabilization capacitor includes charge pump capacitors, bypass capacitors, and decoupling capacitors as known in the art.

The first embodiment structure includes a semiconductor substrate 9, which may be any type of semiconductor substrate known in the art. For example, the semiconductor substrate 9 may comprise a single crystalline silicon substrate, a compound semiconductor substrate, a semiconductor-on-insulator (SOI) substrate, etc. Isolation structures 702, such as shallow trench isolation structures, may be formed in an upper portion of the semiconductor substrate 9. Various semiconductor devices may be formed on the semiconductor substrate 9. The first embodiment structure may comprise a memory array region 100 in which a memory array is to be subsequently formed, and a peripheral device region 200 in which peripheral devices and at least one voltage stabilization capacitor is to be subsequently formed. The various semiconductor devices may comprise transistors such as field effect transistors including a respective pair of source/drain regions 2 and a respective gate electrode 5. Source/drain metal semiconductor alloy regions 8 (such as metal silicide regions) may be formed on the source/drain regions 2. As used herein, (a) source/drain region(s) may refer to (a) source region(s) and/or (a) drain regions, individually or collectively, depending on the context. Further, it is noted that a source/drain region may operate as a source region or a drain region depending on the mode of operation in some cases. Generally, any type of field effect transistors known in the art may be formed on the semiconductor substrate 9.

A subset of the transistors that is formed in the memory array region 100 and is used as components of the memory array is herein referred to as memory transistors 710. A circuit that is formed by interconnection of the memory transistors 710 is herein referred to as a memory transistor circuit 720. The electrical connection to and from the memory transistors 710 may be provided by metal interconnect structures formed within dielectric material layers. The metal interconnect structures are herein referred to as lower-level metal interconnect structures 780, and the dielectric material layers are herein referred to as lower-level dielectric material layers 760. In one embodiment, the type of memory cells within the memory array that is formed within the first embodiment structure may be a type that uses at least one field effect transistor and a memory node capacitor per memory cell. For example, the type of memory cells in the memory array may be a gain cell (GC) memory cell that uses two or three transistors and a memory node capacitor per memory cell. In this embodiment, all components of the memory array may be formed and interconnected except an array of memory node capacitors at this processing step.

Doped semiconductor wells 102 may be formed in the semiconductor substrate 9. Metal-semiconductor alloy regions 108 may be formed on a subset of the doped semiconductor wells 102. At least one doped semiconductor well 102 and optionally at least one metal-semiconductor alloy region 108 may function as electrical ground for a subset of nodes for capacitors to be subsequently formed. A subset of the lower-level metal interconnect structures 780 may be electrically connected to the at least one doped semiconductor well 102 and the optional at least one metal-semiconductor alloy region 108.

Additional semiconductor devices, such as additional transistors, may be formed in the peripheral device region 200 to provide a peripheral circuit 740, which may be any type of circuit known in the art. For example, the peripheral circuit 740 may comprise a logic circuit for operating the memory array to be subsequently formed. In this embodiment, the peripheral circuit 740 may comprise a word line driver circuit, a bit line driver circuit, a sense amplifier circuit, an address decoder circuit, a data latch and buffer circuit, an input/output controller circuit, etc. Additionally or alternatively, the peripheral circuit 740 may comprise a power supply circuit that is to be subsequently electrically connected to a voltage stabilizer capacitor. The electrical connection to and from the various nodes of the peripheral circuit 740 may be provided by additional lower-level metal interconnect structures 780 formed within the lower-level dielectric material layers 760. Generally, the lower-level metal interconnect structures 780 may comprise any type of metal interconnect structures known in the art including, but not limited to, metal line structures, metal via structures, metal pad structures, integrated metal line-and-via structures, etc.

While two metal line interconnect levels are illustrated in FIG. 1, it should be understood that the number of metal line levels that may be used to provide electrical connection within the memory transistor circuit 720 and the peripheral circuit 740 may be selected depending on the complexity of the electrical connections within the memory transistor circuit 720 and the peripheral circuit 740. The number of metal line levels may be generally in a range from 1 to 10, although a greater number may also be used.

Generally, a peripheral circuit 740 may be formed over the semiconductor substrate 9 in the peripheral device region 200, and transistors of a memory array may be formed over the semiconductor substrate 9 in the memory array region 100. A combination of lower-level metal interconnect structures 780 and lower-level dielectric material layers 760 may be formed over the semiconductor substrate 9 such that suitable electrical connections are provided for the memory transistor circuit 720 and the peripheral circuit 740.

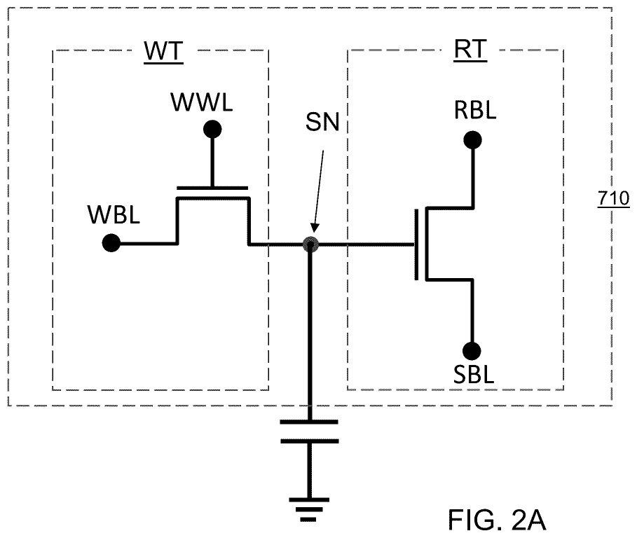

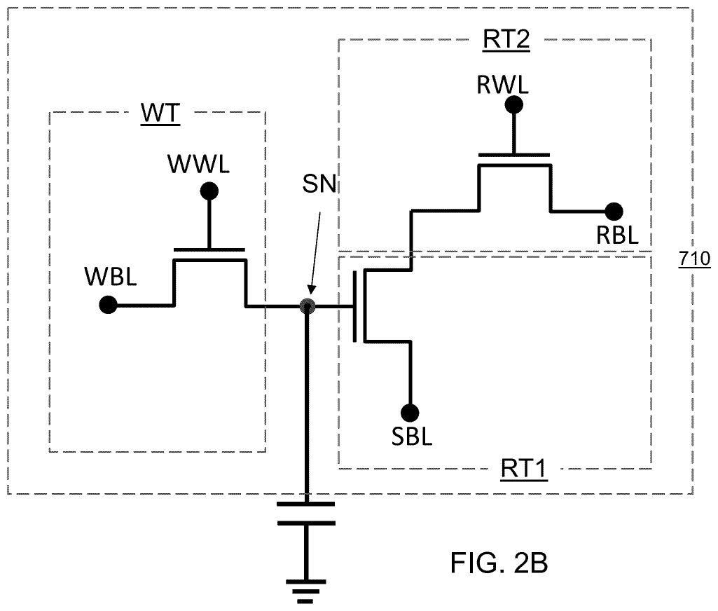

Referring to FIG. 2A, a circuit schematic of a two-transistor gain cell memory cell is illustrated, which may be used for the first embodiment structure in FIG. 1. The two-transistor gain cell memory cell comprises a combination of a write transistor WT, a read transistor RT, and a memory node capacitor. The source node of the write transistor WT may be connected to a write bit line WBL, the gate electrode of the write transistor WT may be connected to a write word line WWL, and the drain node of the write transistor WT may be connected to the gate electrode of the read transistor RT. The drain node of the write transistor WT is also connected to a first electrode of the memory node capacitor, and functions as a storage node SN at which electrical charges are stored. A second electrode of the memory node capacitor may be electrically grounded. The source node of the read transistor RT may be connected to a source-side bit line SBL, and the drain node of the read transistor RT may be connected to a read bit line RBL. The read transistor RT and the write transistor WT may comprise a pair of memory transistors 710 illustrated in FIG. 1.

Referring to FIG. 2B, a circuit schematic of a three-transistor gain cell memory cell is illustrated, which may be used for the first embodiment structure in FIG. 1. The three-transistor gain cell memory cell illustrated in FIG. 2B may be derived from the two-transistor gain cell memory cell illustrated in FIG. 2A by replacing the read transistor RT with a series connection of a first read transistor RT1 and a second read transistor RT2. The drain node of the write transistor WT is connected to the gate electrode of the first read transistor RT1. The source node of the first read transistor RT1 is connected to the source-side bit line SBL. The drain node of the first read transistor RT1 is connected to the source node of the second read transistor RT2. The drain node of the second read transistor RT2 is connected to the read bit line RBL. The gate electrode of the second read transistor RT2 is connected to the read word line RWL.

It should be understood that the exemplary configuration of a gain cell memory cell shown in FIGS. 2A and 2B are merely illustrative, and any alternative configurations for a gain cell memory cell may also be used. Further, embodiments of the present disclosure are not limited to gain cell memory cells, but may be used for any type of memory device using at least one memory transistor 710 and a memory node capacitor. For example, a charge storage memory cell using an access transistor and a memory node capacitor may be used in the same manner as in dynamic random access memory devices. Generally, an array of memory transistors 710 used for a memory array may be formed and may be electrically wired in the first embodiment structure illustrated in FIG. 1, and an array of memory node capacitors may be subsequently formed and may be electrically connected to the array of memory transistors 710.

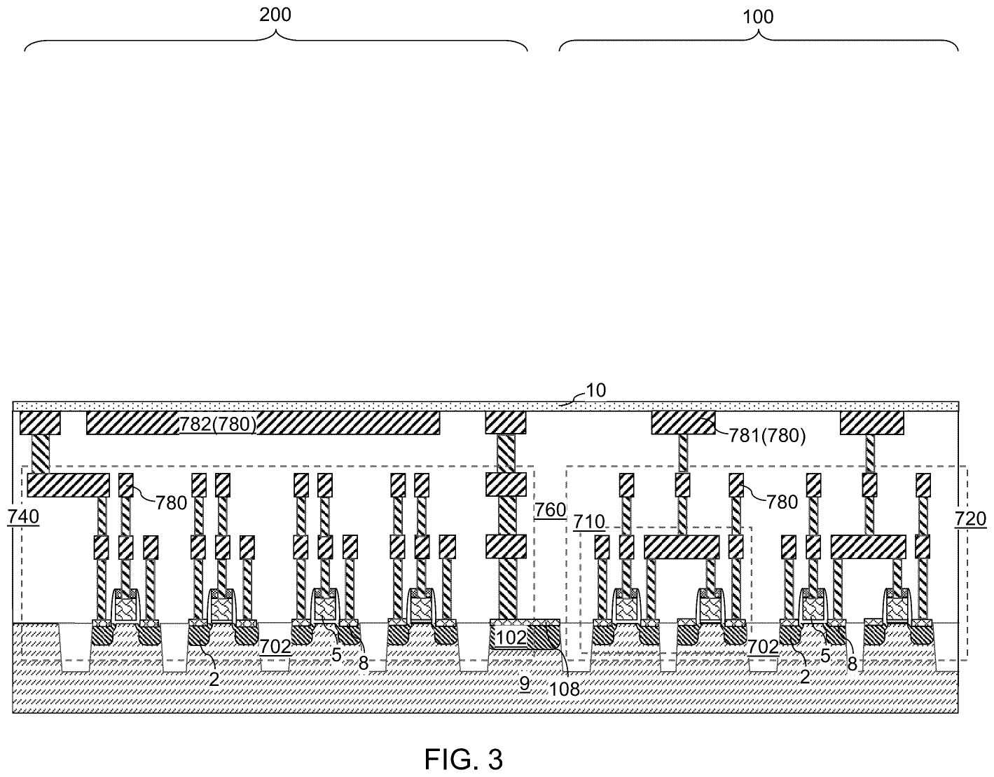

Referring to FIG. 3, metal pads may be formed within a dielectric material layer and may be formed as a subset of the lower-level metal interconnect structures 780. In one embodiment, an additional lower-level dielectric material layer 760 may be formed over the lower-level dielectric material layers 760 provided within the first embodiment structure illustrated in FIG. 1, and the metal pads may be formed within the additional lower-level dielectric material layer 760. Alternately, the metal pads may be formed in the topmost level of the lower-level dielectric material layers 760 as provided within the first embodiment structure illustrated in FIG. 1.

The metal pads may comprise an array of connection metal pads 781 that is formed within the memory array region 100. Each of the connection metal pads 781 may be electrically connected to a respective one of the memory transistors 710. For example, each of the connection metal pads 781 may comprise a component of a storage node SN illustrated in FIGS. 2A and 2B, and may be electrically connected to a gate electrode of a read transistor and a drain node of a write transistor. The metal pads may further comprise a peripheral-region metal pad 782 that is formed with the peripheral device region 200. Generally, the array of connection metal pads 781 and the peripheral-region metal pad 782 may be formed at the topmost level of the lower-level dielectric material layers 760. The top surfaces of the array of connection metal pads 781 and the peripheral-region metal pad 782 may be formed within a horizontal plane including a top surface of the topmost layer selected from the lower-level dielectric material layers 760. Generally, each of the lower-level dielectric material layers 760 may comprise any interlayer dielectric (ILD) material known in the art such as undoped silicate glass, a doped silicate glass, organosilicate glass, silicon nitride, etc.

According to an aspect of the present disclosure, a dielectric capping layer 10 may be formed as a continuous dielectric material layer over the lower-level dielectric material layers 760. In one embodiment, the dielectric capping layer 10 may be formed directly on top surfaces of the connection metal pads 781 and directly one a top surface of the peripheral-region metal pad 782. The dielectric capping layer 10 comprises a dielectric material that may be subsequently used as an etch-stop material layer during a subsequent anisotropic etch process that patterns the memory node capacitors and a voltage stabilization capacitor. For example, the dielectric capping layer 10 may comprise silicon carbide, silicon carbide nitride, silicon oxycarbide, silicon nitride, or a dielectric metal oxide (such as aluminum oxide, hafnium oxide, etc.). The thickness of the dielectric capping layer 10 may be in a range from 5 nm to 60 nm, such as from 10 nm to 30 nm, although lesser and greater thicknesses may also be used.

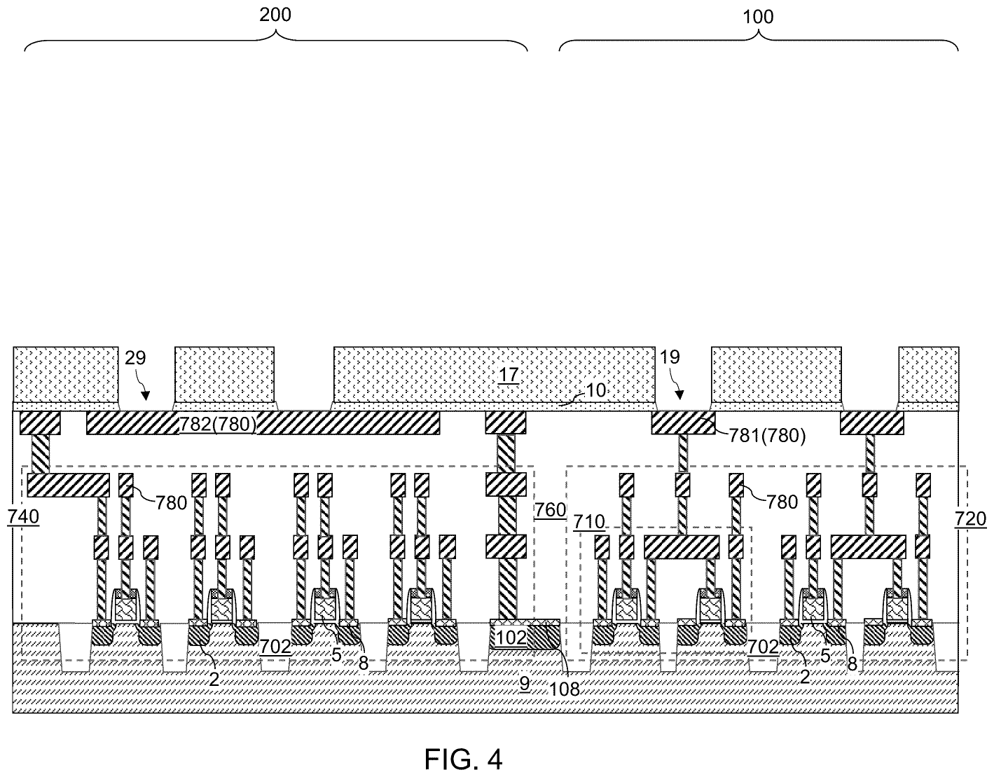

Referring to FIG. 4, discrete openings (19, 29) may be formed through the dielectric capping layer 10. Specifically, a photoresist layer 17 may be applied over the dielectric capping layer 10, and may be lithographically patterned to form openings therein. The pattern of the openings in the photoresist layer 17 may be selected such that the areal extent of each opening in the photoresist layer 17 is located entirely within a periphery of a respective underlying metal pad (781, 782). An etch process may be performed to transfer the pattern of the openings in the photoresist layer 17 through the dielectric capping layer 10. The etch process may comprise an anisotropic etch process such as a reactive ion etch process or an isotropic etch process such as a wet etch process. Generally, the chemistry of the etch process that etches the material of the dielectric capping layer 10 may be selective to the metallic material of the underlying metal pads (781, 782). An array of memory-region openings 19 may be formed in the memory array region 100, and at least one peripheral-region opening 29 may be formed in the peripheral device region 200. The array of connection metal pads 781 may be physically exposed underneath the array of memory-region openings 19. The peripheral-region metal pad 782 may be physically exposed underneath each of the at least one peripheral-region opening 29. The photoresist layer 17 may be subsequently removed, for example, by ashing.

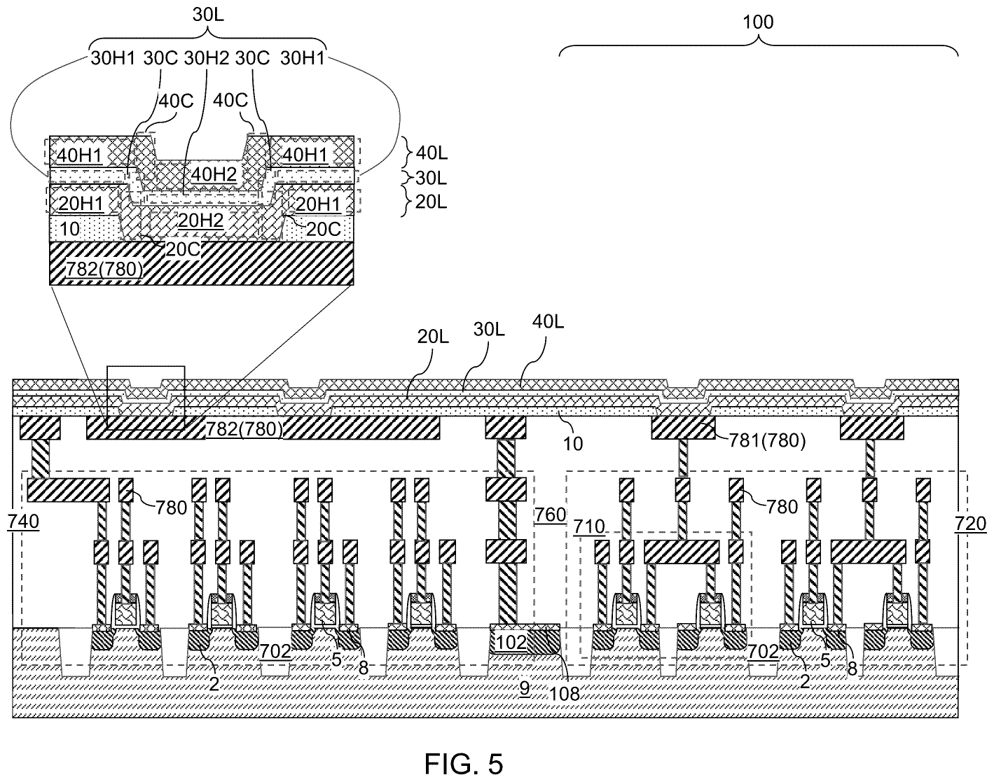

Referring to FIG. 5, a capacitor material layer stack (20L, 30L, 40L) including a first electrode material layer 20L, a node dielectric material layer 30L, and a second electrode material layer 40L may be deposited over the dielectric capping layer 10. The first electrode material layer 20L comprises, and/or consists essentially of, a first metallic material. In one embodiment, the first metallic material may be, for example, a conductive metallic nitride material (such as TiN, TaN, WN, or MoN) or a refractory metal (such as W, Mo, Ta, Nb, or Re) having a melting point higher than 2,000 degrees Celsius and providing sufficient resistance to metal diffusion and/or contamination for surrounding dielectric materials. The first electrode material layer 20L may be deposited by physical vapor deposition or chemical vapor deposition. The thickness of the first electrode material layer 20L may be in a range from 5 nm to 60 nm, such as from 10 nm to 30 nm, although lesser and greater thicknesses may also be used.

The first electrode material layer 20L may be deposited within the array of memory-region openings 19 and within at least one peripheral-region opening 29. In one embodiment, the first electrode material layer 20L may be deposited directly on physically exposed top surface segments of the array of connection metal pads 781, sidewalls of the memory-region openings 19, each physically exposed top surface segment of the peripheral-region metal pad 782, sidewalls of each peripheral-region opening 29, and a top surface of the dielectric capping layer 10. In one embodiment, the first electrode material layer 20L may be formed with vertical undulations in a vertical cross-sectional profile such that the first electrode material layer 20L comprises a first horizontally-extending portion 20H1 having an areal overlap with the dielectric capping layer 10 in a plan view, second horizontally-extending portions 20H2 located within areas of the array of memory-region openings 19 and the at least one peripheral-region opening 29, and tubular connecting portions 20C connecting a periphery of a respective one of the second horizontally-extending portions 20H2 to a periphery of a respective opening in the first horizontally-extending portion 20H1. As used herein, a plan view is a view along the vertical direction. In one embodiment, the tubular connection portions 20C may have a taper in a vertical cross-sectional view such that an outer sidewall of each tubular connection portion 20C may have a taper angle in a range from 5 degrees to 60 degrees relative to the vertical direction. Generally, the topographical features of the openings (19, 29) through the dielectric capping layer 10 may be replicated in a top surface of the first electrode material layer 20L with lateral shifts, such as reduction in the lateral extent, of each recessed surface segment of the top surface of the first electrode material layer 20L relative to the size of the openings (19, 29) through the dielectric capping layer 10.

The node dielectric material layer 30L comprises, and/or consists essentially of, a dielectric material that is suitable as a node dielectric for a capacitor. In one embodiment, the node dielectric material layer 30L comprises a dielectric material having a dielectric constant of at least 7.9. In one embodiment, the node dielectric material layer 30L comprises, and/or consists essentially of, silicon nitride or a dielectric metal oxide such as aluminum oxide or a transition metal oxide. The node dielectric material layer 30L may be deposited by chemical vapor deposition or atomic layer deposition. The thickness of the node dielectric material layer 30L may be in a range from 4 nm to 12 nm, such as from 5 nm to 8 nm, although lesser and greater thicknesses may also be used.

The node dielectric material layer 30L may be deposited as a continuous material layer having a uniform thickness throughout. In one embodiment, the node dielectric material layer 30L may be formed with vertical undulations in a vertical cross-sectional profile such that the node dielectric material layer 30L comprises a first horizontally-extending portion 30H1 having an areal overlap with the dielectric capping layer 10 in the plan view, second horizontally-extending portions 30H2 located within areas of the array of memory-region openings 19 and the at least one peripheral-region opening 29, and tubular connecting portions 30C connecting a periphery of a respective one of the second horizontally-extending portions 30H2 to a periphery of a respective opening in the first horizontally-extending portion 30H1. In one embodiment, the tubular connection portions 30C may have a taper in a vertical cross-sectional view such that an outer sidewall of each tubular connection portion 30C may have a taper angle in a range from 5 degrees to 60 degrees relative to the vertical direction. Generally, the topographical features of the openings (19, 29) through the dielectric capping layer 10 may be replicated in a top surface of the node dielectric material layer 30L with lateral shifts, such as reduction in the lateral extent, of each recessed surface segment of the top surface of the node dielectric material layer 30L relative to the size of the openings (19, 29) through the dielectric capping layer 10.

The second electrode material layer 40L comprises, and/or consists essentially of, a second metallic material. The second metallic material may be the same as, may be different from, the first metallic material. The second metallic material may comprise any material that may be used as the first electrode material. The second electrode material layer 40L may be deposited by physical vapor deposition or chemical vapor deposition. The thickness of the second electrode material layer 40L may be in a range from 5 nm to 60 nm, such as from 10 nm to 30 nm, although lesser and greater thicknesses may also be used.

In one embodiment, the second electrode material layer 40L is formed with vertical undulations in a vertical cross-sectional profile such that the second electrode material layer 40L comprises a first horizontally-extending portion 40H1 having an areal overlap with the dielectric capping layer 10 in a plan view, second horizontally-extending portions 40H2 located within areas of the array of memory-region openings 19 and the at least one peripheral-region opening 29, and tubular connecting portions 40C connecting a periphery of a respective one of the second horizontally-extending portions 40H2 to a periphery of a respective opening in the first horizontally-extending portion 40H1. As used herein, a plan view is a view along the vertical direction. In one embodiment, the tubular connection portions 40C may have a taper in a vertical cross-sectional view such that an outer sidewall of each tubular connection portion 40C may have a taper angle in a range from 5 degrees to 60 degrees relative to the vertical direction. Generally, the topographical features of the openings (19, 29) through the dielectric capping layer 10 may be replicated in a top surface of the second electrode material layer 40L with lateral shifts, such as reduction in the lateral extent, of each recessed surface segment of the top surface of the second electrode material layer 40L relative to the size of the openings (19, 29) through the dielectric capping layer 10. Thus, the top surface of the second electrode material layer 40L may be formed with vertically recessed surface segments that overlie the array of memory-region openings 19 and the at least one peripheral-region opening 29.

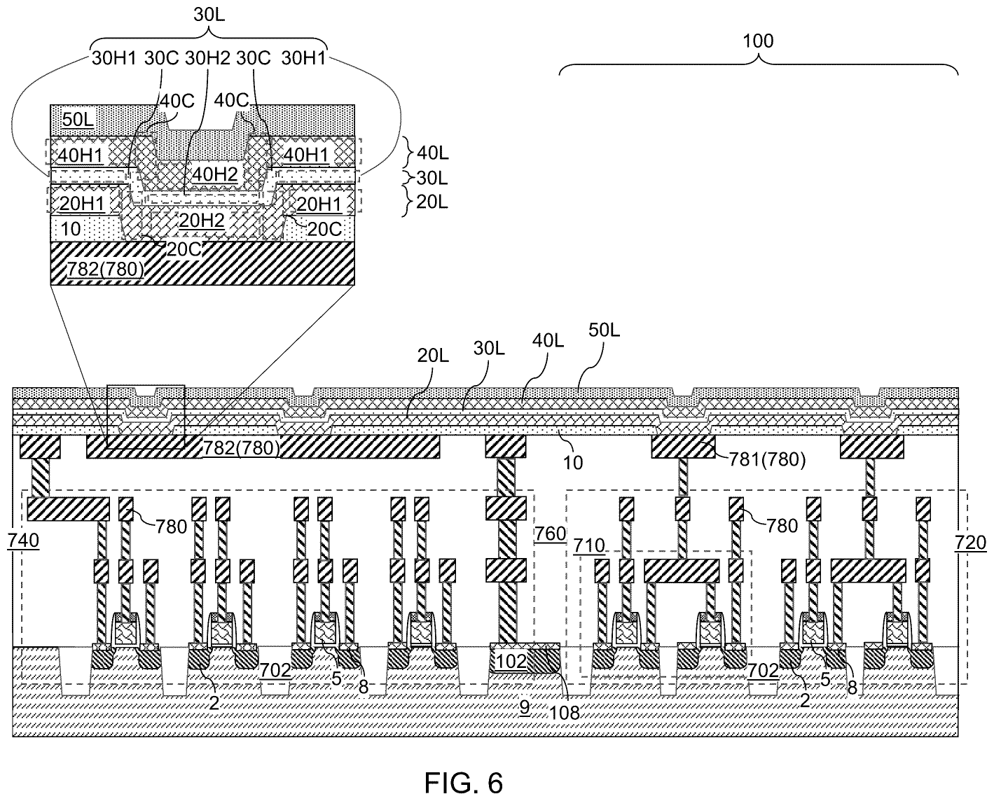

Referring to FIG. 6, a hard mask material layer 50L may be optionally deposited. The hard mask material layer 50L comprises a hard mask material such as silicon nitride, silicon carbide, silicon carbide nitride, silicon oxycarbide, silicon oxynitride, or a dielectric metal oxide (such as aluminum oxide or a transition metal oxide). The thickness of the hard mask material layer 50L may be in a range from 5 nm to 100 nm, such as from 10 nm to 50 nm, although lesser and greater thicknesses may also be used. The hard mask material layer 50L may be deposited, for example, by chemical vapor deposition or atomic layer deposition.

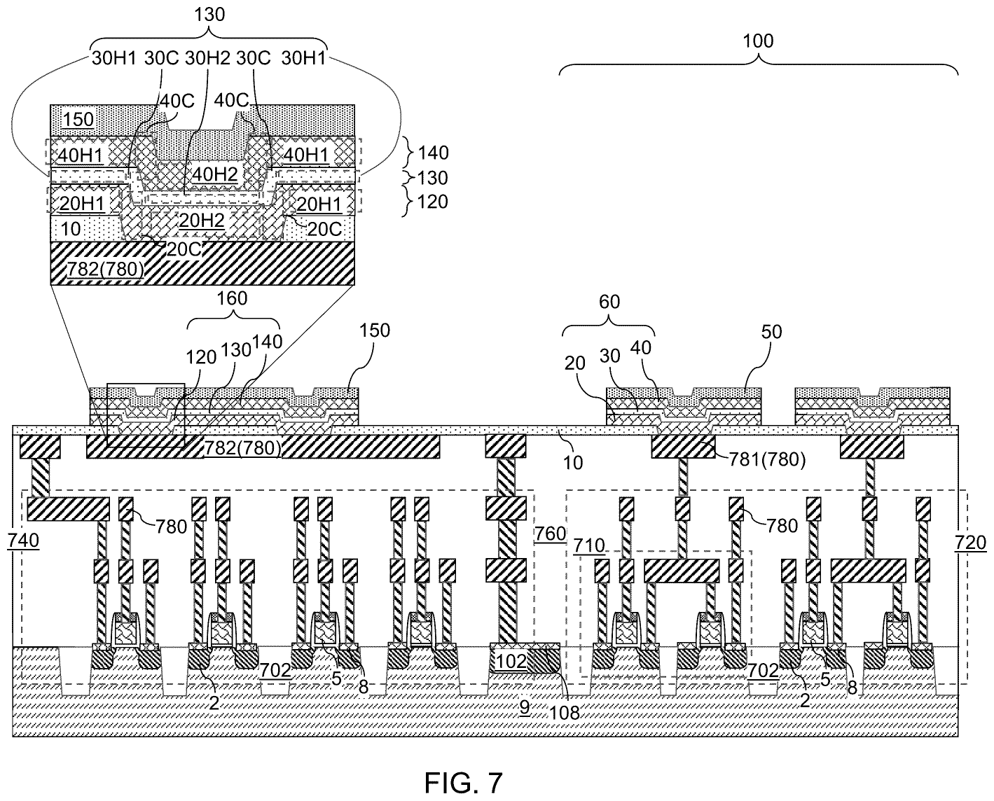

Referring to FIG. 7, a photoresist layer (not shown) may be applied over the hard mask material layer 50L, and may be lithographically patterned into a two-dimensional array of discrete photoresist material portions overlying the array of connection metal pads 781 and a photoresist material portion overlying the peripheral-region metal pad 782. A first anisotropic etch process may be performed to transfer the pattern in the patterned photoresist material portions through the hard mask material layer 50L. Patterned portions of the hard mask material layer 50L include array hard mask plates 50 that are formed in the memory array region 100, and at least one peripheral hard mask plate 150 that is formed in the peripheral device region 200. Subsequently, the photoresist layer may be removed by ashing.

A second anisotropic etch process may be performed to transfer the pattern in the array hard mask plates 50 and the at least one peripheral hard mask plate 150 through the capacitor material layer stack (20L, 30L, 40L). In this embodiment, the combination of the array hard mask plates 50 and the at least one peripheral hard mask plate 150 may be used as an etch mask for etching the materials of the capacitor material layer stack (20L, 30L, 40L). The second anisotropic etch process may have an etch chemistry that is selective to the material of the dielectric capping layer 10. In an alternative embodiment, removal of the photoresist layer that is used as an etch mask for patterning the hard mask material layer 50L may be performed after the second anisotropic etch process.

Each sidewall of the patterned portions of the second electrode material layer 40L is vertically coincident with a sidewall of a respective one of the array hard mask plates 50 and the at least one peripheral hard mask plate 150. Each sidewall of the patterned portions of the node dielectric material layer 30L is vertically coincident with a sidewall of a respective one of the array hard mask plates 50 and the at least one peripheral hard mask plate 150. Each sidewall of the patterned portions of the first electrode material layer 20L is vertically coincident with a sidewall of a respective one of the array hard mask plates 50 and the at least one peripheral hard mask plate 150.

Generally, the capacitor material layer stack (20L, 30L, 40L) may be patterned by transferring the pattern in the array of array hard mask plates 50 and the at least one peripheral hard mask plate 150 at least through the node dielectric material layer 30L and the first electrode material layer 20L using an anisotropic etch process that etches materials of the capacitor material layer stack (20L, 30L, 40L) selectively to a material of the dielectric capping layer 10. The patterned portions of the capacitor material layer stack (20L, 30L, 40L) that remains in the memory array region 100 comprises an array of memory node capacitors 60. The patterned portion of the capacitor material layer stack (20L, 30L, 40L) that remains in the peripheral device region 200 comprises a voltage stabilization capacitor 160. Thus, the capacitor material layer stack (20L, 30L, 40L) may be patterned into an array of memory node capacitors 60 and a voltage stabilization capacitor 160.

Each memory node capacitor 60 comprises a vertical stack of a first memory-capacitor electrode 20, a memory-capacitor node dielectric 30, and a second memory-capacitor electrode 40. Each first memory-capacitor electrode 20 is a patterned portion of the first electrode material layer 20L. Each memory-capacitor node dielectric 30 is a patterned portion of the node dielectric material layer 30L. Each second memory-capacitor electrode 40 is a patterned portion of the second electrode material layer 40L. The voltage stabilization capacitor 160 comprises a vertical stack of a first stabilization-capacitor electrode 120, a stabilization-capacitor node dielectric 130, and a second stabilization-capacitor electrode 140. The first stabilization-capacitor electrode is a patterned portion of the first electrode material layer 20L. The stabilization-capacitor node dielectric 130 is a patterned portion of the node dielectric material layer 30L. The second stabilization-capacitor electrode 140 is a patterned portion of the second electrode material layer 40L.

According to an aspect of the present disclosure, each of the memory node capacitors 60 is a charge storage capacitor for a respective memory cell of the memory array. The sidewalls of the first memory-capacitor electrode 20, the memory-capacitor node dielectric 30, and the second memory-capacitor electrode 40 within each memory node capacitor 60 may be vertically coincident with one another, i.e., located within the same vertical planes. Further, the sidewalls of the first memory-capacitor electrode 20, the memory-capacitor node dielectric 30, and the second memory-capacitor electrode 40 within each memory node capacitor 60 may be vertically coincident with sidewalls of a respective overlying array hard mask plate 50. In one embodiment, the sidewalls of first memory-capacitor electrode 20, the memory-capacitor node dielectric 30, and the second memory-capacitor electrode 40 within each memory node capacitor 60 may be located entirely outside the area defined by sidewalls of a respective underlying connection metal pad 781 in a plan view, i.e., in a view along the vertical direction. In other words, the areal extent of each connection metal pad 781 may be contained entirely within the areal extent of a respective overlying memory node capacitor 60 in a plan view such that the periphery of the respective metal pad 781 is laterally offset inward relative to the periphery of the respective overlying memory node capacitor 60.

Generally, each of the memory node capacitors 60 comprises a first memory-capacitor electrode 20 electrically connected with a respective one of the connection metal pads 781. In one embodiment, each second memory-capacitor electrode 40 may be formed with a contoured top surface having a vertically recessed surface segment that overlies a respective memory-region openings 19.

The peripheral-region metal pad 782 is electrically shorted (i.e., electrically coupled) to the first stabilization-capacitor electrode 120 upon formation of the first stabilization-capacitor electrode 120. In one embodiment, each of the first stabilization-capacitor electrode 120, the stabilization-capacitor node dielectric 130, and the second stabilization-capacitor electrode 140 may be formed with a respective contoured top surface including a respective set of at least one vertically recessed surface segment that overlies the at least one peripheral-region opening 29 in the dielectric capping layer 10.

The first embodiment structure comprises an array of memory node capacitors 60 overlying lower-level dielectric material layers 760 that overlie the transistors. The lower-level metal interconnect structures 780 may be formed within the lower-level dielectric material layers 760, and comprise an array of connection metal pads 781 electrically connected to a respective one of the transistors and electrically connected to a first electrode (i.e., the first memory-capacitor electrode 20) of a respective one of the memory node capacitors 60. The voltage stabilization capacitor 160 may be located over the lower-level dielectric material layers 760, and may be configured to stabilize a voltage of the peripheral circuit 740. The dielectric capping layer 10 overlies the array of connection metal pads 781 and comprises an array of memory-region openings 19 through which electrical connections are provided between the first electrodes (i.e., the first memory-capacitor electrodes 20) and the array of connection metal pads 781 and further comprises at least one peripheral-region opening 29 that underlies or laterally surrounds a first stabilization-capacitor electrode 120.

In one embodiment, the first memory-capacitor electrode 20 of each of the memory node capacitors 60 comprises a first horizontally-extending portion 20H1 that overlies the dielectric capping layer 10, and a downward-protruding portion that is adjoined to an inner periphery of the first horizontally-extending portion 20H1 and protrudes downward relative to the first horizontally-extending portion 20H1 and fills a respective one of the memory-region openings 19. Each memory-capacitor node dielectric 30 may have a vertical undulation in a vertical cross-sectional profile, and may comprise a first horizontally-extending portion 30H1 having an areal overlap with the dielectric capping layer 10 in a plan view, a second horizontally-extending portion 30H2 within an area of one of the memory-region openings 19, and a tubular connecting portion 30C connecting a periphery of the second horizontally-extending portion 30H2 to a periphery of an opening in the first horizontally-extending portion 30H1.

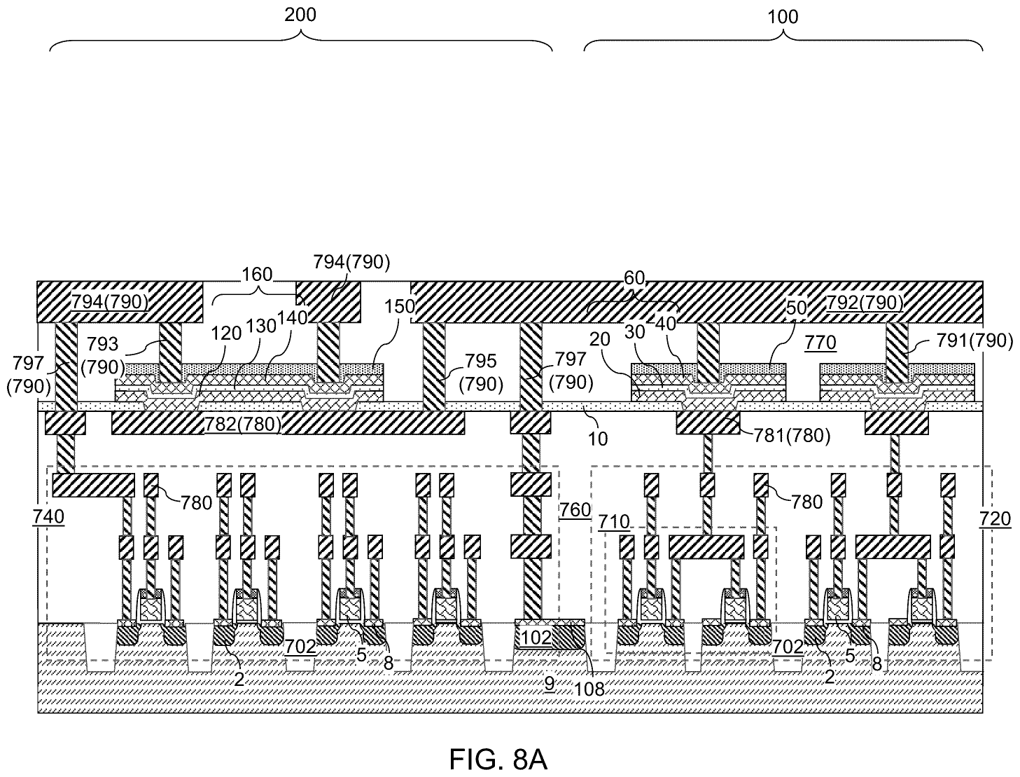

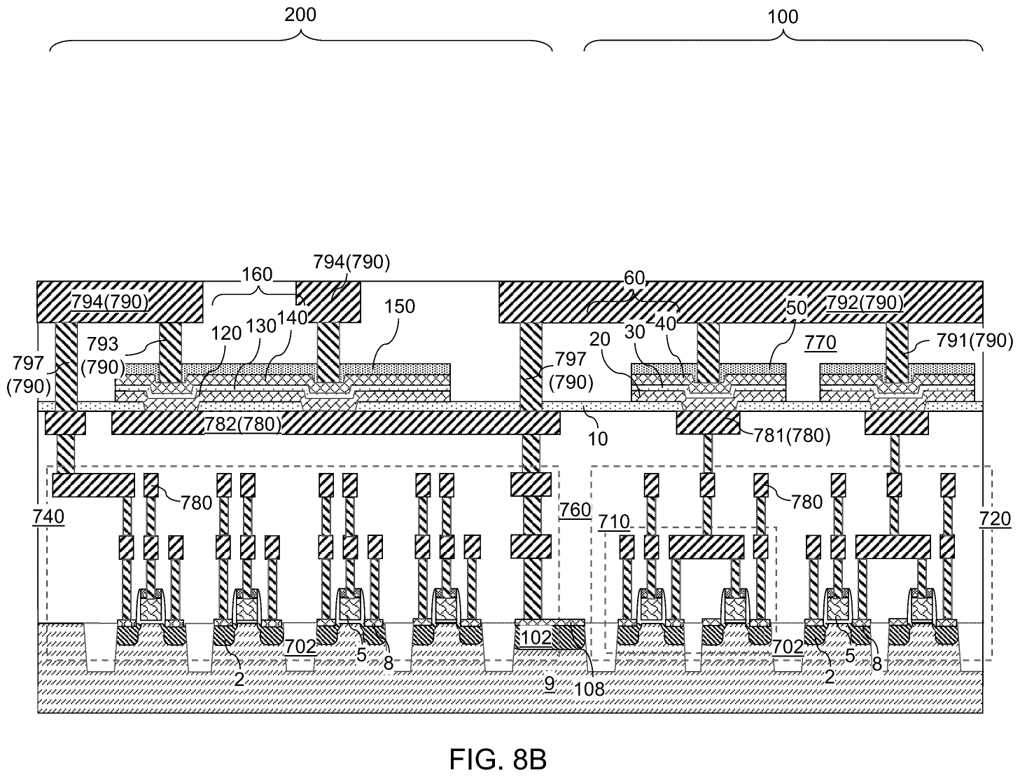

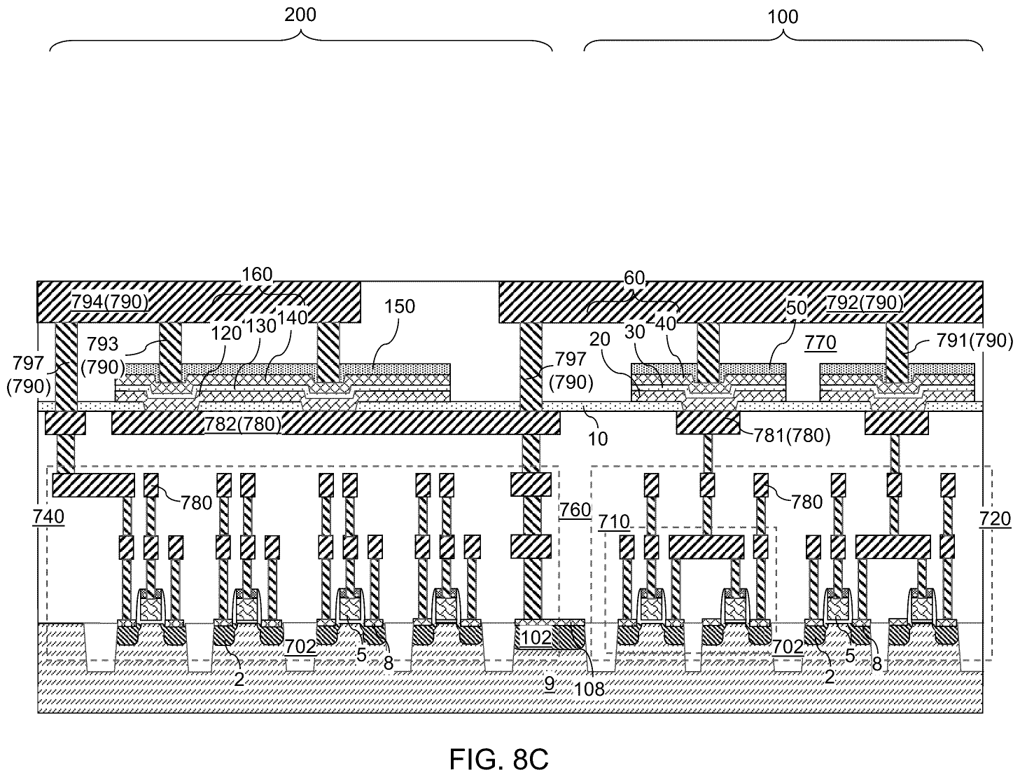

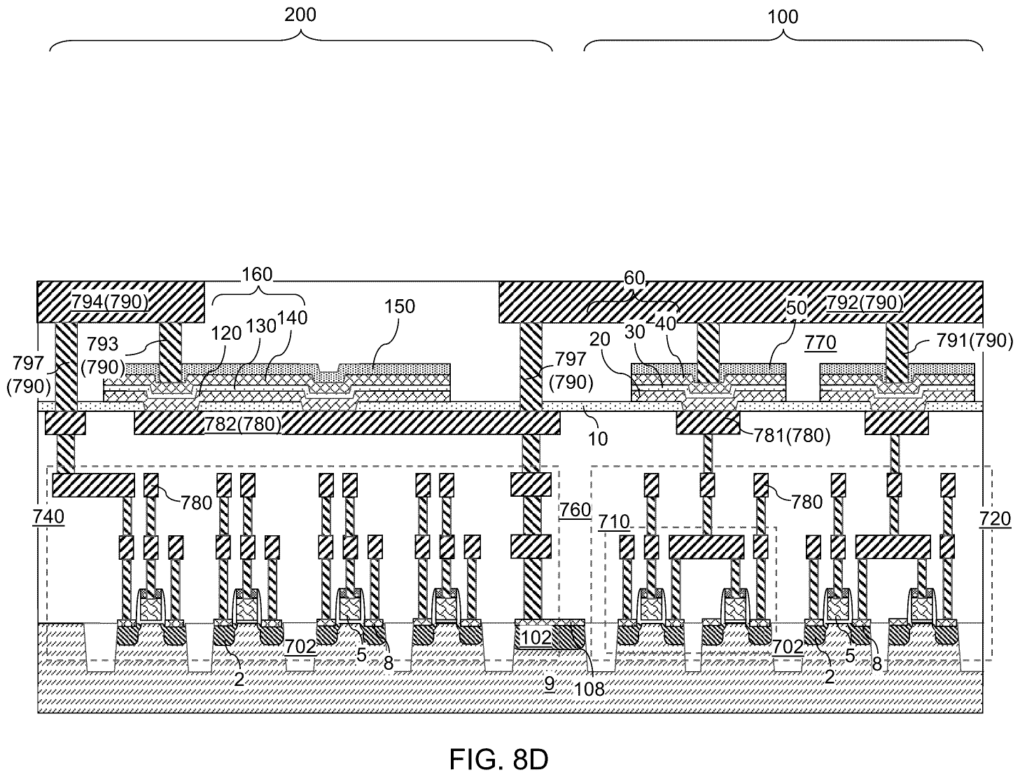

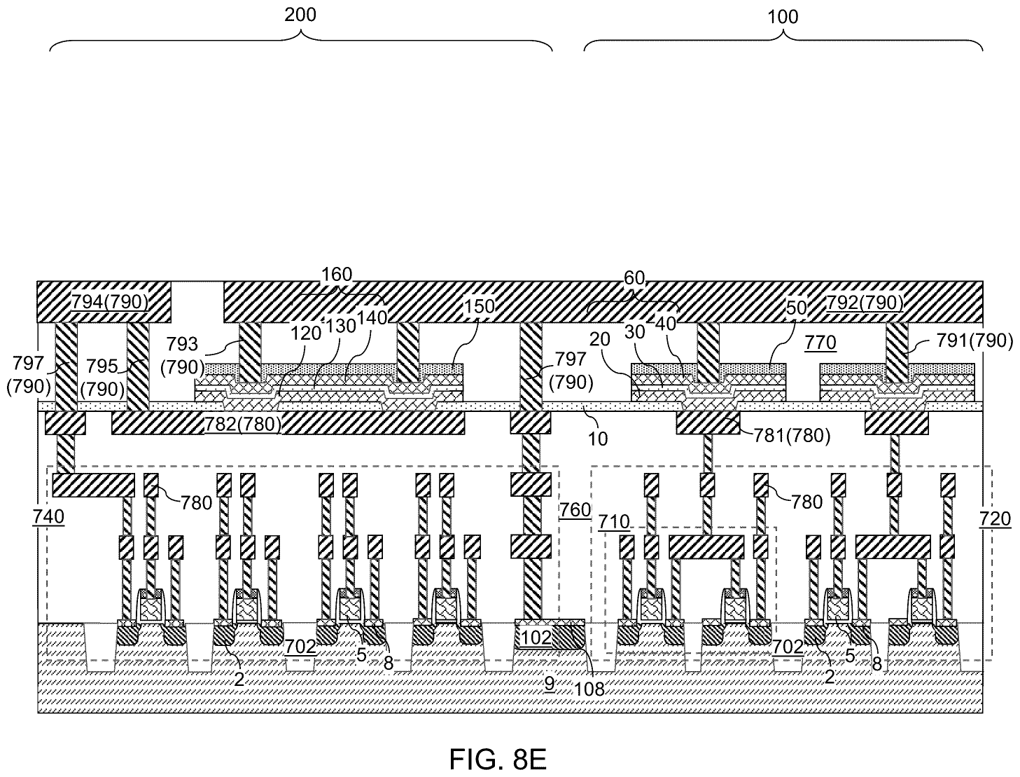

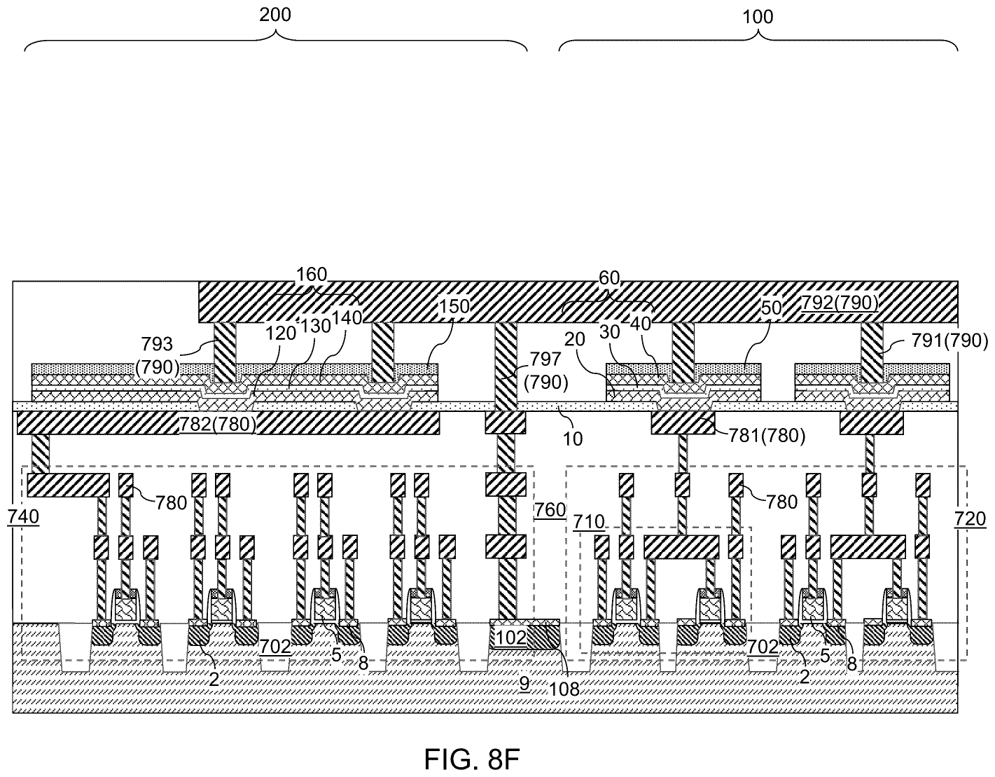

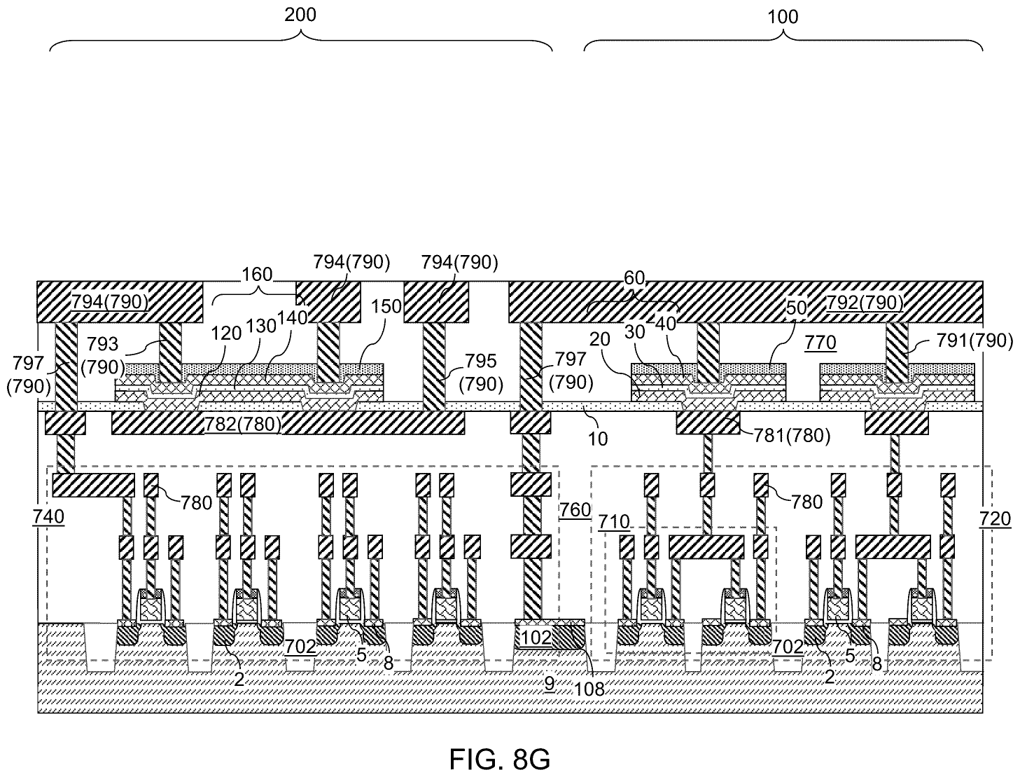

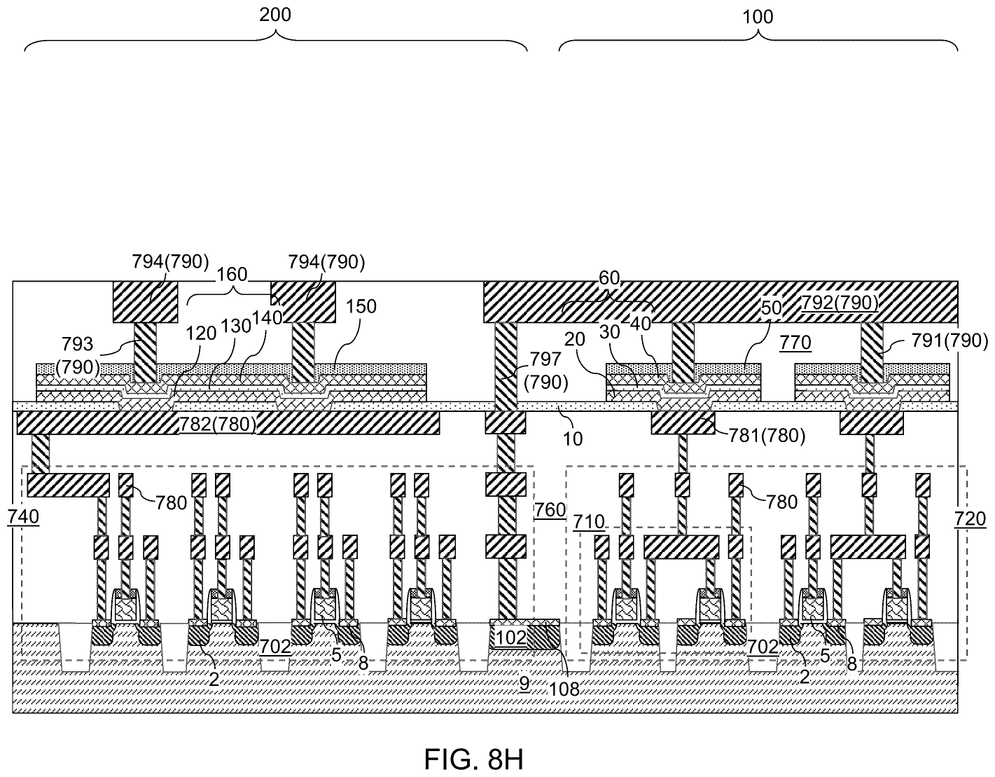

Referring to FIG. 8A, an upper-level dielectric material layer 770 and upper-level metal interconnect structures 790 may be formed to provide electrical connection to and from the second memory-capacitor electrode 40, the second stabilization-capacitor electrode 140, and the lower-level metal interconnect structures 780. The upper-level metal interconnect structures 790 may comprise array electrode contact via structures 791 that contact a respective one of the second memory-capacitor electrodes 40, at least one peripheral top electrode contact via structure 793 that contacts the second stabilization-capacitor electrodes 140, a peripheral bottom electrode contact via structure 795 that vertically extends through the dielectric capping layer 10 and contacts the peripheral-region metal pad 782, and connection via structures 797 that contact a respective metal line or a respective metal pad that may be formed within the lower-level dielectric material layers 760. Further, the upper-level metal interconnect structures 790 may comprise a memory-region upper metal line 792 that contacts a plurality of the array electrode contact via structures 791, and at least one peripheral-region metal line 794 that contacts a respective subset of the peripheral top electrode contact via structures 793.

In one embodiment, the memory-region upper metal line 792 may contact a connection via structure 797 that is electrically connected to an electrical ground node, which may comprise a doped semiconductor well 102 and the semiconductor substrate 9. In some embodiments, one of the first stabilization-capacitor electrode 120 and the second stabilization-capacitor electrode 140 may be electrically grounded, and another of the stabilization-capacitor electrode 120 and the second stabilization-capacitor electrode 140 may be connected to a power supply node of a circuit, such as the peripheral circuit 740. In one embodiment, the first stabilization-capacitor electrode 120 may be electrically grounded through the peripheral bottom electrode contact via structure 795. In this embodiment, the memory-region upper metal line 792 may contact the peripheral bottom electrode contact via structure 795. In one embodiment, the voltage stabilization capacitor 160 may be configured to stabilize a voltage of the peripheral circuit 740. In one embodiment, the voltage stabilization capacitor 160 comprises an electrical node (which may, or may not, be a power supply node) that is not electrically shorted (i.e., not unintentionally electrically coupled) to any of the connection metal pads 781.

FIGS. 8B-8F are vertical cross-sectional views of alternative configurations of the first embodiment structure according to the first embodiment of the present disclosure.

Referring to FIG. 8B, a first alternative configuration of the first embodiment structure may be derived from the first embodiment structure of FIG. 8A by connecting the peripheral-region metal pad 782 directly to a lower-level metal interconnect structure 780 such as a metal via structure. In this embodiment, the connection via structure 797 may be formed directly on a top surface of the peripheral-region metal pad 782.

Referring to FIG. 8C, a second alternative configuration of the first embodiment structure may be derived from the first alternative configuration of the first embodiment structure of FIG. 8B by connecting each peripheral top electrode contact via structure 793 to a single peripheral-region metal line 794.

Referring to FIG. 8D, a third alternative configuration of the first embodiment structure may be derived from the second alternative configuration of the first embodiment structure of FIG. 8B by using a single peripheral top electrode contact via structure 793.

Referring to FIG. 8E, a fourth configuration of the first embodiment structure may be derived from the first embodiment structure of FIG. 8A by electrically grounding the second stabilization-capacitor electrode 140 through the peripheral top electrode contact via structures 793. In this embodiment, the memory-region upper metal line 792 may contact the peripheral top electrode contact via structure 793. In one embodiment, the voltage stabilization capacitor 160 may be configured to stabilize a voltage of the peripheral circuit 740. In one embodiment, the voltage stabilization capacitor 160 comprises a power supply node that is not directly connected to connection metal pads 781. For example, the first stabilization-capacitor electrode 120 may be electrically connected to the power supply node through a peripheral bottom electrode contact via structure 795, a peripheral region metal line 794, and a connection via structure 797.

Referring to FIG. 8F, a fifth alternative configuration of the first embodiment structure may be derived from the fourth alternative configuration of the first embodiment structure of FIG. 8E by connecting the peripheral-region metal pad 782 directly to a lower-level metal interconnect structure 780 such as a metal via structure. In this embodiment, the peripheral bottom electrode contact via structure 795 may be omitted.

Referring to FIG. 8G, a sixth alternative configuration of the first embodiment structure may be derived from any of the above configurations of the first embodiment structure by not electrically grounding any of the first stabilization-capacitor electrode 120 and the second stabilization-capacitor electrode 140. In this embodiment, both of the first stabilization-capacitor electrode 120 and the second stabilization-capacitor electrode 140 are not electrically coupled to any of the connection metal pads 781. In one embodiment, the second stabilization-capacitor electrode 140 may be electrically shorted to a power supply node though a peripheral bottom electrode contact via structure 795, a peripheral-region metal line 794, and a connection via structure 797.

Referring to FIG. 8H, a seventh alternative configuration of the first embodiment structure may be derived from any of the above configurations of the first embodiment structure by not electrically grounding any of the first stabilization-capacitor electrode 120 and the second stabilization-capacitor electrode 140. In this embodiment, both of the first stabilization-capacitor electrode 120 and the second stabilization-capacitor electrode 140 are not electrically coupled to any of the connection metal pads 781. In one embodiment, the first stabilization-capacitor electrode 120 and the peripheral-region metal pad 782 may be electrically shorted to a power supply node through a peripheral-region metal pad 782.

Referring collectively to FIGS. 8A-8H, the memory array may comprise an array of gain cell transistors, and the first electrodes (i.e., the first memory-capacitor electrodes 20) of the memory node capacitors 60 are electrically connected to a gate electrode of a respective one of the gain cell transistors through a respective subset of the lower-level metal interconnect structures 780.

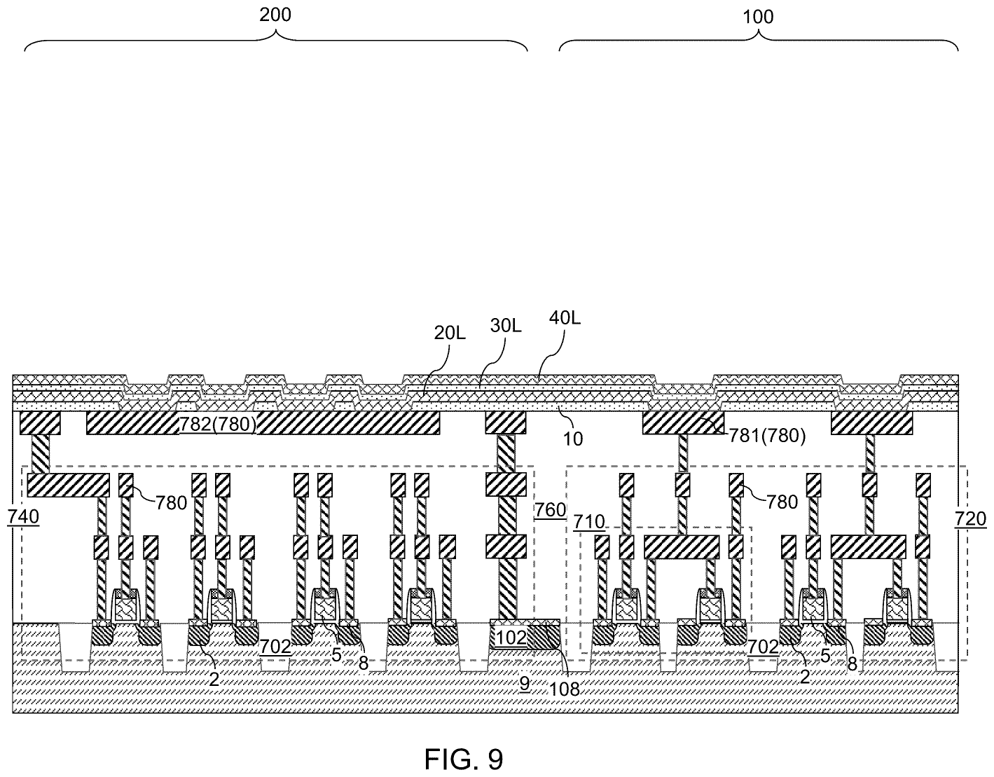

Referring to FIG. 9, a second embodiment structure is illustrated after deposition of a capacitor material layer stack (20L, 30L, 40L) including a first electrode material layer 20L, a node dielectric material layer 30L, and a second electrode material layer 40L over the dielectric capping layer 10. The second embodiment structure may be formed by performing the processing steps described with reference to FIGS. 1, 3, 4, and 5.

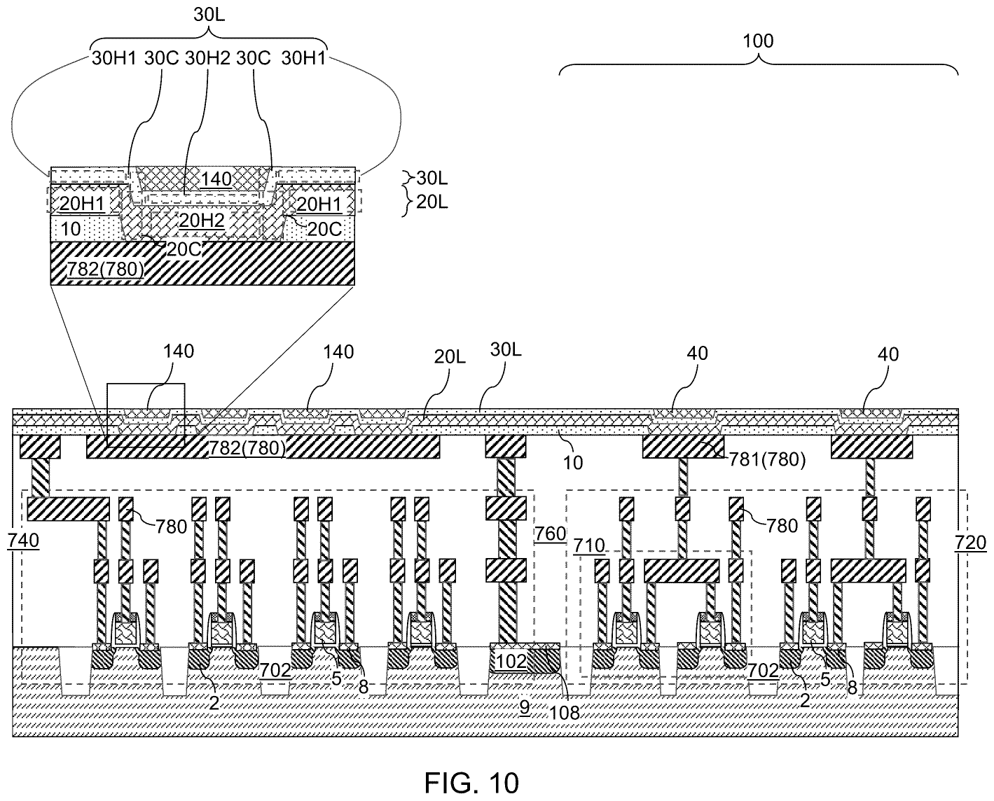

Referring to FIG. 10, a planarization process may be performed to remove portions of the second electrode material layer 40L that overlie a horizontal plane including the topmost surface of the node dielectric material layer 30L. For example, a chemical mechanical polishing (CMP) process may be performed to remove the portions of the second electrode material layer 40L that overlie a horizontal plane including the topmost surface of the node dielectric material layer 30L. Each discrete remaining portion of the second electrode material layer 40L that is formed over a respective memory-region opening 19 constitutes a second memory-capacitor electrode 40. Each second memory-capacitor electrode 40 may have a respective lateral extent that is less than, and is located entirely within, the lateral extent of a respective underlying memory-region opening 19 in the dielectric capping layer 10.

At least one remaining portion of the second electrode material layer 40L may be formed within the peripheral device region 200. Each remaining portion of the second electrode material layer 40L is herein referred to as a second stabilization-capacitor electrode 140. Each second stabilization-capacitor electrode 140 may have a respective lateral extent that is less than, and is located entirely within, the lateral extent of a respective underlying peripheral-region opening 29 in the dielectric capping layer 10. The second memory-capacitor electrodes 40 are top electrodes of an array of memory node capacitors to be subsequently formed, and each second stabilization-capacitor electrode 140 is a top electrode of a voltage stabilization capacitor to be subsequently formed. In one embodiment, all top surfaces of the second memory-capacitor electrodes 40 and the at least one second stabilization capacitor electrode 140 may be formed within the horizontal plane including the topmost planar surface of the node dielectric material layer 30L.

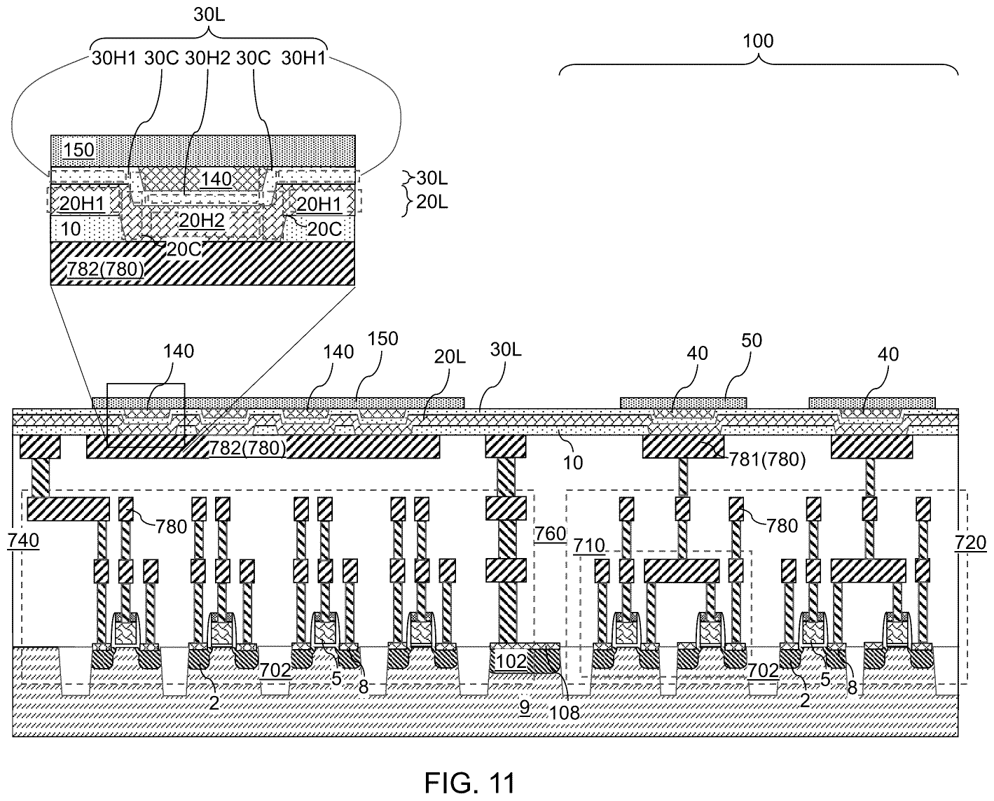

Referring to FIG. 11, a hard mask material layer may be formed over the node dielectric material layer 30L and the various second electrodes (40, 140) by performing the processing steps described with reference to FIG. 6. A photoresist layer (not shown) may be applied over the hard mask material layer, and may be lithographically patterned into a two-dimensional array of discrete photoresist material portions overlying the array of connection metal pads 781 and a photoresist material portion overlying the peripheral-region metal pad 782. A first anisotropic etch process may be performed to transfer the pattern in the patterned photoresist material portions through the hard mask material layer. Patterned portions of the hard mask material layer 50L include array hard mask plates 50 that are formed in the memory array region 100, and at least one peripheral hard mask plate 150 that is formed in the peripheral device region 200. Subsequently, the photoresist layer may be removed by ashing.

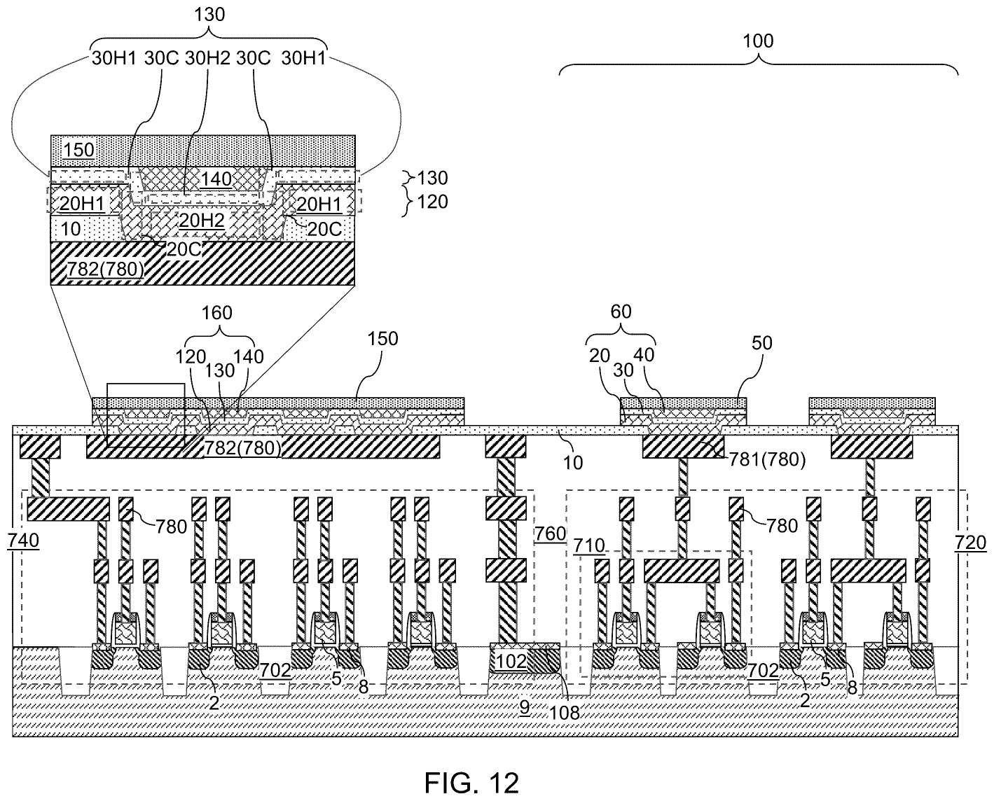

Referring to FIG. 12, a second anisotropic etch process may be performed to transfer the pattern in the array hard mask plates 50 and the at least one peripheral hard mask plate 150 through a capacitor material layer stack (20L, 30L, 40) that includes the first electrode material layer 20L, the node dielectric material layer 30L, and the various second electrodes (40, 140). In this embodiment, the combination of the array hard mask plates 50 and the at least one peripheral hard mask plate 150 may be used as an etch mask for etching the materials of the capacitor material layer stack (20L, 30L, 40). The second anisotropic etch process may have an etch chemistry that etches the materials of the node dielectric material layer 30L and the first electrode material layer 20L selectively to the material of the dielectric capping layer 10. The entirety of the second electrodes (40, 140) may be covered by the array hard mask plates 50 and the at least one peripheral hard mask plate 150 during the second anisotropic etch process. Thus, the second electrodes (40, 140) are not etched during the second anisotropic etch process.

Each sidewall of the second electrodes (40, 140) is laterally recessed inward from the periphery of a respective overlying one of the array hard mask plates 50 and the at least one peripheral hard mask plate 150. Each sidewall of the patterned portions of the node dielectric material layer 30L is vertically coincident with a sidewall of a respective one of the array hard mask plates 50 and the at least one peripheral hard mask plate 150. Each sidewall of the patterned portions of the first electrode material layer 20L may be vertically coincident with a sidewall of a respective one of the array hard mask plates 50 and the at least one peripheral hard mask plate 150.

Generally, the capacitor material layer stack (20L, 30L, 40) may be patterned by transferring the pattern in the array of array hard mask plates 50 and the at least one peripheral hard mask plate 150 at least through the node dielectric material layer 30L and the first electrode material layer 20L using an anisotropic etch process that etches materials of the capacitor material layer stack (20L, 30L, 40) selectively to a material of the dielectric capping layer 10. The patterned portions of the capacitor material layer stack (20L, 30L, 40) that remains in the memory array region 100 comprises an array of memory node capacitors 60. The patterned portion of the capacitor material layer stack (20L, 30L, 40) that remains in the peripheral device region 200 comprises a voltage stabilization capacitor 160. Thus, the capacitor material layer stack (20L, 30L, 40) may be patterned into an array of memory node capacitors 60 and a voltage stabilization capacitor 160.

Each memory node capacitor 60 comprises a vertical stack of a first memory-capacitor electrode 20, a memory-capacitor node dielectric 30, and a second memory-capacitor electrode 40. Each first memory-capacitor electrode 20 is a patterned portion of the first electrode material layer 20L. Each memory-capacitor node dielectric 30 is a patterned portion of the node dielectric material layer 30L. Each second memory-capacitor electrode 40 is a patterned portion of the second electrode material layer 40L. The voltage stabilization capacitor 160 comprises a vertical stack of a first stabilization-capacitor electrode 120, a stabilization-capacitor node dielectric 130, and a second stabilization-capacitor electrode 140. The first stabilization-capacitor electrode is a patterned portion of the first electrode material layer 20L. The stabilization-capacitor node dielectric 130 is a patterned portion of the node dielectric material layer 30L. The second stabilization-capacitor electrode 140 is a patterned portion of the second electrode material layer 40L.

According to an aspect of the present disclosure, each of the memory node capacitors 60 is a charge storage capacitor for a respective memory cell of the memory array. The sidewalls of the first memory-capacitor electrode 20 and the memory-capacitor node dielectric 30 within each memory node capacitor 60 may be vertically coincident with one another, i.e., located within the same vertical planes. Further, the sidewalls of the first memory-capacitor electrode 20 and the memory-capacitor node dielectric 30 within each memory node capacitor 60 may be vertically coincident with sidewalls of a respective overlying array hard mask plate 50. In one embodiment, the sidewalls of first memory-capacitor electrode 20 and the memory-capacitor node dielectric 30 within each memory node capacitor 60 may be located entirely outside the area defined by sidewalls of a respective underlying connection metal pad 781 in a plan view, i.e., in a view along the vertical direction. In other words, the areal extent of each connection metal pad 781 may be contained entirely within the areal extent of a respective overlying first memory-capacitor electrode 20 in a plan view such that the periphery of the respective metal pad 781 is laterally offset inward relative to the periphery of the respective overlying first memory-capacitor electrode 20.

In one embodiment, the sidewalls of second memory-capacitor electrode 40 within each memory node capacitor 60 may be located entirely inside the area defined by sidewalls of the respective underlying connection metal pad 781 in the plan view. In other words, the areal extent of each second memory-capacitor electrode 40 may be contained entirely within the areal extent of a respective underlying connection metal pad 781 in a plan view such that the periphery of the respective metal pad 781 is laterally offset outward relative to the periphery of the respective overlying second memory-capacitor electrode 40. Generally, each of the memory node capacitors 60 comprises a first memory-capacitor electrode 20 electrically connected with a respective one of the connection metal pads 781.

The peripheral-region metal pad 782 may be electrically coupled to the first stabilization-capacitor electrode 120 upon formation of the first stabilization-capacitor electrode 120. In one embodiment, each of the first stabilization-capacitor electrode 120 and the stabilization-capacitor node dielectric 130 may be formed with a respective contoured top surface including a respective set of at least one vertically recessed surface segment that overlies the at least one peripheral-region opening 29 in the dielectric capping layer 10.

The second embodiment structure comprises an array of memory node capacitors 60 overlying lower-level dielectric material layers 760 that overlie the transistors. The lower-level metal interconnect structures 780 may be formed within the lower-level dielectric material layers 760, and comprise an array of connection metal pads 781 electrically connected to a respective one of the transistors and electrically connected to a first electrode (i.e., the first memory-capacitor electrode 20) of a respective one of the memory node capacitors 60. The voltage stabilization capacitor 160 may be located over the lower-level dielectric material layers 760, and may be configured to stabilize a voltage of the peripheral circuit 740. The dielectric capping layer 10 overlies the array of connection metal pads 781 and comprises an array of memory-region openings 19 through which electrical connections are provided between the first electrodes (i.e., the first memory-capacitor electrodes 20) and the array of connection metal pads 781 and further comprises at least one peripheral-region opening 29 that underlies or laterally surrounds a first stabilization-capacitor electrode 120.

In one embodiment, the first memory-capacitor electrode 20 of each of the memory node capacitors 60 comprises a first horizontally-extending portion 20H1 that overlies the dielectric capping layer 10, and a downward-protruding portion that is adjoined to an inner periphery of the first horizontally-extending portion 20H1 and protrudes downward relative to the first horizontally-extending portion 20H1 and fills a respective one of the memory-region openings 19. Each memory-capacitor node dielectric 30 may have a vertical undulation in a vertical cross-sectional profile, and may comprise a first horizontally-extending portion 30H1 having an areal overlap with the dielectric capping layer 10 in a plan view, a second horizontally-extending portion 30H2 within an area of one of the memory-region openings 19, and a tubular connecting portion 30C connecting a periphery of the second horizontally-extending portion 30H2 to a periphery of an opening in the first horizontally-extending portion 30H1.

In one embodiment, each of the memory node capacitors 60 comprises a node dielectric (such as a memory-capacitor node dielectric 30) contacting a top surface of a first electrode (i.e., a first memory-capacitor electrode 20), and a second electrode (i.e., a second stabilization-capacitor electrode 140) having a top surface located within a horizontal plane including a top surface of the node dielectric (such as the memory-capacitor node dielectric 30). In one embodiment, each of the memory node capacitors 60 comprises a node dielectric (such as a memory-capacitor node dielectric 30) having sidewalls, and is contacted by a bottom surface of an array hard mask plate 50 having sidewalls that are vertically coincident with the sidewalls of the node dielectric (such as a memory-capacitor node dielectric 30).

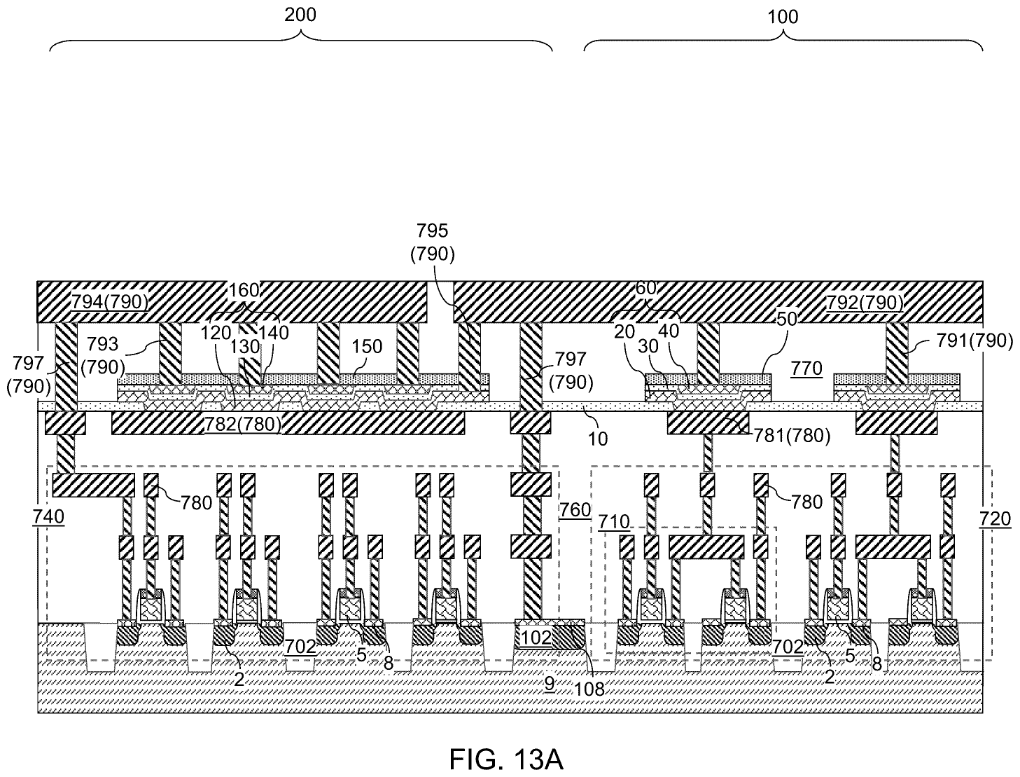

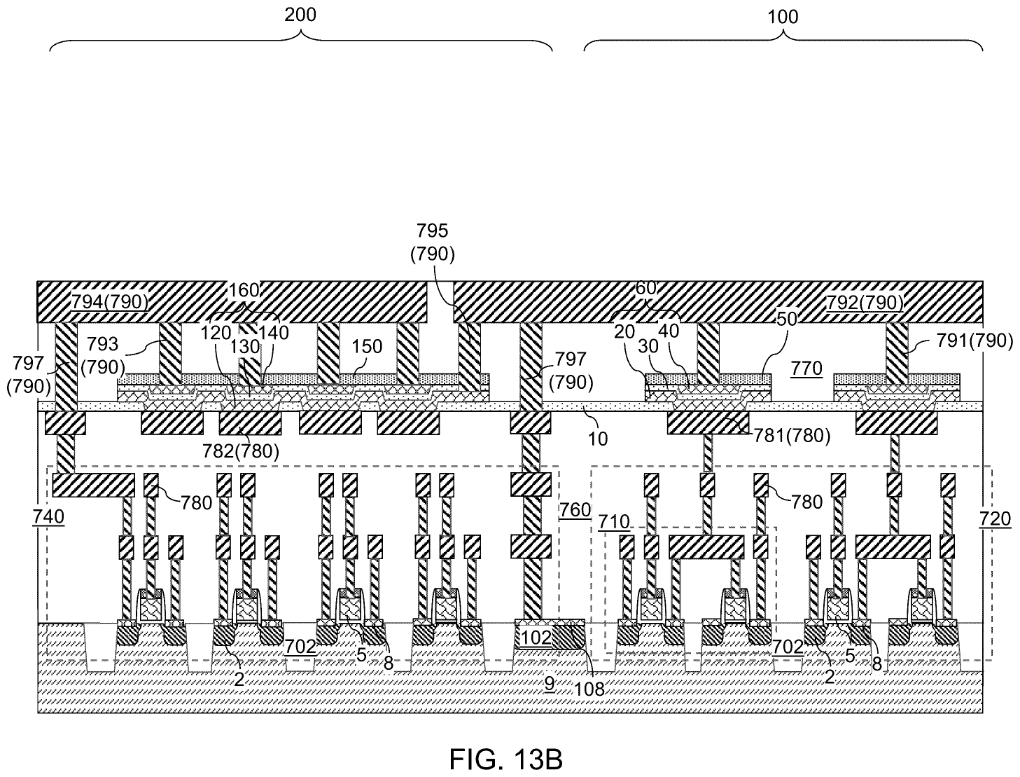

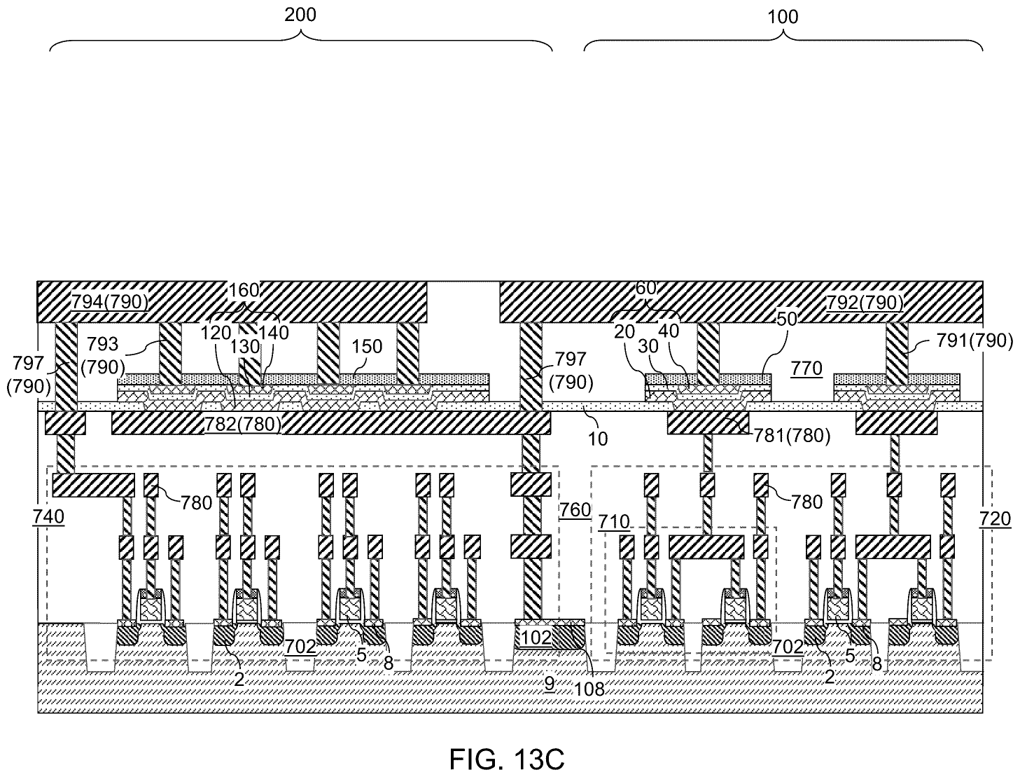

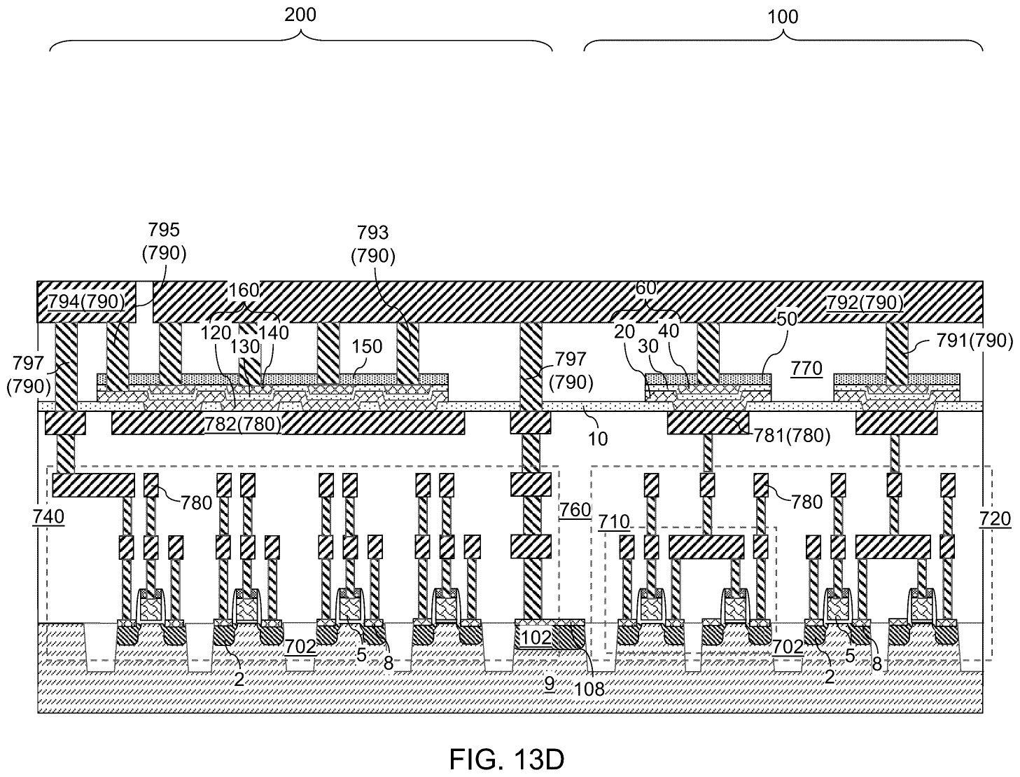

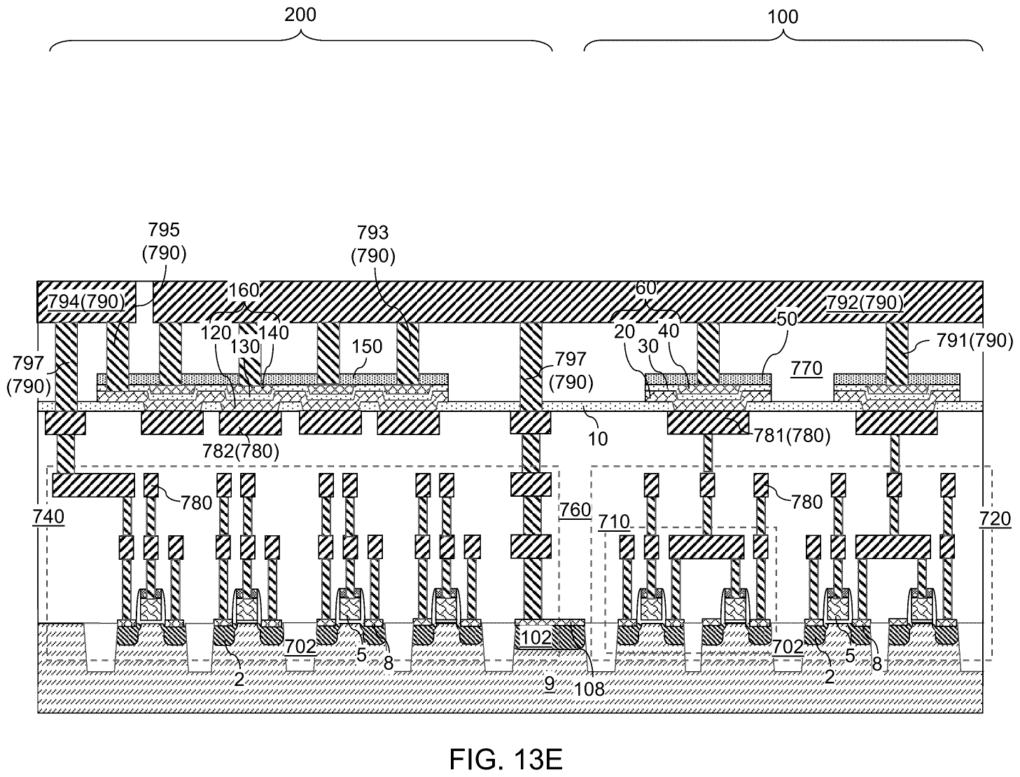

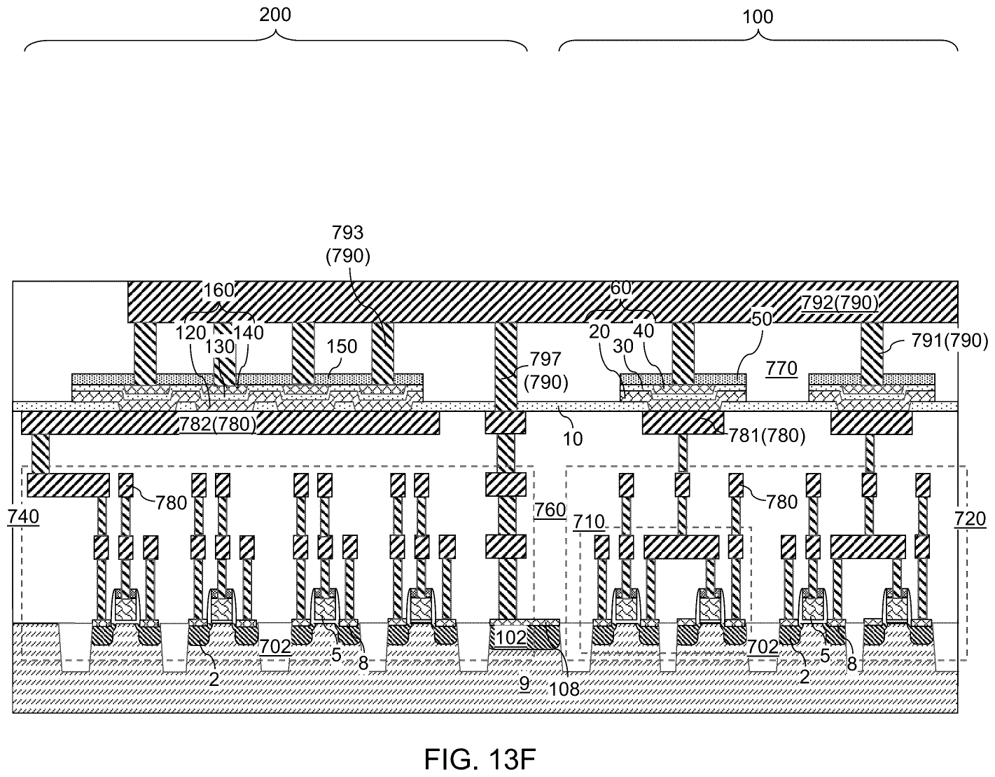

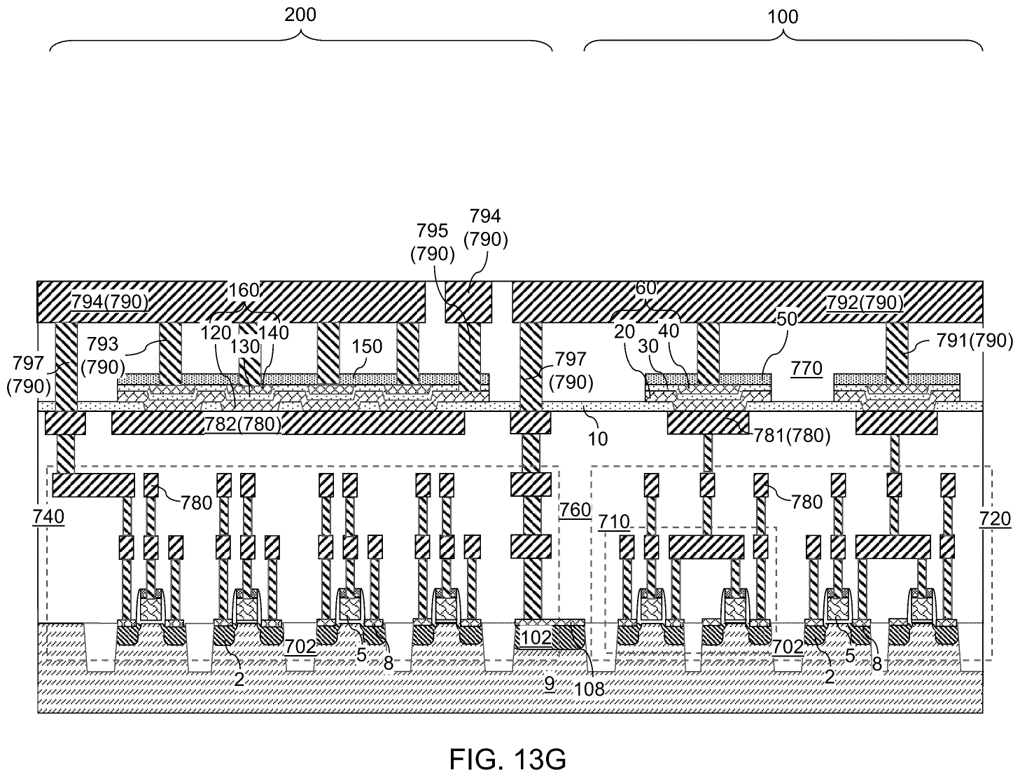

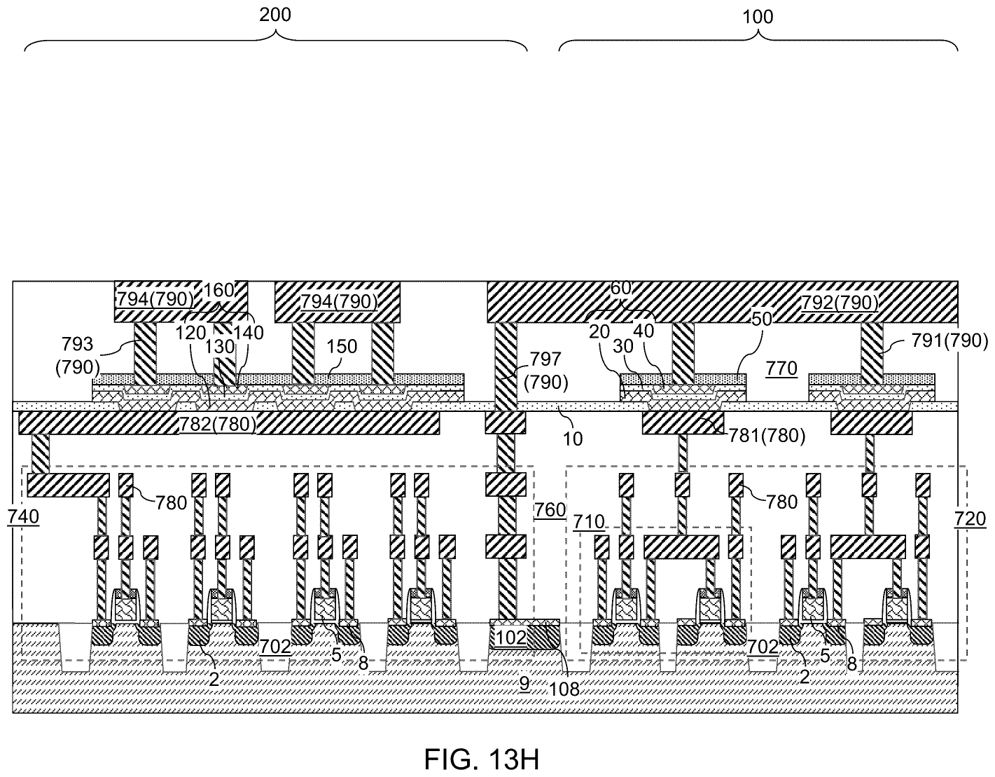

Referring to FIG. 13A, an upper-level dielectric material layer 770 and upper-level metal interconnect structures 790 may be formed to provide electrical connection to and from the second memory-capacitor electrode 40, the second stabilization-capacitor electrode 140, and the lower-level metal interconnect structures 780. The upper-level metal interconnect structures 790 may comprise array electrode contact via structures 791 that contact a respective one of the second memory-capacitor electrodes 40, at least one peripheral top electrode contact via structure 793 that contacts the second stabilization-capacitor electrodes 140, a peripheral bottom electrode contact via structure 795 that contacts the first stabilization-capacitor electrode 120, and connection via structures 797 that contact a respective metal line or a respective metal pad that may be formed within the lower-level dielectric material layers 760. Further, the upper-level metal interconnect structures 790 may comprise a memory-region upper metal line 792 that contacts a plurality of the array electrode contact via structures 791, and at least one peripheral-region metal line 794 that contacts a respective subset of the peripheral top electrode contact via structures 793. The peripheral bottom electrode contact via structure 795 vertically extends through a portion of the stabilization-capacitor node dielectric 130 that does not underlie any second stabilization-capacitor electrode 140.

In one embodiment, the memory-region upper metal line 792 may contact a connection via structure 797 that is electrically connected to an electrical ground node, which may comprise a doped semiconductor well 102 and the semiconductor substrate 9. In some embodiments, one of the first stabilization-capacitor electrode 120 and the second stabilization-capacitor electrode 140 may be electrically grounded, and another of the stabilization-capacitor electrode 120 and the second stabilization-capacitor electrode 140 may be connected to a power supply node of a circuit, such as the peripheral circuit 740. In one embodiment, the first stabilization-capacitor electrode 120 may be electrically grounded through the peripheral bottom electrode contact via structure 795. In this embodiment, the memory-region upper metal line 792 may contact the peripheral bottom electrode contact via structure 795. In one embodiment, the voltage stabilization capacitor 160 may be configured to stabilize a voltage of the peripheral circuit 740. In one embodiment, the voltage stabilization capacitor 160 comprises an electrical node (which may, or may not, be a power supply node) that is not electrically coupled to any of the connection metal pads 781.

FIGS. 13B-13H are vertical cross-sectional views of alternative configurations of the second embodiment structure according to the second embodiment of the present disclosure.

Referring to FIG. 13B, a first alternative configuration of the second embodiment structure may be derived from the second embodiment structure of FIG. 13A by forming at least one hole (such as an array of holes) through the peripheral-region metal pad 782, or by forming a plurality of peripheral-region metal pads 782 (such as a two-dimensional array of peripheral-region metal pads 782) in lieu of a single peripheral-region metal pad 782.

Referring to FIG. 13C, a second alternative configuration of the second embodiment structure may be derived from the second embodiment structure of FIG. 13A by connecting the peripheral-region metal pad 782 directly to a lower-level metal interconnect structure 780 such as a metal via structure. In this embodiment, the connection via structure 797 may be formed directly on a top surface of the peripheral-region metal pad 782.

Referring to FIG. 13D, a third alternative configuration of the second embodiment structure may be derived from the second embodiment structure of FIG. 13B by electrically grounding the second stabilization-capacitor electrode 140 through the peripheral top electrode contact via structures 793. In this embodiment, the memory-region upper metal line 792 may contact the peripheral top electrode contact via structure 793. In one embodiment, the voltage stabilization capacitor 160 may be configured to stabilize a voltage of the peripheral circuit 740. In one embodiment, the voltage stabilization capacitor 160 comprises a power supply node that is not directly connected to connection metal pads 781. For example, the first stabilization-capacitor electrode 120 may be electrically connected to the power supply node through a peripheral bottom electrode contact via structure 795, a peripheral region metal line 794, and a connection via structure 797.

Referring to FIG. 13E, a fourth configuration of the second embodiment structure may be derived from the second embodiment structure of FIG. 13A by forming at least one hole (such as an array of holes) through the peripheral-region metal pad 782, or by forming a plurality of peripheral-region metal pads 782 (such as a two-dimensional array of peripheral-region metal pads 782) in lieu of a single peripheral-region metal pad 782.

Referring to FIG. 13F, a fifth alternative configuration of the second embodiment structure may be derived from the fourth alternative configuration of the second embodiment structure of FIG. 13E by connecting the peripheral-region metal pad 782 directly to a lower-level metal interconnect structure 780 such as a metal via structure. In this embodiment, the peripheral bottom electrode contact via structure 795 may be omitted.

Referring to FIG. 13G, a sixth alternative configuration of the second embodiment structure may be derived from any of the above configurations of the second embodiment structure by not electrically grounding any of the first stabilization-capacitor electrode 120 and the second stabilization-capacitor electrode 140. In this embodiment, both of the first stabilization-capacitor electrode 120 and the second stabilization-capacitor electrode 140 are not electrically coupled to any of the connection metal pads 781. In one embodiment, the second stabilization-capacitor electrode 140 may be electrically shorted to a power supply node though a peripheral bottom electrode contact via structure 795, a peripheral-region metal line 794, and a connection via structure 797.

Referring to FIG. 13H, a seventh alternative configuration of the second embodiment structure may be derived from any of the above configurations of the second embodiment structure by not electrically grounding any of the first stabilization-capacitor electrode 120 and the second stabilization-capacitor electrode 140. In this embodiment, both of the first stabilization-capacitor electrode 120 and the second stabilization-capacitor electrode 140 are not electrically coupled to any of the connection metal pads 781. In one embodiment, the first stabilization-capacitor electrode 120 and the peripheral-region metal pad 782 may be electrically shorted to a power supply node through a peripheral-region metal pad 782.

Referring collectively to FIGS. 13A-13H, the memory array may comprise an array of gain cell transistors, and the first electrodes (i.e., the first memory-capacitor electrodes 20) of the memory node capacitors 60 are electrically connected to a gate electrode of a respective one of the gain cell transistors through a respective subset of the lower-level metal interconnect structures 780.

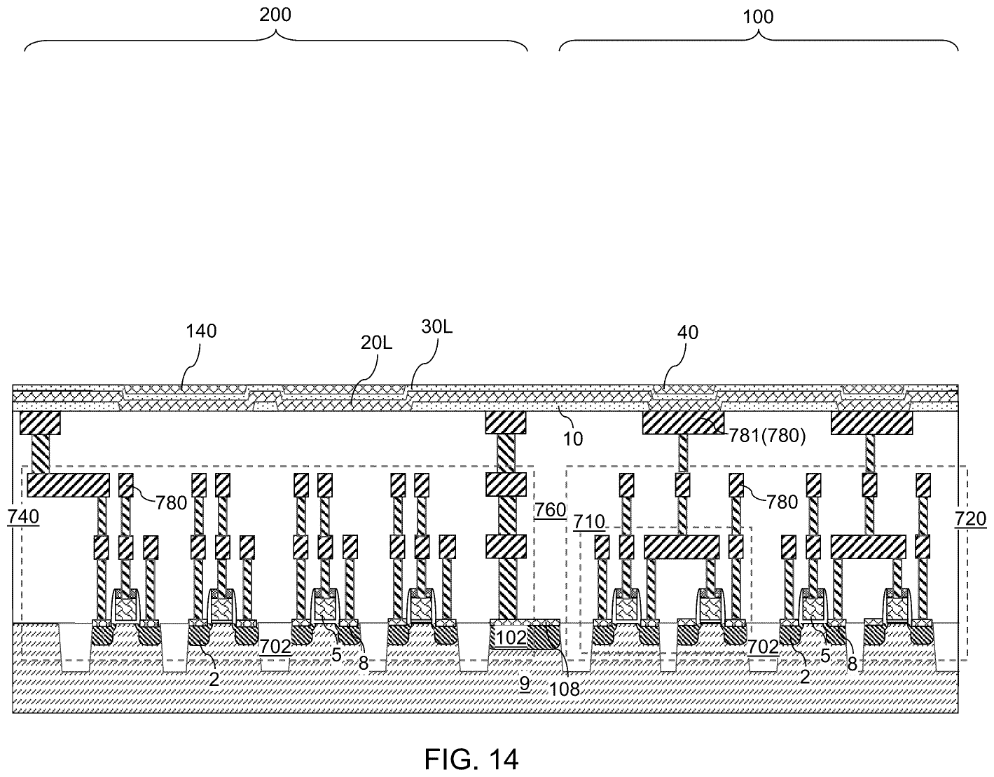

Referring to FIG. 14, a third embodiment structure according to the third embodiment of the present disclosure is illustrated, which may be derived from the second embodiment structure illustrated in FIG. 10 by omitting formation of the peripheral-region metal pad(s) 782. In this embodiment, each portion of the first electrode material layer 20L that is located within the at least one peripheral-region opening 29 may contact a dielectric surface of the lower-level dielectric material layers 760. The total number of the at least one second stabilization-capacitor electrode 140 and the areal extent of each second stabilization-capacitor electrode 140 may be selected to minimize the dishing of the at least one second stabilization-capacitor electrode 140 during the chemical mechanical polishing process that patterns the at least one second stabilization-capacitor electrode 140.

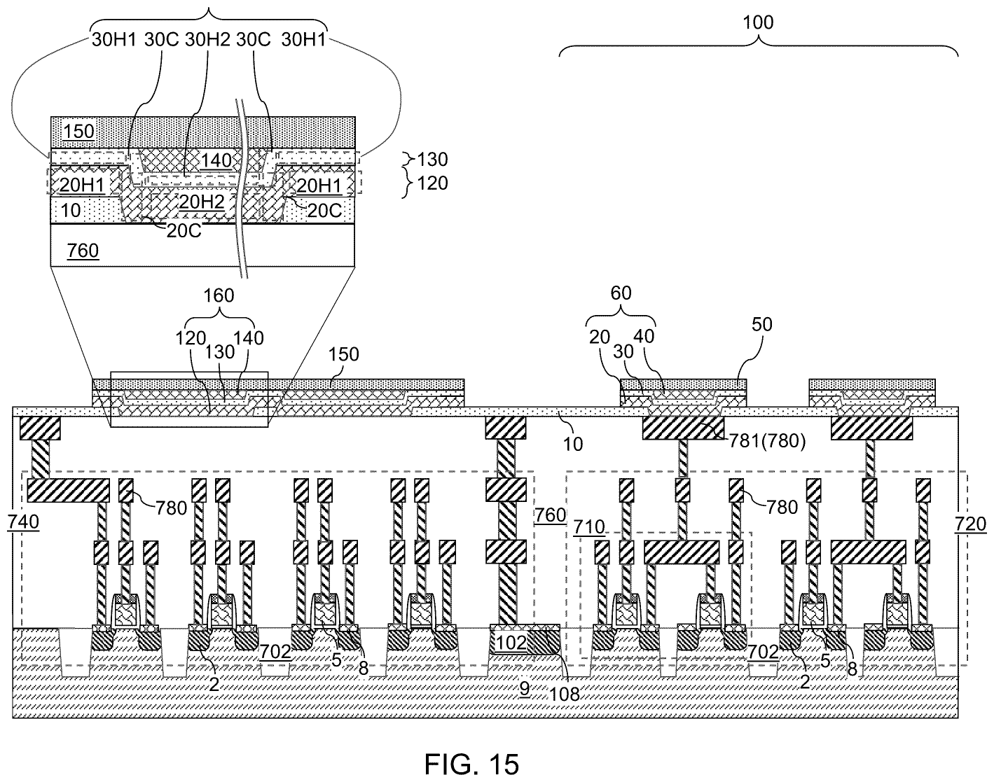

Referring to FIG. 15, the processing steps described with reference to FIG. 11 may be performed to form array hard mask plates 50 and at least one peripheral hard mask plate 150. Subsequently, a second anisotropic etch process may be performed to transfer the pattern in the array hard mask plates 50 and the at least one peripheral hard mask plate 150 through a capacitor material layer stack (20L, 30L, 40) that includes the first electrode material layer 20L, the node dielectric material layer 30L, and the various second electrodes (40, 140). In this embodiment, the combination of the array hard mask plates 50 and the at least one peripheral hard mask plate 150 may be used as an etch mask for etching the materials of the capacitor material layer stack (20L, 30L, 40). The second anisotropic etch process may have an etch chemistry that etches the materials of the node dielectric material layer 30L and the first electrode material layer 20L selectively to the material of the dielectric capping layer 10. The entirety of the second electrodes (40, 140) may be covered by the array hard mask plates 50 and the at least one peripheral hard mask plate 150 during the second anisotropic etch process. Thus, the second electrodes (40, 140) are not etched during the second anisotropic etch process.

Each sidewall of the second electrodes (40, 140) is laterally recessed inward from the periphery of a respective overlying one of the array hard mask plates 50 and the at least one peripheral hard mask plate 150. Each sidewall of the patterned portions of the node dielectric material layer 30L is vertically coincident with a sidewall of a respective one of the array hard mask plates 50 and the at least one peripheral hard mask plate 150. Each sidewall of the patterned portions of the first electrode material layer 20L is vertically coincident with a sidewall of a respective one of the array hard mask plates 50 and the at least one peripheral hard mask plate 150.

Generally, the capacitor material layer stack (20L, 30L, 40) may be patterned by transferring the pattern in the array of array hard mask plates 50 and the at least one peripheral hard mask plate 150 at least through the node dielectric material layer 30L and the first electrode material layer 20L using an anisotropic etch process that etches materials of the capacitor material layer stack (20L, 30L, 40) selectively to a material of the dielectric capping layer 10. The patterned portions of the capacitor material layer stack (20L, 30L, 40) that remains in the memory array region 100 comprises an array of memory node capacitors 60. The patterned portion of the capacitor material layer stack (20L, 30L, 40) that remains in the peripheral device region 200 comprises a voltage stabilization capacitor 160. Thus, the capacitor material layer stack (20L, 30L, 40) may be patterned into an array of memory node capacitors 60 and a voltage stabilization capacitor 160.

Each memory node capacitor 60 comprises a vertical stack of a first memory-capacitor electrode 20, a memory-capacitor node dielectric 30, and a second memory-capacitor electrode 40. Each first memory-capacitor electrode 20 is a patterned portion of the first electrode material layer 20L. Each memory-capacitor node dielectric 30 is a patterned portion of the node dielectric material layer 30L. Each second memory-capacitor electrode 40 is a patterned portion of the second electrode material layer 40L. The voltage stabilization capacitor 160 comprises a vertical stack of a first stabilization-capacitor electrode 120, a stabilization-capacitor node dielectric 130, and a second stabilization-capacitor electrode 140. The first stabilization-capacitor electrode is a patterned portion of the first electrode material layer 20L. The stabilization-capacitor node dielectric 130 is a patterned portion of the node dielectric material layer 30L. The second stabilization-capacitor electrode 140 is a patterned portion of the second electrode material layer 40L.

According to an aspect of the present disclosure, each of the memory node capacitors 60 is a charge storage capacitor for a respective memory cell of the memory array. The sidewalls of the first memory-capacitor electrode 20 and the memory-capacitor node dielectric 30 within each memory node capacitor 60 may be vertically coincident with one another, i.e., located within the same vertical planes. Further, the sidewalls of the first memory-capacitor electrode 20 and the memory-capacitor node dielectric 30 within each memory node capacitor 60 may be vertically coincident with sidewalls of a respective overlying array hard mask plate 50. In one embodiment, the sidewalls of first memory-capacitor electrode 20 and the memory-capacitor node dielectric 30 within each memory node capacitor 60 may be located entirely outside the area defined by sidewalls of a respective underlying connection metal pad 781 in a plan view, i.e., in a view along the vertical direction. In other words, the areal extent of each connection metal pad 781 may be contained entirely within the areal extent of a respective overlying first memory-capacitor electrode 20 in a plan view such that the periphery of the respective metal pad 781 is laterally offset inward relative to the periphery of the respective overlying first memory-capacitor electrode 20.

In one embodiment, the sidewalls of second memory-capacitor electrode 40 within each memory node capacitor 60 may be located entirely inside the area defined by sidewalls of the respective underlying connection metal pad 781 in the plan view. In other words, the areal extent of each second memory-capacitor electrode 40 may be contained entirely within the areal extent of a respective underlying connection metal pad 781 in a plan view such that the periphery of the respective metal pad 781 is laterally offset outward relative to the periphery of the respective overlying second memory-capacitor electrode 40. Generally, each of the memory node capacitors 60 comprises a first memory-capacitor electrode 20 electrically connected with a respective one of the connection metal pads 781.

The peripheral-region metal pad 782 is electrically shorted to the first stabilization-capacitor electrode 120 upon formation of the first stabilization-capacitor electrode 120. In one embodiment, each of the first stabilization-capacitor electrode 120 and the stabilization-capacitor node dielectric 130 may be formed with a respective contoured top surface including a respective set of at least one vertically recessed surface segment that overlies the at least one peripheral-region opening 29 in the dielectric capping layer 10.

The third embodiment structure comprises an array of memory node capacitors 60 overlying lower-level dielectric material layers 760 that overlie the transistors. The lower-level metal interconnect structures 780 may be formed within the lower-level dielectric material layers 760, and comprise an array of connection metal pads 781 electrically connected to a respective one of the transistors and electrically connected to a first electrode (i.e., the first memory-capacitor electrode 20) of a respective one of the memory node capacitors 60. The voltage stabilization capacitor 160 may be located over the lower-level dielectric material layers 760, and may be configured to stabilize a voltage of the peripheral circuit 740. The dielectric capping layer 10 overlies the array of connection metal pads 781 and comprises an array of memory-region openings 19 through which electrical connections are provided between the first electrodes (i.e., the first memory-capacitor electrodes 20) and the array of connection metal pads 781 and further comprises at least one peripheral-region opening 29 that underlies or laterally surrounds a first stabilization-capacitor electrode 120.

In one embodiment, the first memory-capacitor electrode 20 of each of the memory node capacitors 60 comprises a first horizontally-extending portion that 20H1 overlies the dielectric capping layer 10, and a downward-protruding portion that is adjoined to an inner periphery of the first horizontally-extending portion 20H1 and protrudes downward relative to the first horizontally-extending portion 20H1 and fills a respective one of the memory-region openings 19. Each memory-capacitor node dielectric 30 may have a vertical undulation in a vertical cross-sectional profile, and may comprise a first horizontally-extending portion 30H1 having an areal overlap with the dielectric capping layer 10 in a plan view, a second horizontally-extending portion 30H2 within an area of one of the memory-region openings 19, and a tubular connecting portion 30C connecting a periphery of the second horizontally-extending portion 30H2 to a periphery of an opening in the first horizontally-extending portion 30H1.

In one embodiment, each of the memory node capacitors 60 comprises a node dielectric (such as a memory-capacitor node dielectric 30) contacting a top surface of a first electrode (i.e., a first memory-capacitor electrode 20), and a second electrode (i.e., a second stabilization-capacitor electrode 140) having a top surface located within a horizontal plane including a top surface of the node dielectric (such as the memory-capacitor node dielectric 30). In one embodiment, each of the memory node capacitors 60 comprises a node dielectric (such as a memory-capacitor node dielectric 30) having sidewalls, and is contacted by a bottom surface of an array hard mask plate 50 having sidewalls that are vertically coincident with the sidewalls of the node dielectric (such as a memory-capacitor node dielectric 30).

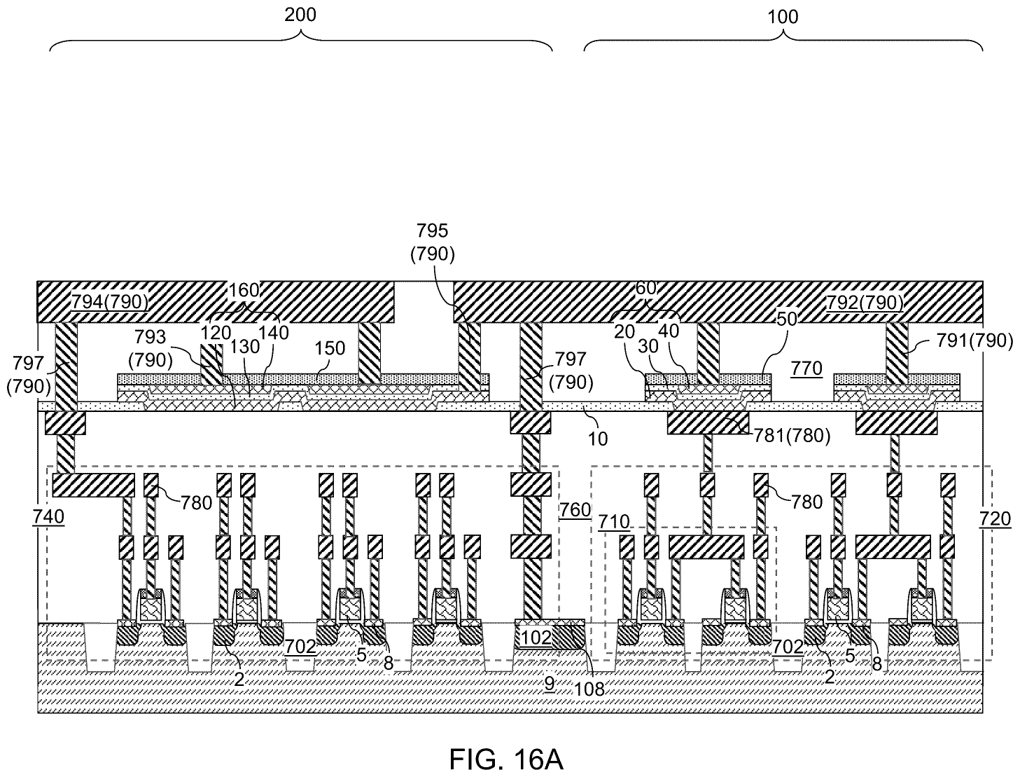

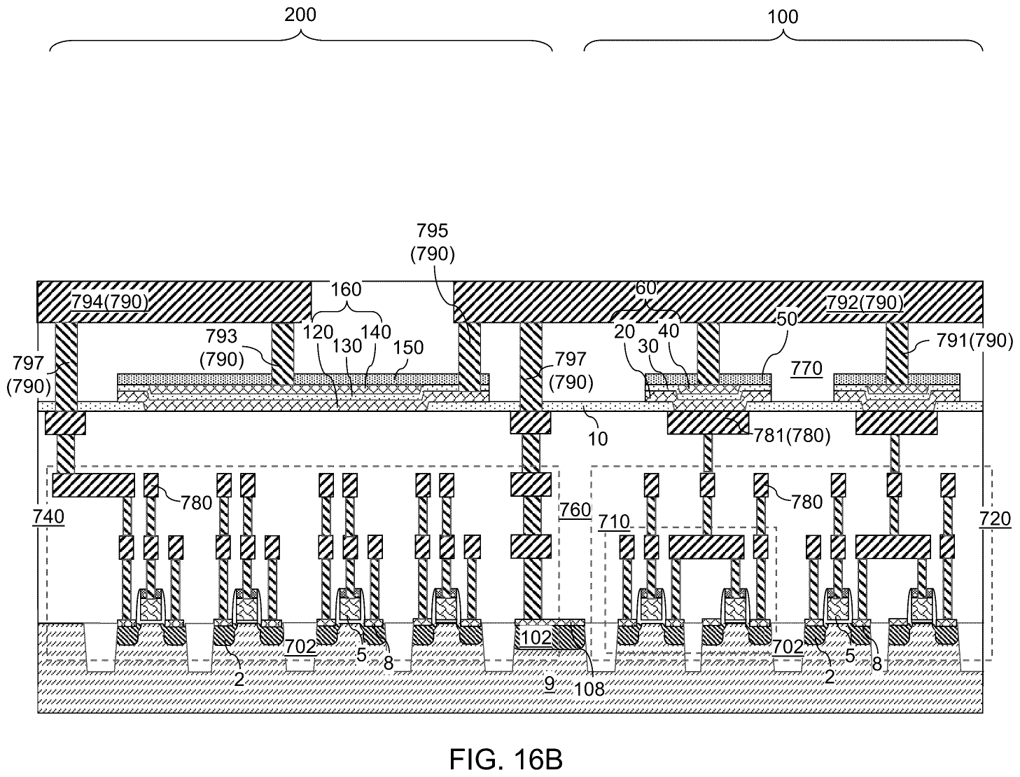

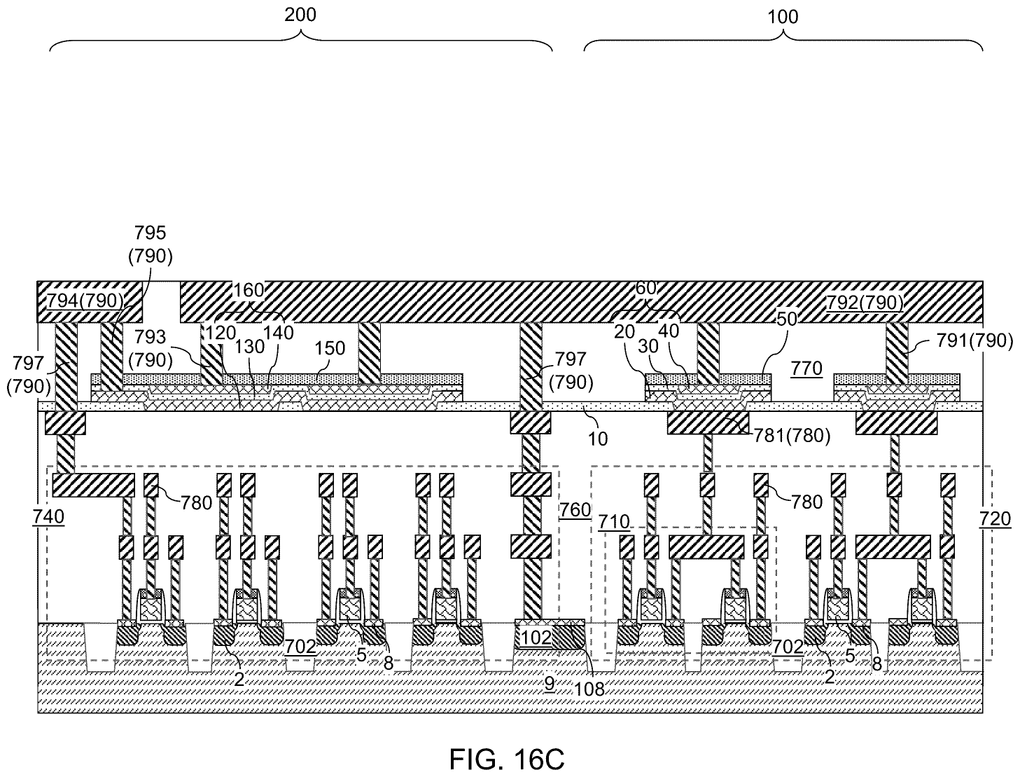

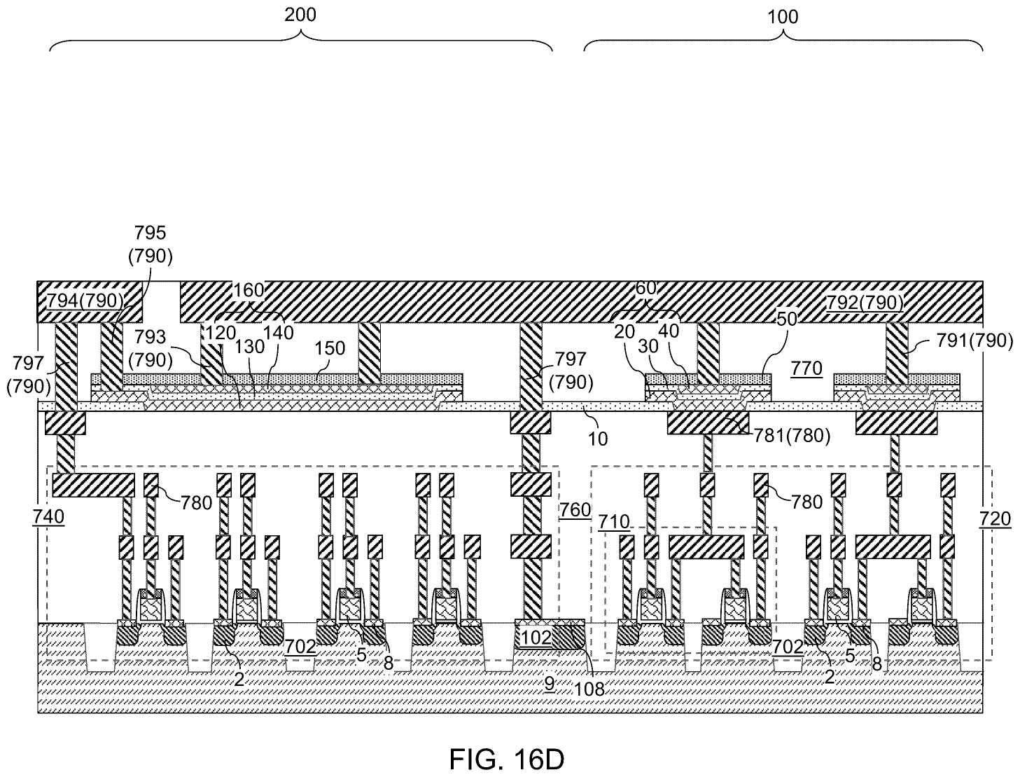

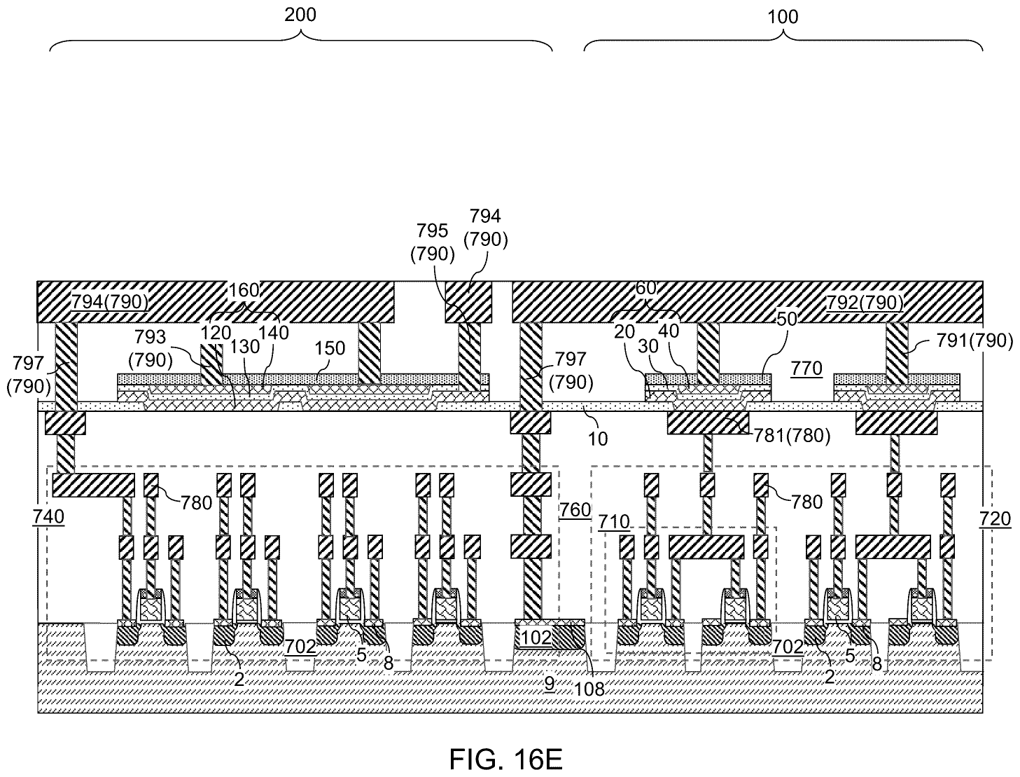

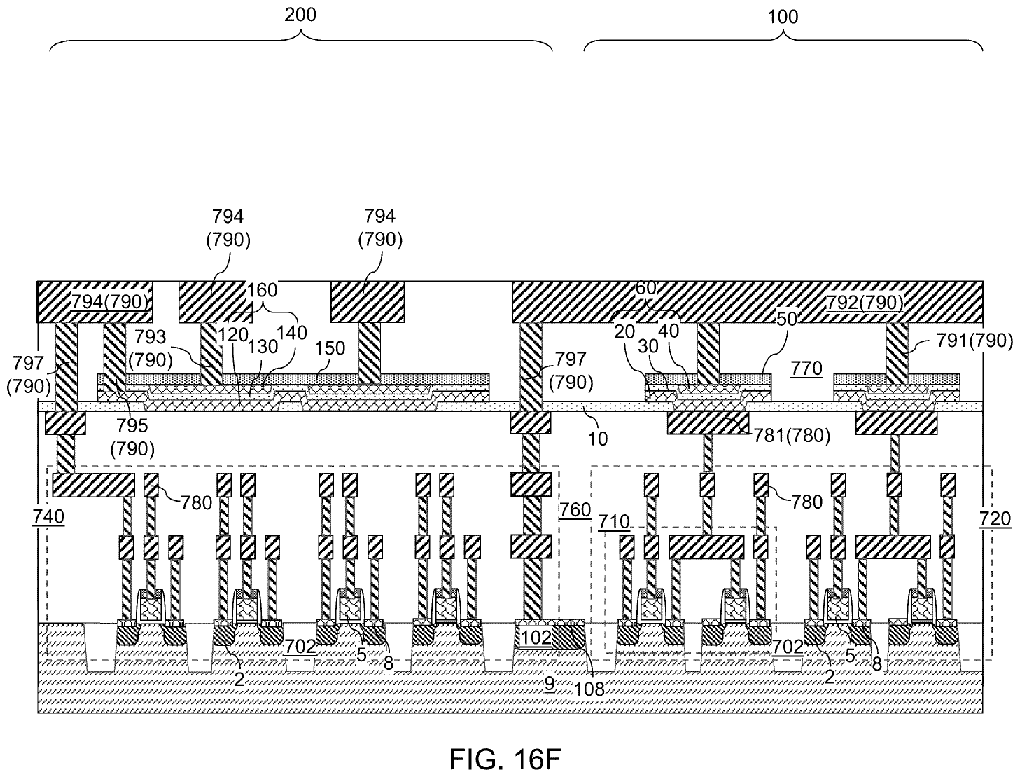

Referring to FIG. 16A, an upper-level dielectric material layer 770 and upper-level metal interconnect structures 790 may be formed to provide electrical connection to and from the second memory-capacitor electrode 40, the second stabilization-capacitor electrode 140, and the lower-level metal interconnect structures 780. The upper-level metal interconnect structures 790 may comprise array electrode contact via structures 791 that contact a respective one of the second memory-capacitor electrodes 40, at least one peripheral top electrode contact via structure 793 that contacts the second stabilization-capacitor electrodes 140, a peripheral bottom electrode contact via structure 795 that contacts the first stabilization-capacitor electrode 120, and connection via structures 797 that contact a respective metal line or a respective metal pad that may be formed within the lower-level dielectric material layers 760. Further, the upper-level metal interconnect structures 790 may comprise a memory-region upper metal line 792 that contacts a plurality of the array electrode contact via structures 791, and at least one peripheral-region metal line 794 that contacts a respective subset of the peripheral top electrode contact via structures 793. The peripheral bottom electrode contact via structure 795 vertically extends through a portion of the stabilization-capacitor node dielectric 130 that does not underlie any second stabilization-capacitor electrode 140.

In one embodiment, the memory-region upper metal line 792 may contact a connection via structure 797 that is electrically connected to an electrical ground node, which may comprise a doped semiconductor well 102 and the semiconductor substrate 9. In some embodiments, one of the first stabilization-capacitor electrode 120 and the second stabilization-capacitor electrode 140 may be electrically grounded, and another of the stabilization-capacitor electrode 120 and the second stabilization-capacitor electrode 140 may be connected to a power supply node of a circuit, such as the peripheral circuit 740. In one embodiment, the first stabilization-capacitor electrode 120 may be electrically grounded through the peripheral bottom electrode contact via structure 795. In this embodiment, the memory-region upper metal line 792 may contact the peripheral bottom electrode contact via structure 795. In one embodiment, the voltage stabilization capacitor 160 may be configured to stabilize a voltage of the peripheral circuit 740. In one embodiment, the voltage stabilization capacitor 160 comprises an electrical node (which may, or may not, be a power supply node) that is not electrically shorted to any of the connection metal pads 781.

FIGS. 16B-16F are vertical cross-sectional views of alternative configurations of the third embodiment structure according to the third embodiment of the present disclosure.

Referring to FIG. 16B, a first alternative configuration of the third embodiment structure may be derived from the third embodiment structure of FIG. 13A by forming a single peripheral top electrode contact via structure 793 in lieu of a plurality of peripheral top electrode contact via structures 793.

Referring to FIG. 16C, a second alternative configuration of the third embodiment structure may be derived from the third embodiment structure of FIG. 16A by electrically grounding the second stabilization-capacitor electrode 140 through the peripheral top electrode contact via structures 793. In this embodiment, the memory-region upper metal line 792 may contact the peripheral top electrode contact via structure 793. In one embodiment, the voltage stabilization capacitor 160 may be configured to stabilize a voltage of the peripheral circuit 740. In one embodiment, the voltage stabilization capacitor 160 comprises a power supply node that is not directly connected to connection metal pads 781. For example, the first stabilization-capacitor electrode 120 may be electrically connected to the power supply node through a peripheral bottom electrode contact via structure 795, a peripheral region metal line 794, and a connection via structure 797.

Referring to FIG. 16D, a third alternative configuration of the third embodiment structure may be derived from the second configuration of the third embodiment structure of FIG. 16C by forming a single peripheral-region opening 29 in lieu of a plurality of peripheral-region openings 29. In this embodiment, the first stabilization-capacitor electrode 120 may comprise a single recessed region that is formed within the single peripheral-region opening 29.

Referring to FIG. 16E, a fourth alternative configuration of the third embodiment structure may be derived from any of the above configurations of the third embodiment structure by not electrically grounding any of the first stabilization-capacitor electrode 120 and the second stabilization-capacitor electrode 140. In this embodiment, both of the first stabilization-capacitor electrode 120 and the second stabilization-capacitor electrode 140 are not electrically shorted to any of the connection metal pads 781. In one embodiment, the second stabilization-capacitor electrode 140 may be electrically shorted to a power supply node.

Referring to FIG. 16F, a fifth alternative configuration of the third embodiment structure may be derived from any of the above configurations of the third embodiment structure by not electrically grounding any of the first stabilization-capacitor electrode 120 and the second stabilization-capacitor electrode 140. In this embodiment, both of the first stabilization-capacitor electrode 120 and the second stabilization-capacitor electrode 140 are not electrically shorted to any of the connection metal pads 781. In one embodiment, the first stabilization-capacitor electrode 120 may be electrically shorted to a power supply node though a peripheral bottom electrode contact via structure 795, a peripheral-region metal line 794, and a connection via structure 797.

Referring collectively to FIGS. 16A-16F, the memory array may comprise an array of gain cell transistors, and the first electrodes (i.e., the first memory-capacitor electrodes 20) of the memory node capacitors 60 are electrically connected to a gate electrode of a respective one of the gain cell transistors through a respective subset of the lower-level metal interconnect structures 780.

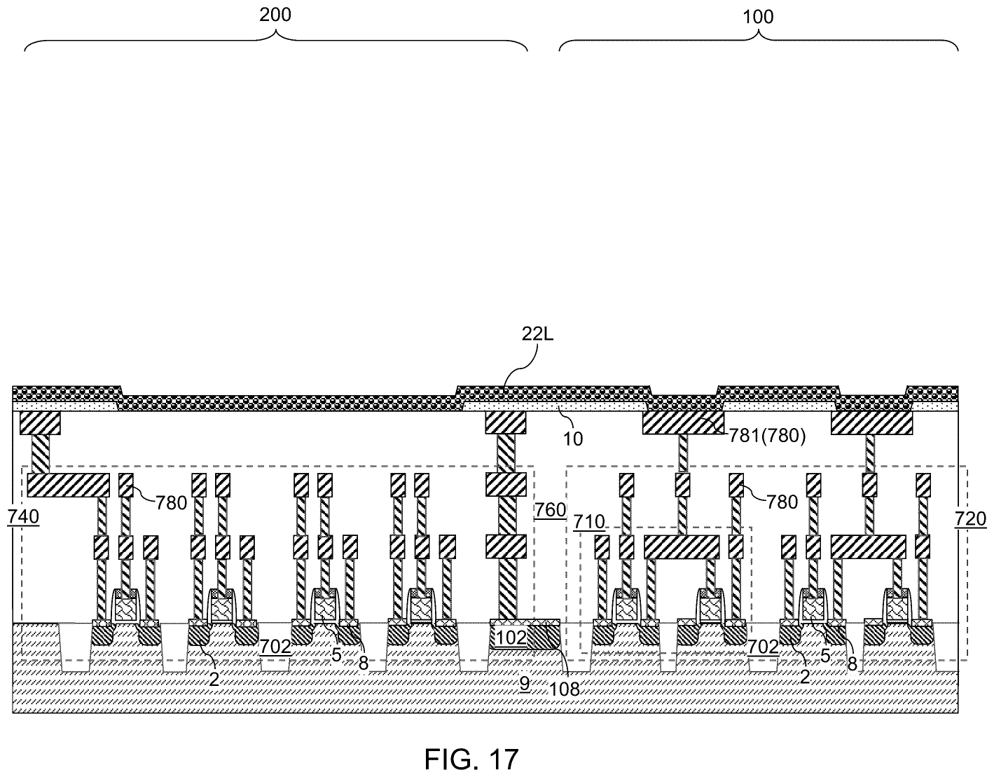

Referring to FIG. 17, a fourth embodiment structure according to a fourth embodiment of the present disclosure may be derived from the first embodiment structure illustrated in FIG. 4 by removing the photoresist layer 17, and by depositing a metallic fill material layer 22L. The metallic fill material layer 22L may be deposited in the array of memory-region openings 19, in the at least one peripheral-region opening 29, and over the dielectric capping layer 10. The metallic fill material layer 22L may comprise, and/or may consist essentially of, a conductive metallic nitride material (such as TiN, TaN, WN, or MoN) or a refractory metal (such as W, Mo, Ta, Nb, or Re) having a melting point higher than 2,000 degrees Celsius and providing sufficient resistance to metal diffusion and/or contamination for surrounding dielectric materials. The metallic fill material layer 22L may be deposited by physical vapor deposition or chemical vapor deposition. The thickness of the first electrode material layer 20L may be in a range from 10 nm to 100 nm, such as from 20 nm to 40 nm, although lesser and greater thicknesses may also be used.

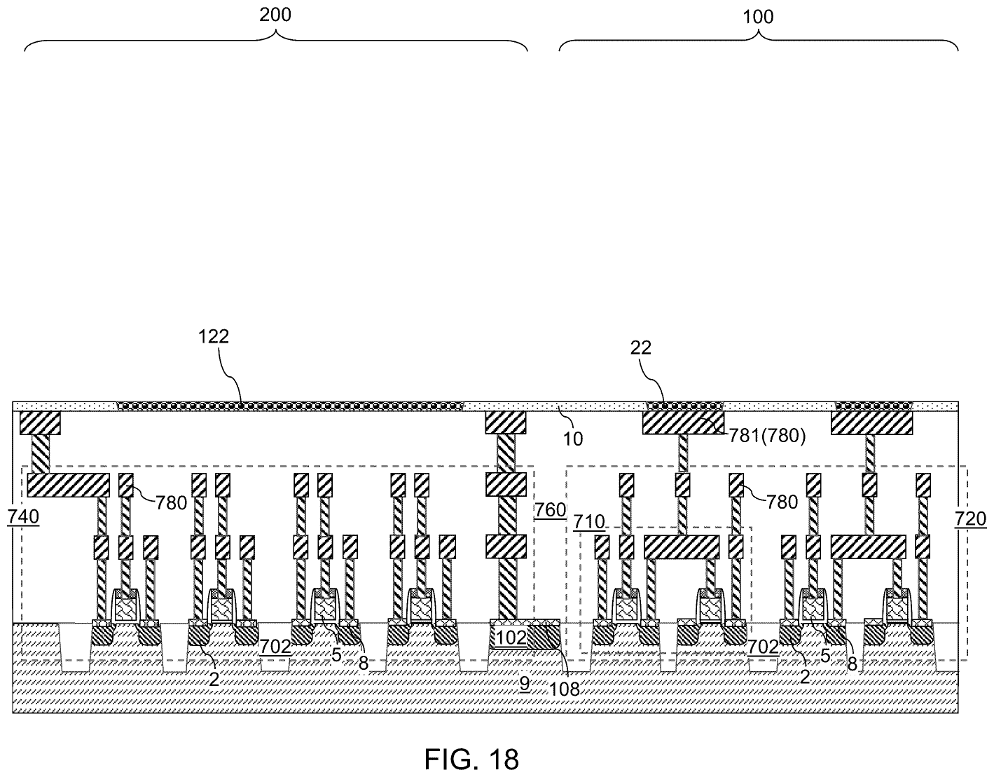

Referring to FIG. 18, a planarization process may be performed to remove portions of the metallic fill material layer 22L from above a horizontal plane including the top surface of the dielectric capping layer 10. For example, a chemical mechanical polishing process may be performed to remove the metallic material of the metallic fill material layer 22L from above the horizontal plane including the top surface of the dielectric capping layer 10. The dielectric capping layer 10 may be used as a planarization stopper layer during the chemical mechanical polishing process. Remaining portions of the metallic fill material layer 22L comprise an array of memory damascene pads 22 that fills the array of memory-region openings 19 and at least one peripheral damascene pad 122 that fills the at least one peripheral-region opening 29. The array of memory damascene pads 22 is formed in the array of memory-region openings 19, and the at least one peripheral damascene pad 122 is formed in the at least one peripheral-region opening 29. The top surfaces of the memory damascene pads 22 and the at least one peripheral damascene pad 122 may be formed within the horizontal plane including the top surface of the dielectric capping layer wherein the first electrode material layer 20L is formed on the array of memory damascene pads 22 and on the at least one peripheral damascene pad 122.

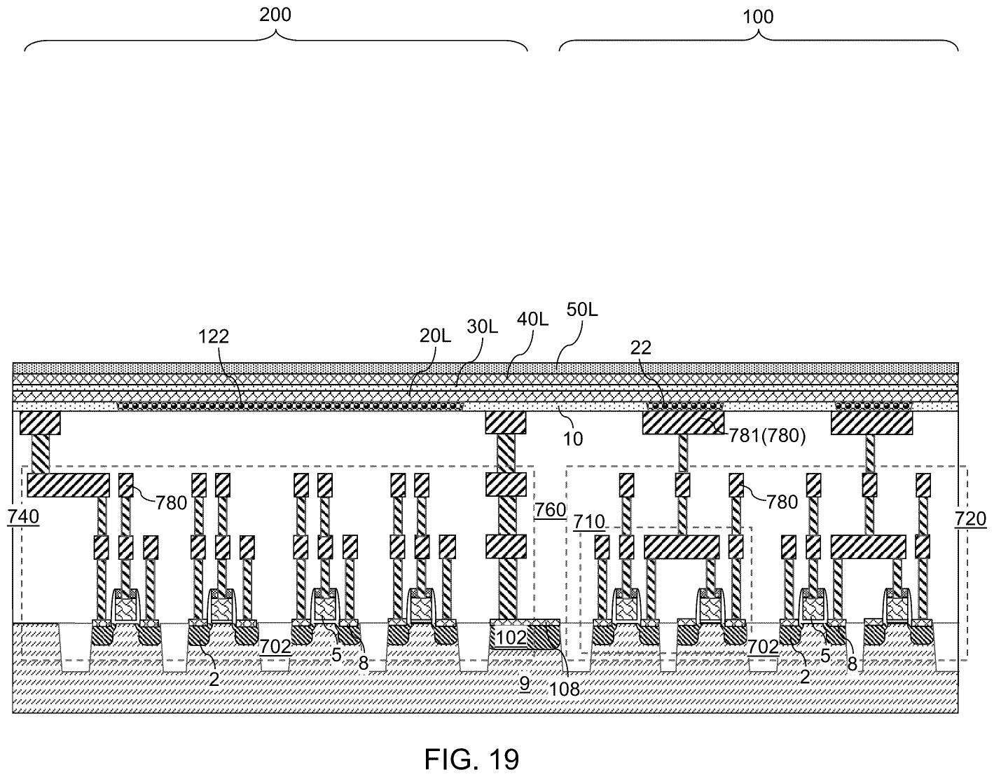

Referring to FIG. 19, the processing steps described with reference to FIG. 5 may be performed to form a capacitor material layer stack (20L, 30L, 40L) including a first electrode material layer 20L, a node dielectric material layer 30L, and a second electrode material layer 40L over the dielectric capping layer 10. The first electrode material layer 20L may be deposited directly on the top surfaces of the memory damascene pads 22 and the at least one peripheral damascene pad 122. Subsequently, the processing steps described with reference to FIG. 6 may be performed to form a hard mask material layer 50L.

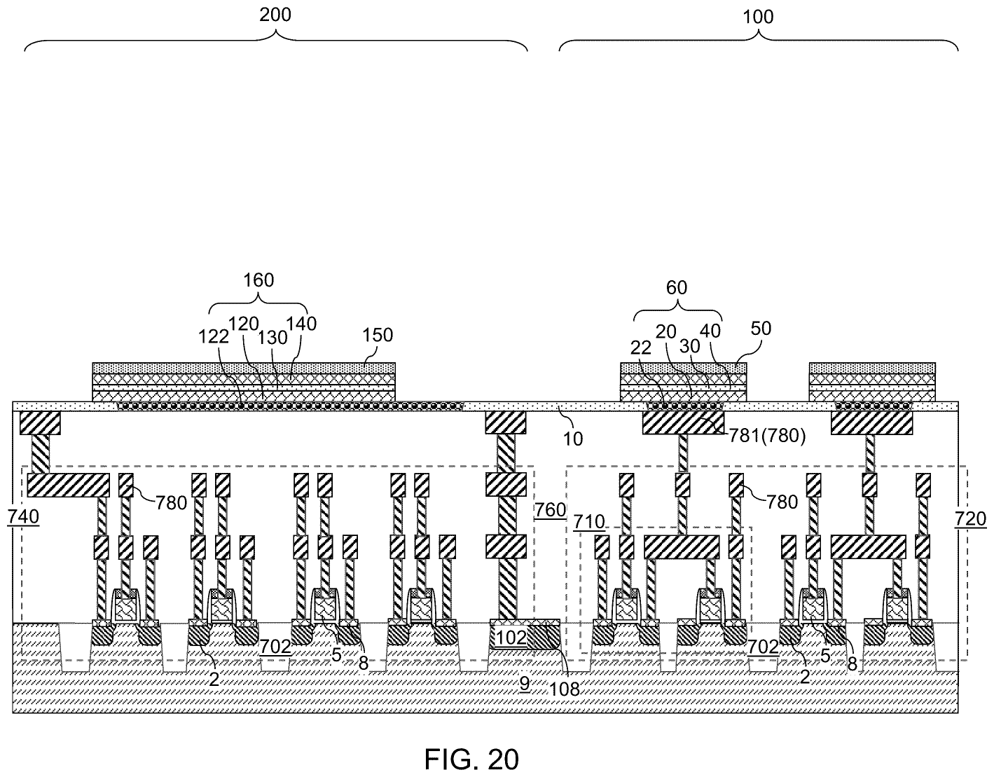

Referring to FIG. 20, a photoresist layer (not shown) may be applied over the hard mask material layer 50L, and may be lithographically patterned into a two-dimensional array of discrete photoresist material portions overlying the array of memory damascene pads 22 and a photoresist material portion overlying the at least one peripheral damascene pad 122. A first anisotropic etch process may be performed to transfer the pattern in the patterned photoresist material portions through the hard mask material layer 50L. Patterned portions of the hard mask material layer 50L include array hard mask plates 50 that are formed in the memory array region 100, and at least one peripheral hard mask plate 150 that is formed in the peripheral device region 200. Subsequently, the photoresist layer may be removed by ashing.

A second anisotropic etch process may be performed to transfer the pattern in the array hard mask plates 50 and the at least one peripheral hard mask plate 150 through the capacitor material layer stack (20L, 30L, 40L). In this embodiment, the combination of the array hard mask plates 50 and the at least one peripheral hard mask plate 150 may be used as an etch mask for etching the materials of the capacitor material layer stack (20L, 30L, 40L). The second anisotropic etch process may have an etch chemistry that is selective to the material of the dielectric capping layer 10. In an alternative embodiment, removal of the photoresist layer that is used as an etch mask for patterning the hard mask material layer 50L may be performed after the second anisotropic etch process.

Each sidewall of the patterned portions of the second electrode material layer 40L is vertically coincident with a sidewall of a respective one of the array hard mask plates 50 and the at least one peripheral hard mask plate 150. Each sidewall of the patterned portions of the node dielectric material layer 30L is vertically coincident with a sidewall of a respective one of the array hard mask plates 50 and the at least one peripheral hard mask plate 150. Each sidewall of the patterned portions of the first electrode material layer 20L is vertically coincident with a sidewall of a respective one of the array hard mask plates 50 and the at least one peripheral hard mask plate 150.

Generally, the capacitor material layer stack (20L, 30L, 40L) may be patterned by transferring the pattern in the array of array hard mask plates 50 and the at least one peripheral hard mask plate 150 at least through the node dielectric material layer 30L and the first electrode material layer 20L using an anisotropic etch process that etches materials of the capacitor material layer stack (20L, 30L, 40L) selectively to a material of the dielectric capping layer 10. The patterned portions of the capacitor material layer stack (20L, 30L, 40L) that remains in the memory array region 100 comprises an array of memory node capacitors 60. The patterned portion of the capacitor material layer stack (20L, 30L, 40L) that remains in the peripheral device region 200 comprises a voltage stabilization capacitor 160. Thus, the capacitor material layer stack (20L, 30L, 40L) may be patterned into an array of memory node capacitors 60 and a voltage stabilization capacitor 160.

Each memory node capacitor 60 comprises a vertical stack of a first memory-capacitor electrode 20, a memory-capacitor node dielectric 30, and a second memory-capacitor electrode 40. Each first memory-capacitor electrode 20 is a patterned portion of the first electrode material layer 20L. Each memory-capacitor node dielectric 30 is a patterned portion of the node dielectric material layer 30L. Each second memory-capacitor electrode 40 is a patterned portion of the second electrode material layer 40L. The voltage stabilization capacitor 160 comprises a vertical stack of a first stabilization-capacitor electrode 120, a stabilization-capacitor node dielectric 130, and a second stabilization-capacitor electrode 140. The first stabilization-capacitor electrode is a patterned portion of the first electrode material layer 20L. The stabilization-capacitor node dielectric 130 is a patterned portion of the node dielectric material layer 30L. The second stabilization-capacitor electrode 140 is a patterned portion of the second electrode material layer 40L.

According to an aspect of the present disclosure, each of the memory node capacitors 60 is a charge storage capacitor for a respective memory cell of the memory array. The sidewalls of the first memory-capacitor electrode 20, the memory-capacitor node dielectric 30, and the second memory-capacitor electrode 40 within each memory node capacitor 60 may be vertically coincident with one another, i.e., located within the same vertical planes. Further, the sidewalls of the first memory-capacitor electrode 20, the memory-capacitor node dielectric 30, and the second memory-capacitor electrode 40 within each memory node capacitor 60 may be vertically coincident with sidewalls of a respective overlying array hard mask plate 50. In one embodiment, the sidewalls of first memory-capacitor electrode 20, the memory-capacitor node dielectric 30, and the second memory-capacitor electrode 40 within each memory node capacitor 60 may be located entirely outside the area defined by sidewalls of a respective underlying memory damascene pad 22 in a plan view, i.e., in a view along the vertical direction. In other words, the areal extent of each memory damascene pad 22 may be contained entirely within the areal extent of a respective overlying memory node capacitor 60 in a plan view such that the periphery of the respective metal pad 781 is laterally offset inward relative to the periphery of the respective overlying memory node capacitor 60.

Generally, each of the memory node capacitors 60 comprises a first memory-capacitor electrode 20 electrically connected with a respective one of the memory damascene pads 22. In one embodiment, each second memory-capacitor electrode 40 may be formed with a contoured top surface having a vertically recessed surface segment that overlies a respective memory-region openings 19.

The at least one peripheral damascene pad 122 is electrically shorted to the first stabilization-capacitor electrode 120 upon formation of the first stabilization-capacitor electrode 120. In one embodiment, each of the first stabilization-capacitor electrode 120, the stabilization-capacitor node dielectric 130, and the second stabilization-capacitor electrode 140 may be formed with a respective contoured top surface including a respective set of at least one vertically recessed surface segment that overlies the at least one peripheral-region opening 29 in the dielectric capping layer 10.

The first embodiment structure comprises an array of memory node capacitors 60 overlying lower-level dielectric material layers 760 that overlie the transistors. The lower-level metal interconnect structures 780 may be formed within the lower-level dielectric material layers 760, and comprise an array of memory damascene pads 22 electrically connected to a respective one of the transistors and electrically connected to a first electrode (i.e., the first memory-capacitor electrode 20) of a respective one of the memory node capacitors 60. The voltage stabilization capacitor 160 may be located over the lower-level dielectric material layers 760, and may be configured to stabilize a voltage of the peripheral circuit 740. The dielectric capping layer 10 having formed therein the array of memory damascene pads 22 which fills an array of memory-region openings 19 and further has formed therein at least one peripheral damascene pad 122 which fills the at least one peripheral-region opening 29. Each memory damascene pad 22 underlies, and is electrically shorted to, a first electrode (i.e., the first memory-capacitor electrodes 20) of a memory node capacitor 60. Each peripheral damascene pad 122 underlies, and is electrically shorted to, a first electrode (i.e., the first stabilization-capacitor electrode 120) of the voltage stabilization capacitor 160.

In one embodiment, the entirety of the first memory-capacitor electrode 20 of each of the memory node capacitors 60 may have a uniform thickness throughout between a top surface and a bottom surface. The entirety of the memory-capacitor node dielectric 30 of each of the memory node capacitors 60 may have a uniform thickness throughout between a top surface and a bottom surface. The entirety of the second memory-capacitor electrode 40 of each of the memory node capacitors 60 may have a uniform thickness throughout between a top surface and a bottom surface.

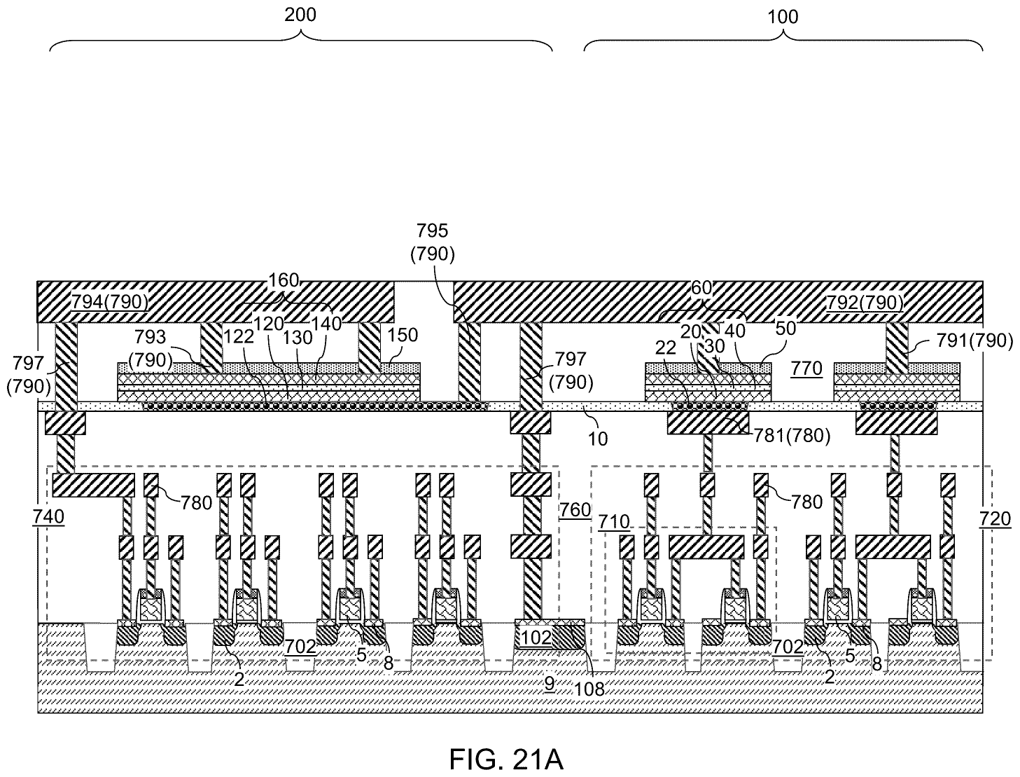

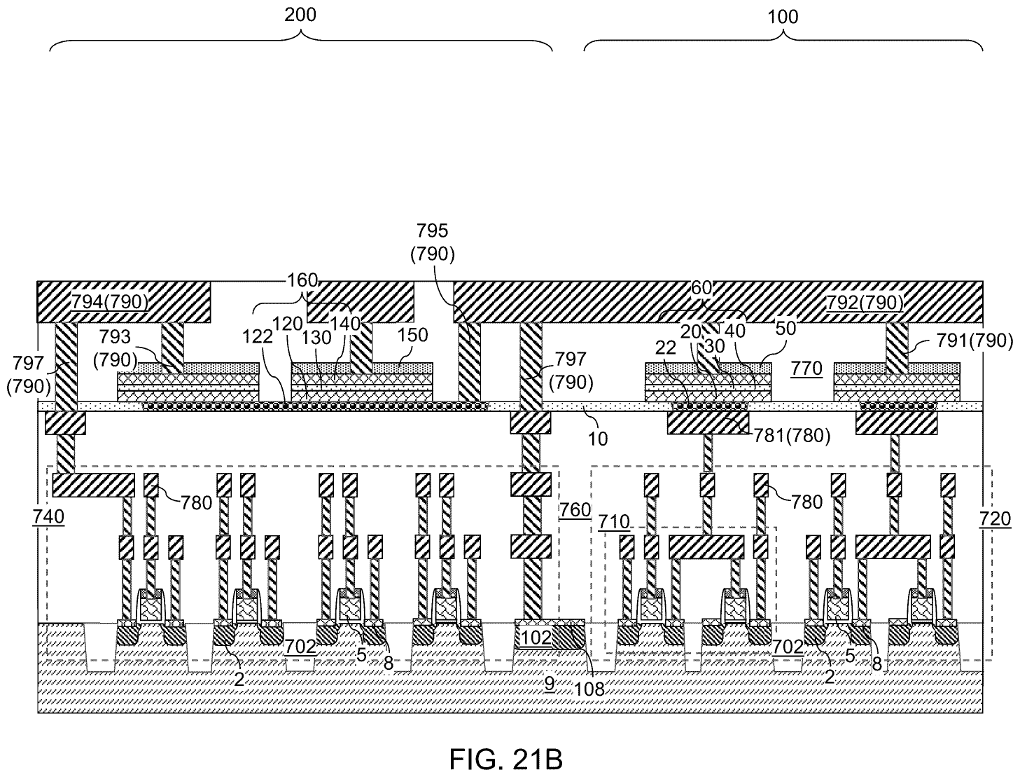

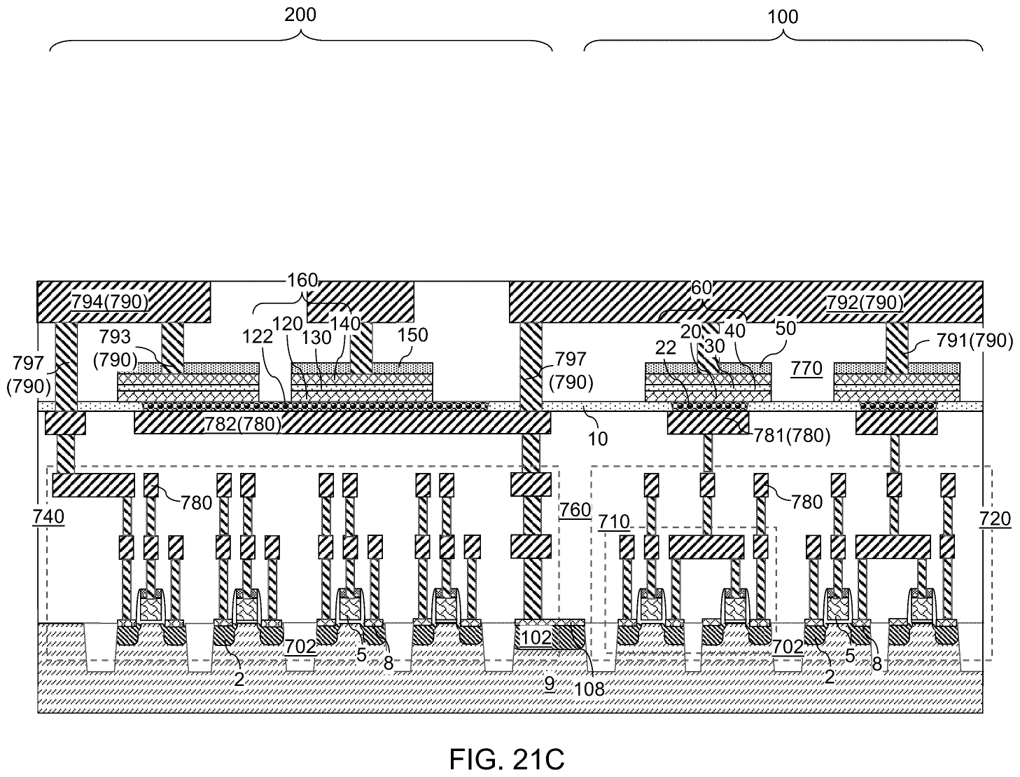

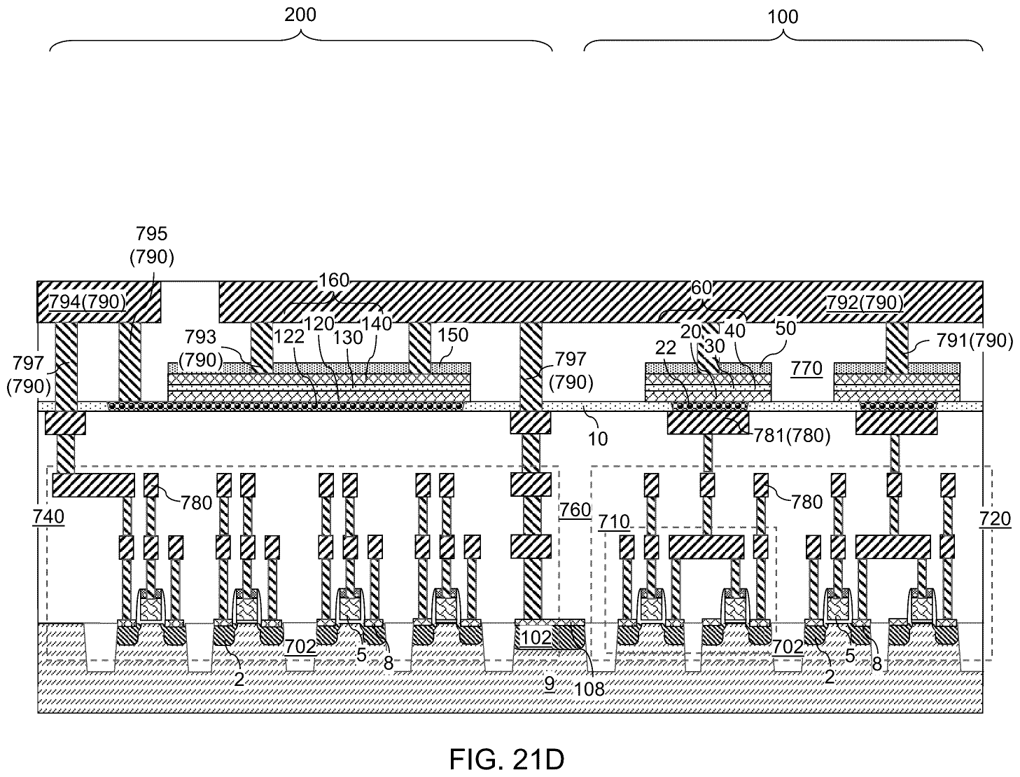

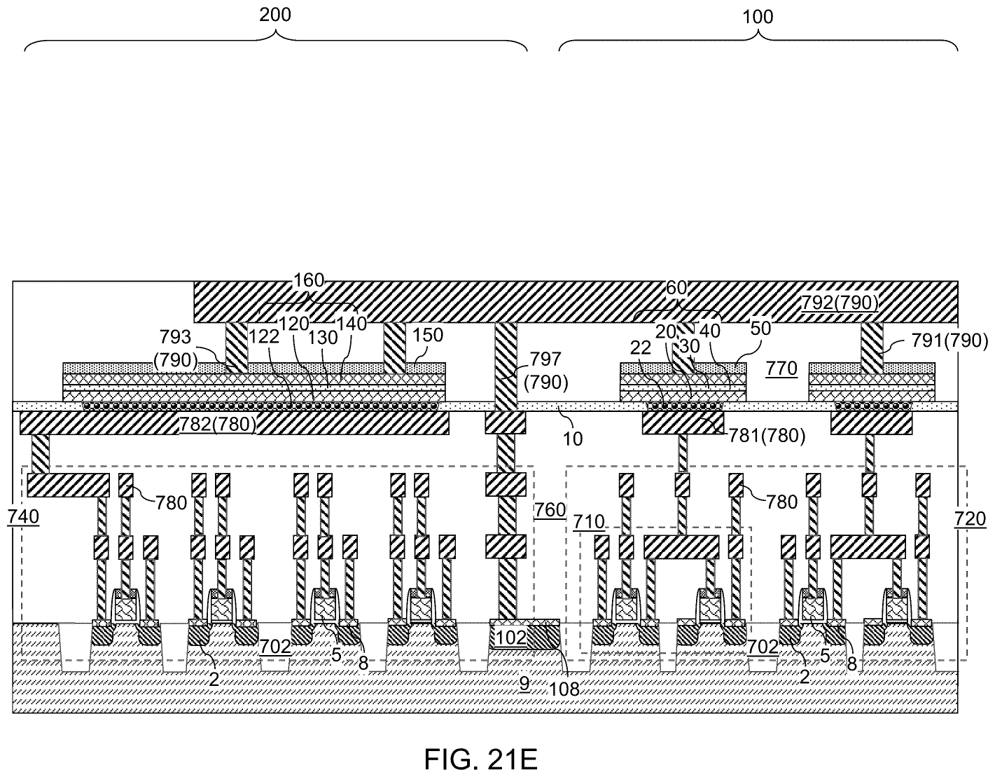

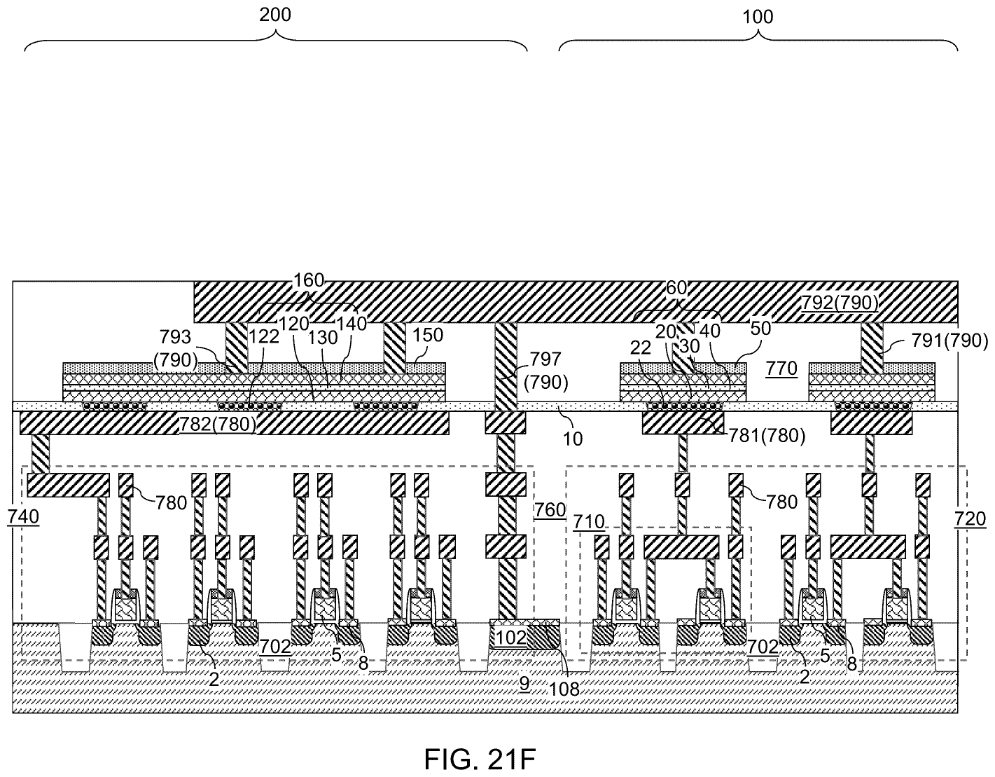

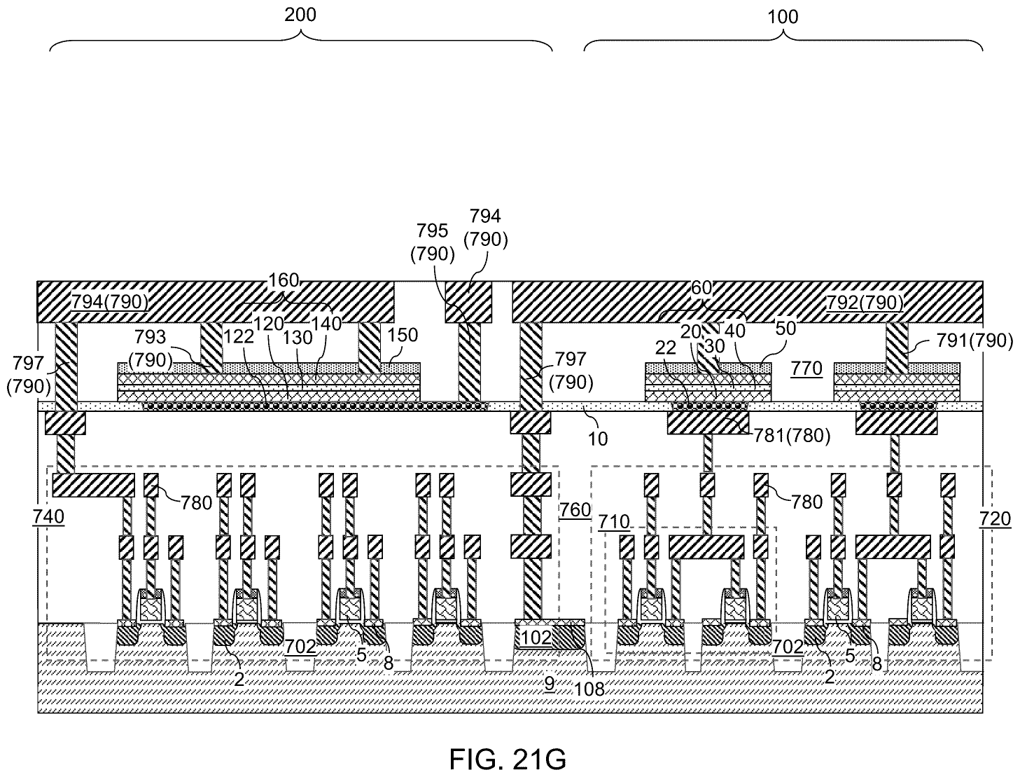

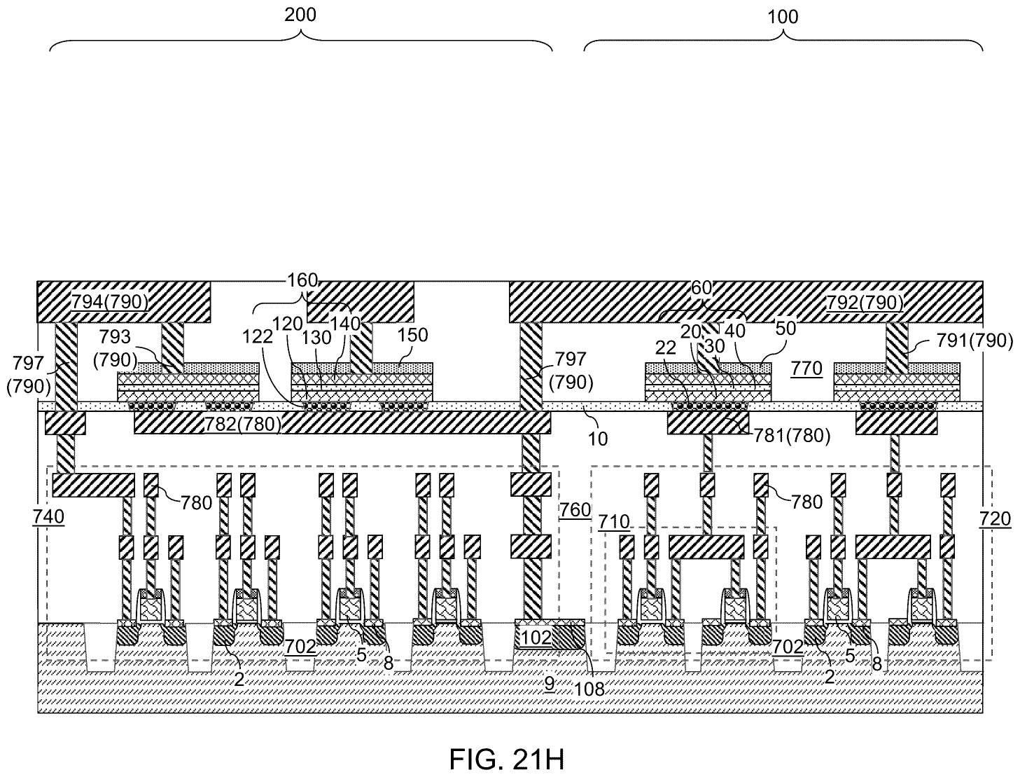

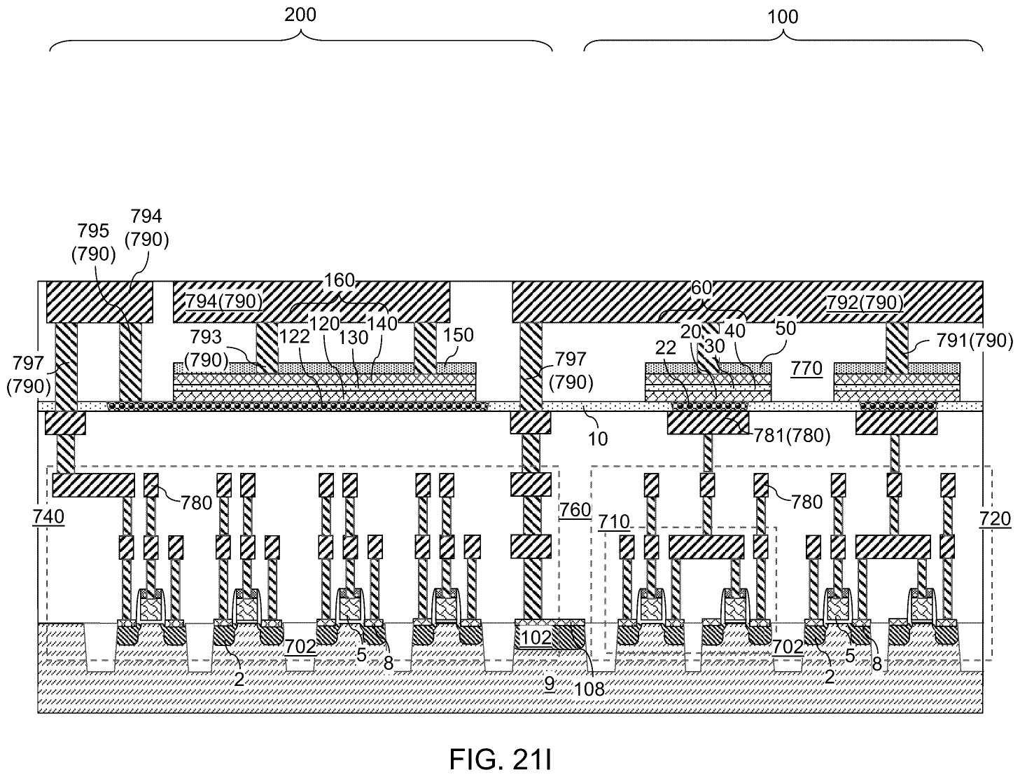

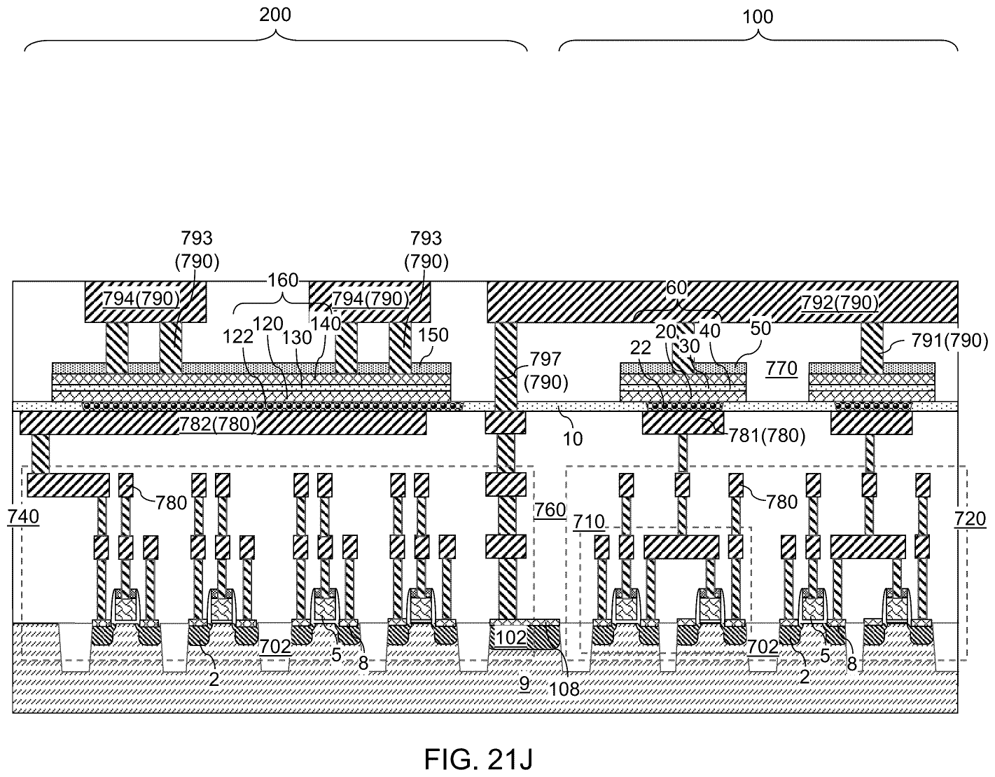

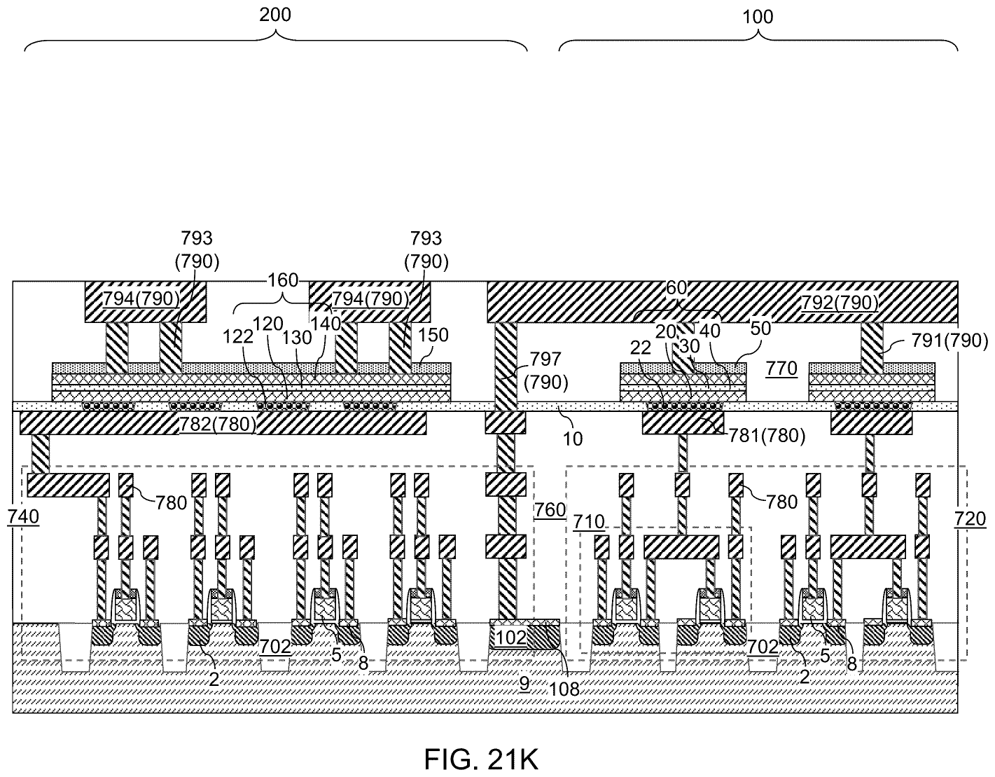

Referring to FIG. 21A, an upper-level dielectric material layer 770 and upper-level metal interconnect structures 790 may be formed to provide electrical connection to and from the second memory-capacitor electrode 40, the second stabilization-capacitor electrode 140, and the lower-level metal interconnect structures 780. The upper-level metal interconnect structures 790 may comprise array electrode contact via structures 791 that contact a respective one of the second memory-capacitor electrodes 40, at least one peripheral top electrode contact via structure 793 that contacts the second stabilization-capacitor electrodes 140, a peripheral bottom electrode contact via structure 795 that contacts the at least one peripheral damascene pad 122, and connection via structures 797 that contact a respective metal line or a respective metal pad that may be formed within the lower-level dielectric material layers 760. Further, the upper-level metal interconnect structures 790 may comprise a memory-region upper metal line 792 that contacts a plurality of the array electrode contact via structures 791, and at least one peripheral-region metal line 794 that contacts a respective subset of the peripheral top electrode contact via structures 793.

In one embodiment, the memory-region upper metal line 792 may contact a connection via structure 797 that is electrically connected to an electrical ground node, which may comprise a doped semiconductor well 102 and the semiconductor substrate 9. In some embodiments, one of the first stabilization-capacitor electrode 120 and the second stabilization-capacitor electrode 140 may be electrically grounded, and another of the stabilization-capacitor electrode 120 and the second stabilization-capacitor electrode 140 may be connected to a power supply node of a circuit, such as the peripheral circuit 740. In one embodiment, the first stabilization-capacitor electrode 120 may be electrically grounded through the peripheral bottom electrode contact via structure 795. In this embodiment, the memory-region upper metal line 792 may contact the peripheral bottom electrode contact via structure 795. In one embodiment, the voltage stabilization capacitor 160 may be configured to stabilize a voltage of the peripheral circuit 740. In one embodiment, the voltage stabilization capacitor 160 comprises an electrical node (which may, or may not, be a power supply node) that is not electrically shorted to any of the memory damascene pads 22.

FIGS. 21B-21K are vertical cross-sectional views of alternative configurations of the fourth embodiment structure according to the fourth embodiment of the present disclosure.

Referring to FIG. 21B, a first alternative configuration of the fourth embodiment structure may be derived from the fourth embodiment structure of FIG. 21A by forming a plurality of voltage stabilization capacitors 160 having first stabilization-capacitor electrodes 120 that contact the same peripheral damascene pad 122.

Referring to FIG. 21C, a second alternative configuration of the fourth embodiment structure may be derived from the fourth embodiment structure of FIG. 21A or from the first alternative embodiment of the fourth embodiment structure of FIG. 21B by connecting the at least one peripheral damascene pad 122 directly to a lower-level metal interconnect structure 780 such as a metal via structure. In this embodiment, the connection via structure 797 may be formed directly on a top surface of the at least one peripheral damascene pad 122.

Referring to FIG. 21D, a third alternative configuration of the fourth embodiment structure may be derived from the fourth embodiment structure of FIG. 21A by electrically grounding the second stabilization-capacitor electrode 140 through the peripheral top electrode contact via structures 793. In this embodiment, the memory-region upper metal line 792 may contact the peripheral top electrode contact via structure 793. In one embodiment, the voltage stabilization capacitor 160 may be configured to stabilize a voltage of the peripheral circuit 740. In one embodiment, the voltage stabilization capacitor 160 comprises a power supply node that is not directly connected to memory damascene pads 22. For example, the first stabilization-capacitor electrode 120 may be electrically connected to the power supply node through a peripheral bottom electrode contact via structure 795, a peripheral region metal line 794, and a connection via structure 797.

Referring to FIG. 21E, a fourth alternative configuration of the fourth embodiment structure may be derived from the third alternative configuration of the fourth embodiment structure of FIG. 21D by extending one of the metal lines formed within the lower-level dielectric material layers 760 such that the one of the metal lines contacts a bottom surface of the at least one peripheral damascene pad 122. In this embodiment, the peripheral bottom electrode contact via structure 795 may be omitted.

Referring to FIG. 21F, a fifth alternative configuration of the fourth embodiment structure may be derived from the fourth alternative configuration of the fourth embodiment structure by forming a plurality of peripheral damascene pads 122 in lieu of a single peripheral damascene pad 122.

Referring to FIG. 21G, a sixth alternative configuration of the fourth embodiment structure may be derived from any of the above configurations of the fourth embodiment structure by not electrically grounding any of the first stabilization-capacitor electrode 120 and the second stabilization-capacitor electrode 140. In this embodiment, both of the first stabilization-capacitor electrode 120 and the second stabilization-capacitor electrode 140 are not electrically shorted to any of the memory damascene pads 22. In one embodiment, the second stabilization-capacitor electrode 140 may be electrically shorted to a power supply node.

Referring to FIG. 21H, a seventh alternative configuration of the fourth embodiment structure may be derived from any of the above configurations of the fourth embodiment structure (such as the second alternative configuration illustrated in FIG. 21C) by forming a plurality of peripheral damascene pads 122 in lieu of a single peripheral damascene pad 122.

Referring to FIG. 21I, an eighth alternative configuration of the fourth embodiment structure may be derived from any of the above configurations of the fourth embodiment structure by not electrically grounding any of the first stabilization-capacitor electrode 120 and the second stabilization-capacitor electrode 140. In this embodiment, both of the first stabilization-capacitor electrode 120 and the second stabilization-capacitor electrode 140 are not electrically shorted to any of the memory damascene pads 22. In one embodiment, the first stabilization-capacitor electrode 120 may be electrically shorted to a power supply node though a peripheral bottom electrode contact via structure 795, a peripheral-region metal line 794, and a connection via structure 797. The second stabilization-capacitor electrode 140 may be electrically connected to a single peripheral-region metal line 794 or to a plurality of peripheral-region metal lines 794.

Referring to FIG. 21J, a ninth alternative configuration of the fourth embodiment structure may be derived from any of the above configurations of the fourth embodiment structure by not electrically connecting the first stabilization-capacitor electrode 120 to an electrical node of the peripheral circuit 740 through a peripheral-region metal pad 782. In this embodiment, both of the first stabilization-capacitor electrode 120 and the second stabilization-capacitor electrode 140 are not electrically shorted to any of the memory damascene pads 22. In one embodiment, the first stabilization-capacitor electrode 120 may be electrically shorted to a power supply node though a peripheral-region metal pad 782. The second stabilization-capacitor electrode 140 may be electrically connected to a single peripheral-region metal line 794 or to a plurality of peripheral-region metal lines 794.

Referring to FIG. 21K, a tenth alternative configuration of the fourth embodiment structure may be derived from the ninth configurations of the fourth embodiment structure by forming a plurality of peripheral damascene pads 122 in lieu of a single peripheral damascene pad 122. The second stabilization-capacitor electrode 140 may be electrically connected to a single peripheral-region metal line 794 or to a plurality of peripheral-region metal lines 794.

Referring collectively to FIGS. 21A-21K, the memory array may comprise an array of gain cell transistors, and the first electrodes (i.e., the first memory-capacitor electrodes 20) of the memory node capacitors 60 are electrically connected to a gate electrode of a respective one of the gain cell transistors through a respective subset of the lower-level metal interconnect structures 780.

Referring collectively to FIGS. 1-21K and according to various embodiments of the present disclosure, a device structure is provided, which comprises: a peripheral circuit 740 located over a semiconductor substrate 9 in a peripheral device region 200; a memory array comprising transistors located over the semiconductor substrate 9 in a memory array region 100 and an array of memory node capacitors 60 overlying lower-level dielectric material layers 760 that overlie the transistors, wherein lower-level metal interconnect structures 780 may be formed within the lower-level dielectric material layers 760 and comprise an array of connection metal pads 781 electrically connected to a respective one of the transistors and electrically connected to a first electrode (i.e., a first memory-capacitor electrode 20) of a respective one of the memory node capacitors 60; a voltage stabilization capacitor 160 located over the lower-level dielectric material layers 760 and configured to stabilize a voltage of the peripheral circuit 740; and a dielectric capping layer 10 overlying the array of connection metal pads 781 and comprising an array of memory-region openings 19 through which electrical connections are provided between the first electrodes (i.e., the first memory-capacitor electrodes 20) and the array of connection metal pads 781 and further comprising at least one peripheral-region opening 29 that underlies or laterally surrounds a first stabilization-capacitor electrode 120.

In one embodiment, the first electrode (i.e., the first memory-capacitor electrode 20) of the respective one of the memory node capacitors 60 comprises a first horizontally-extending portion 20H1 that overlies the dielectric capping layer 10, and a downward-protruding portion that is adjoined to an inner periphery of the first horizontally-extending portion 20H1 and protrudes downward relative to the first horizontally-extending portion 20H1 and fills a respective one of the memory-region openings 19. In one embodiment, each of the memory node capacitors 60 comprises a respective node dielectric (such as a memory-capacitor node dielectric 30) having a vertical undulation in a vertical cross-sectional profile and comprises a first horizontally-extending portion 30H1 having an areal overlap with the dielectric capping layer 10 in a plan view, a second horizontally-extending portion 30H2 within an area of one of the memory-region openings 19, and a tubular connecting portion 30C connecting a periphery of the second horizontally-extending portion 30H2 to a periphery of an opening in the first horizontally-extending portion 30H1. In one embodiment, each of the memory node capacitors 60 comprises: a node dielectric (such as a memory-capacitor node dielectric 30) contacting a top surface of the first electrode (i.e., the first memory-capacitor electrode 20); and a second electrode (i.e., a second stabilization-capacitor electrode 140) having a top surface located within a horizontal plane including a top surface of the node dielectric (such as a memory-capacitor node dielectric 30). In one embodiment, each of the memory node capacitors 60 comprises a node dielectric (such as a memory-capacitor node dielectric 30) having sidewalls, and is contacted by a bottom surface of an array hard mask plate 50 having sidewalls that are vertically coincident with the sidewalls of the node dielectric (such as a memory-capacitor node dielectric 30). In one embodiment, the device structure further comprises an array of memory damascene pads 22 located in the array of memory-region openings 19, wherein each first electrode (i.e., the first memory-capacitor electrode 20) of the memory node capacitors 60 contacts a top surface of a respective one of the memory damascene pads 22. In one embodiment, the memory array comprises an array of gain cell transistors; and the first electrodes (i.e., the first memory-capacitor electrodes 20) of the memory node capacitors 60 are electrically connected to a gate electrode of a respective one of the gain cell transistors through a respective subset of the lower-level metal interconnect structures 780.

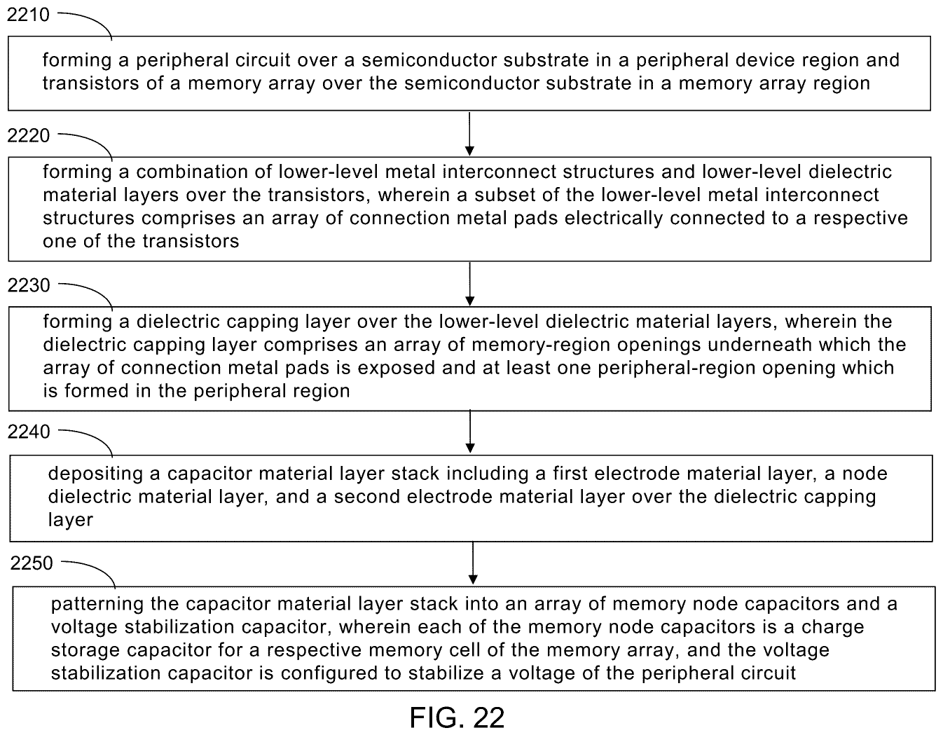

FIG. 22 is a first flowchart that illustrates a sequence of processing steps for forming a semiconductor structure of the present disclosure.

Referring to step 2210 and FIGS. 1, 2A, and 2B, a peripheral circuit 740 may be formed over a semiconductor substrate 9 in a peripheral device region 200, and transistors of a memory array may be formed over the semiconductor substrate 9 in a memory array region 100.

Referring to step 2220 and FIGS. 1 and 3, a combination of lower-level metal interconnect structures 780 and lower-level dielectric material layers 760 may be formed over the transistors. A subset of the lower-level metal interconnect structures 780 comprises an array of connection metal pads 781 electrically connected to a respective one of the transistors.

Referring to step 2230 and FIGS. 3 and 4, a dielectric capping layer 10 may be formed over the lower-level dielectric material layers 760. The dielectric capping layer 10 comprises an array of memory-region openings 19 underneath which the array of connection metal pads 781 is exposed and at least one peripheral-region opening 29 which is formed in the peripheral device region 200.

Referring to step 2240 and FIGS. 5, 9, and 17-19, a capacitor material layer stack (20L, 30L, 40L) including a first electrode material layer 20L, a node dielectric material layer 30L, and a second electrode material layer 40L may be deposited over the dielectric capping layer 10.

Referring to step 2250 and FIGS. 6, 7, 8A-8H, 10, 11, 12, 13A-13H, 14, 15, 16A-16F, 20, and 21A-21K, the capacitor material layer stack (20L, 30L, 40L) may be patterned into an array of memory node capacitors 60 and a voltage stabilization capacitor 160. Each of the memory node capacitors 60 is a charge storage capacitor for a respective memory cell of the memory array, and the voltage stabilization capacitor 160 is configured to stabilize a voltage of the peripheral circuit 740.

In one embodiment, the first electrode material layer 20L may be deposited directly on physically exposed of the array of connection metal pads 781, sidewalls of the memory-region openings 19, and a top surface of the dielectric capping layer 10. In one embodiment, the node dielectric material layer 30L may be formed with vertical undulations in a vertical cross-sectional profile such that the node dielectric material layer 30L comprises a first horizontally-extending portion 30H1 having an areal overlap with the dielectric capping layer 10 in a plan view, second horizontally-extending portions 30H2 within areas of the an array of memory-region openings 19 and the at least one peripheral-region opening 29, and tubular connecting portions 30C connecting a periphery of a respective one of the second horizontally-extending portions 30H2 to a periphery of a respective opening in the first horizontally-extending portion 30H1. In one embodiment, the method may further include: forming a hard mask material layer 50L at least over the node dielectric material layer 30L of the capacitor material layer stack (20L, 30L, 40L); patterning the hard mask material layer 50L into array hard mask plates 50 and at least one peripheral hard mask plate 150; and transferring a pattern in the array of array hard mask plates 50 and the at least one peripheral hard mask plate 150 at least through the node dielectric material layer 30L and the first electrode material layer 20L using an anisotropic etch process that etches materials of the capacitor material layer stack (20L, 30L, 40L) selectively to a material of the dielectric capping layer 10, whereby the capacitor material layer stack (20L, 30L, 40L) may be patterned. In one embodiment, a top surface of the second electrode material layer 40L may be formed with vertically recessed surface segments that overlie the array of memory-region openings 19 and the at least one peripheral-region opening 29; and each sidewall of patterned portions of the second electrode material layer 40L may be vertically coincident with a sidewall of a respective one of the array hard mask plates 50 and the at least one peripheral hard mask plate 150. In one embodiment, the method may further include the step of removing portions of the second electrode material layer 40L above a horizontal plane including a top surface of the node dielectric material layer 30L, wherein remaining portions of the second electrode material layer 40L comprise second electrodes 40 of the array of memory node capacitors 60 and a second electrode 140 of the voltage stabilization capacitor 160. In one embodiment, the method may further include: depositing a metallic fill material layer in the array of memory-region openings 19, in the at least one peripheral-region opening 29, and over the dielectric capping layer 10; and removing portions of the metallic fill material layer from above a horizontal plane including a top surface of the dielectric capping layer 10, wherein remaining portions of the metallic fill material layer comprise an array of memory damascene pads that fills the array of memory-region openings 19 and at least one peripheral damascene pad that fills the at least one peripheral-region opening 29. In one embodiment, the portions of the metallic fill material layer are removed by performing a chemical mechanical polishing process that removes a material of the metallic fill material layer using the dielectric capping layer 10 as a planarization stopper layer.

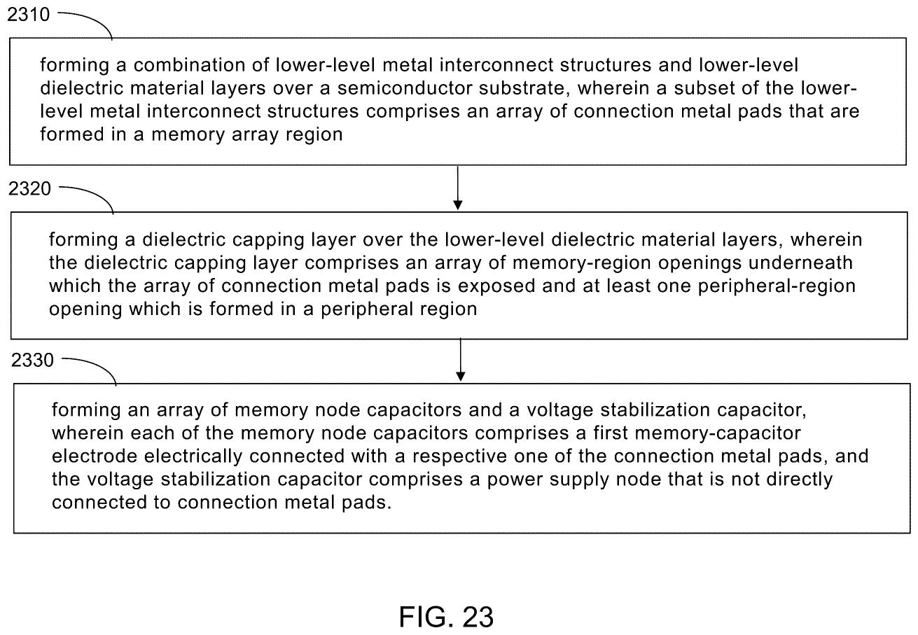

FIG. 23 is a second flowchart that illustrates a sequence of processing steps for forming a semiconductor structure of the present disclosure.

Referring to step 2310 and FIGS. 1, 2A, 2B, and 3, a combination of lower-level metal interconnect structures 780 and lower-level dielectric material layers 760 may be formed over a semiconductor substrate 9. A subset of the lower-level metal interconnect structures 780 comprises an array of connection metal pads 781 that are formed in a memory array region 100.

Referring to step 2320 and FIGS. 3 and 4, a dielectric capping layer 10 may be formed over the lower-level dielectric material layers 760. The dielectric capping layer 10 comprises an array of memory-region openings 19 underneath which the array of connection metal pads 781 is exposed and at least one peripheral-region opening 29 which is formed in a peripheral device region 200.

Referring to step 2330 and FIGS. 5, 6, 7, 8A-8H, 9, 10, 11, 12, 13A-13H, 14, 15, 16A-16F, 17, 18, 19, 20, and 21A-21K, an array of memory node capacitors 60 and a voltage stabilization capacitor 160 may be formed. Each of the memory node capacitors 60 comprises a first memory-capacitor electrode 20 electrically connected with a respective one of the connection metal pads 781, and the voltage stabilization capacitor 160 comprises a power supply node that is not directly connected to connection metal pads 781.

In one embodiment, the method may further include: depositing a capacitor material layer stack (20L, 30L, 40L) including a first electrode material layer 20L, a node dielectric material layer 30L, and a second electrode material layer 40L over the dielectric capping layer 10; and patterning the capacitor material layer stack (20L, 30L, 40L) into the array of memory node capacitors 60 and the voltage stabilization capacitor 160, wherein each first memory-capacitor electrode 30 is a patterned portion of the first electrode material layer 30L, and a first stabilization-capacitor electrode 130 of the voltage stabilization capacitor 160 is an additional patterned portion of the first electrode material layer 30L. In one embodiment, the first electrode material layer 30L is deposited within the array of memory-region openings 19 and within at least one peripheral-region opening 29. In one embodiment, the method may further include forming a peripheral-region metal pad 782 within the lower-level dielectric material layers 760, wherein: the dielectric capping layer 10 may be formed directly on a top surface of the peripheral-region metal pad 782; and the peripheral-region metal pad 782 may be electrically shorted to the first stabilization-capacitor electrode 160 upon formation of the first stabilization-capacitor electrode 160. In one embodiment, the method may further include: forming an array of memory damascene pads 781 in the array of memory-region openings 19; and forming at least one peripheral damascene pad in the at least one peripheral-region opening 29, wherein the first electrode material layer 30L is formed on the array of memory damascene pads and on the at least one peripheral damascene pad.

The various embodiments of the present disclosure provide an efficient method for simultaneously forming memory node capacitors and a voltage stabilization capacitor in a semiconductor structure. By integrating these capacitors within the lower-level dielectric material layers and lower-level metal interconnect structures, and utilizing the dielectric capping layer with memory-region openings and peripheral-region openings, the method addresses the challenges of achieving high capacitance with minimal device footprint. This approach eliminates the need for additional masks, thereby reducing production costs and process complexity, while ensuring improved performance and scalability of the memory array and peripheral circuit.

The foregoing outlines features of several embodiments so that those skilled in the art may better understand the aspects of the present disclosure. Each embodiment described using the term “comprises” also inherently discloses that the term “comprises” may be replaced with “consists essentially of” or with the term “consists of” in some embodiments, unless expressly disclosed otherwise herein. Whenever two or more elements are listed as alternatives in a same paragraph or in different paragraphs, a Markush group including a listing of the two or more elements may also be impliedly disclosed. Whenever the auxiliary verb “can” is used in this disclosure to describe formation of an element or performance of a processing step, an embodiment in which such an element or such a processing step is not performed is also expressly contemplated, provided that the resulting apparatus or device may provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a device structure comprising:
forming a peripheral circuit over a semiconductor substrate in a peripheral device region and transistors of a memory array over the semiconductor substrate in a memory array region;
forming a combination of lower-level metal interconnect structures and lower-level dielectric material layers over the transistors, wherein a subset of the lower-level metal interconnect structures comprises an array of connection metal pads electrically connected to a respective one of the transistors;
forming a dielectric capping layer over the lower-level dielectric material layers, wherein the dielectric capping layer comprises an array of memory-region openings underneath which the array of connection metal pads is exposed and at least one peripheral-region opening which is formed in the peripheral device region;
depositing a capacitor material layer stack including a first electrode material layer, a node dielectric material layer, and a second electrode material layer over the dielectric capping layer; and
patterning the capacitor material layer stack into an array of memory node capacitors and a voltage stabilization capacitor, wherein each of the memory node capacitors is a charge storage capacitor for a respective memory cell of the memory array, and the voltage stabilization capacitor is configured to stabilize a voltage of the peripheral circuit.

2. The method of claim 1, wherein the first electrode material layer is deposited directly on exposed top surface segments of the array of connection metal pads, sidewalls of the memory-region openings, and a top surface of the dielectric capping layer.

3. The method of claim 1, wherein the node dielectric material layer is formed with vertical undulations in a vertical cross-sectional profile such that the node dielectric material layer comprises a first horizontally-extending portion having an areal overlap with the dielectric capping layer in a plan view, second horizontally-extending portions within areas of the an array of memory-region openings and the at least one peripheral-region opening, and tubular connecting portions connecting a periphery of a respective one of the second horizontally-extending portions to a periphery of a respective opening in the first horizontally-extending portion.

4. The method of claim 1, further comprising:
forming a hard mask material layer at least over the node dielectric material layer of the capacitor material layer stack;
patterning the hard mask material layer into array hard mask plates and at least one peripheral hard mask plate; and
transferring a pattern in the array of array hard mask plates and the at least one peripheral hard mask plate at least through the node dielectric material layer and the first electrode material layer using an anisotropic etch process that etches materials of the capacitor material layer stack selectively to a material of the dielectric capping layer, whereby the capacitor material layer stack is patterned.

5. The method of claim 4, wherein:
a top surface of the second electrode material layer is formed with vertically recessed surface segments that overlie the array of memory-region openings and the at least one peripheral-region opening; and
each sidewall of patterned portions of the second electrode material layer is vertically coincident with a sidewall of a respective one of the array hard mask plates and the at least one peripheral hard mask plate.

6. The method of claim 4, further comprising removing portions of the second electrode material layer above a horizontal plane including a top surface of the node dielectric material layer, wherein remaining portions of the second electrode material layer comprise second electrodes of the array of memory node capacitors and a second electrode of the voltage stabilization capacitor.

7. The method of claim 1, further comprising:
depositing a metallic fill material layer in the array of memory-region openings, in the at least one peripheral-region opening, and over the dielectric capping layer; and
removing portions of the metallic fill material layer from above a horizontal plane including a top surface of the dielectric capping layer, wherein remaining portions of the metallic fill material layer comprise an array of memory pads that fills the array of memory-region openings and at least one peripheral pad that fills the at least one peripheral-region opening.

8. The method of claim 7, wherein the portions of the metallic fill material layer are removed by performing a chemical mechanical polishing process that removes a material of the metallic fill material layer using the dielectric capping layer as a planarization stopper layer.

9. A method of forming a device structure comprising:
forming a combination of lower-level metal interconnect structures and lower-level dielectric material layers over a semiconductor substrate, wherein a subset of the lower-level metal interconnect structures comprises an array of connection metal pads that are formed in a memory array region;
forming a dielectric capping layer over the lower-level dielectric material layers, wherein the dielectric capping layer comprises an array of memory-region openings underneath which the array of connection metal pads is exposed and at least one peripheral-region opening which is formed in a peripheral device region; and
forming an array of memory node capacitors and a voltage stabilization capacitor, wherein each of the memory node capacitors comprises a first memory-capacitor electrode electrically connected with a respective one of the connection metal pads, and the voltage stabilization capacitor comprises an electrical node that is not electrically shorted to any of the connection metal pads.

10. The method of claim 9, further comprising:
depositing a capacitor material layer stack including a first electrode material layer, a node dielectric material layer, and a second electrode material layer over the dielectric capping layer; and
patterning the capacitor material layer stack into the array of memory node capacitors and the voltage stabilization capacitor, wherein each first memory-capacitor electrode is a patterned portion of the first electrode material layer, and a first stabilization-capacitor electrode of the voltage stabilization capacitor is an additional patterned portion of the first electrode material layer.

11. The method of claim 10, wherein the first electrode material layer is deposited within the array of memory-region openings and within at least one peripheral-region opening.

12. The method of claim 10, further comprising forming a peripheral-region metal pad within the lower-level dielectric material layers, wherein:
the dielectric capping layer is formed directly on a top surface of the peripheral-region metal pad; and
the peripheral-region metal pad is electrically shorted to the first stabilization-capacitor electrode upon formation of the first stabilization-capacitor electrode.

13. The method of claim 12, further comprising:
forming an array of memory damascene pads in the array of memory-region openings; and
forming at least one peripheral damascene pad in the at least one peripheral-region opening, wherein the first electrode material layer is formed on the array of memory damascene pads and on the at least one peripheral damascene pad.

14. A device structure comprising:
a peripheral circuit located over a semiconductor substrate in a peripheral device region;
a memory array comprising transistors located over the semiconductor substrate in a memory array region and an array of memory node capacitors overlying lower-level dielectric material layers that overlie the transistors, wherein lower-level metal interconnect structures are formed within the lower-level dielectric material layers and comprise an array of connection metal pads electrically connected to a respective one of the transistors and electrically connected to a first electrode of a respective one of the memory node capacitors;
a voltage stabilization capacitor located over the lower-level dielectric material layers and configured to stabilize a voltage of the peripheral circuit; and
a dielectric capping layer overlying the array of connection metal pads and comprising an array of memory-region openings through which electrical connections are provided between the first electrodes and the array of connection metal pads and further comprising at least one peripheral-region opening that underlies or laterally surrounds a first stabilization-capacitor electrode.

15. The device structure of claim 14, wherein the first electrode of the respective one of the memory node capacitors comprises a horizontally-extending portion that overlies the dielectric capping layer, and a downward-protruding portion that is adjoined to an inner periphery of the horizontally-extending portion and protrudes downward relative to the horizontally-extending portion and fills a respective one of the memory-region openings.

16. The device structure of claim 14, wherein each of the memory node capacitors comprises a respective node dielectric having a vertical undulation in a vertical cross-sectional profile and comprises a first horizontally-extending portion having an areal overlap with the dielectric capping layer in a plan view, a second horizontally-extending portion within an area of one of the memory-region openings, and a tubular connecting portion connecting a periphery of the second horizontally-extending portion to a periphery of an opening in the first horizontally-extending portion.

17. The device structure of claim 14, wherein each of the memory node capacitors comprises:
a node dielectric contacting a top surface of the first electrode; and
a second electrode having a top surface located within a horizontal plane including a top surface of the node dielectric.

18. The device structure of claim 14, wherein each of the memory node capacitors comprises a node dielectric having sidewalls, and is contacted by a bottom surface of an array hard mask plate having sidewalls that are vertically coincident with the sidewalls of the node dielectric.

19. The device structure of claim 14, further comprising an array of memory damascene pads located in the array of memory-region openings, wherein each first electrode of the memory node capacitors contacts a top surface of a respective one of the memory damascene pads.

20. The device structure of claim 14, wherein:
the memory array comprises an array of gain cell transistors; and
the first electrodes of the memory node capacitors are electrically connected to a gate electrode of a respective one of the gain cell transistors through a respective subset of the lower-level metal interconnect structures.
